(19) United States
(12) Patent Application Publication
(10) Pub. No.: US 2025/0004070 A1
(43) Pub. Date: Jan. 2, 2025

(54) CIRCUITS, DEVICES, SYSTEMS AND METHODS FOR IMPLEMENTING POWER ADAPTERS AND MODULES

(71) Applicant: Smart Power Partners LLC, Wheaton, IL (US)

(72) Inventors: John J. King, Wheaton, IL (US); Stephen DeLano, Mitlon, MA (US)

(73) Assignee: Smart Power Partners LLC, Wheaton, IL (US)

(21) Appl. No.: 18/751,744

(22) Filed: Jun. 24, 2024

Related U.S. Application Data
(60) Provisional application No. 63/624,347, filed on Jan. 24, 2024.
(60) Provisional application No. 63/546,939, filed on Nov. 2, 2023.
(60) Provisional application No. 63/542,578, filed on Oct. 5, 2023.
(60) Provisional application No. 63/524,480, filed on Jun. 30, 2023.

(51) Int. Cl. G01R 31/67; H01R 13/66; H01R 13/70

(52) U.S. Cl. CPC G01R 31/67; H01R 13/6683; H01R 13/70

(57) ABSTRACT

An error detection module adapted to be attached to an in-wall power adapter is described. The error detection module may comprise a switch element configured to route a line voltage to a load; a control circuit coupled to the switch element, wherein the control circuit is adapted to control the switch element; and a user interface adapted to provide a test result associated with a detected error; wherein the control circuit controls the switch element to detect a type of wiring error.

### TECHNICAL FIELD

An implementation of the present invention relates generally to power adapters and modules, and methods of implementing power adapters and modules for monitoring conditions and controlling devices.

### BACKGROUND

Power adapters, such as switches and outlets which apply or control the application of power to a load (e.g., a light or other appliance), are an important part of any residential or commercial building and can provide beneficial control of a load attached to the power adapter, such as timing control, motion detection, and dimming for example. As power adapters continue to advance, additional functionality may be available to a user. In addition to providing control, power adapters may provide sensing capabilities. However, it may be difficult to integrate the various power adapters as a part of a single system. Further, homeowners may benefit from additional sensor or control capability associated with more devices, or additional monitoring or functional control of devices other than the power adapters. Homeowners may also benefit from systems that are simple to implement.

Accordingly, systems, circuits, devices, arrangements and methods that enable a user such as a homeowner or other building owner to easily and efficiently implement different power adapters are beneficial.

### SUMMARY

An error detection module adapted to be attached to an in-wall power adapter is described. The error detection module may comprise a switch element configured to route a line voltage to a load; a control circuit coupled to the switch element, wherein the control circuit is adapted to control the switch element; and a user interface adapted to provide a test result associated with a detected error; wherein the control circuit controls the switch element to detect a type of wiring error.

Another error detection module adapted to be attached to an in-wall power adapter may comprise a switch element configured to connect a line voltage to one of a load contact element and a traveler contact element; a control circuit coupled to the switch element, wherein the control circuit is adapted to control the switch element; and a user interface adapted to provide a test result associated with a detected wiring error; wherein the control circuit controls the switch element to detect a type of wiring error.

A method of detecting a wiring error for an in-wall power adapter is also described. The method may comprise configuring a switch element to route a line voltage to a load; coupling a control circuit to the switch element, wherein the control circuit is adapted to control the switch element; and providing a user interface to indicate a test result associated with a detected wiring error; wherein the control circuit controls the switch element to detect a type of wiring error.

### BRIEF DESCRIPTION OF THE DRAWINGS

FIG. 1 is a block diagram of a system 100 for monitoring and controlling a building.

FIG. 2 is a block diagram of a plurality of power adapters and modules according to one implementation.

FIG. 3 is a block diagram of a plurality of power adapters and modules according to another implementation.

FIG. 4 is a block diagram of a plurality of power adapters and modules according to another implementation.

FIG. 5 is a block diagram of a plurality of power adapters and modules according to another implementation.

FIG. 6 is a block diagram of a plurality of power adapters and modules according to another implementation.

FIG. 7 is a block diagram of a plurality of power adapters and modules according to another implementation.

FIG. 8 is a block diagram of a plurality of power adapters and modules according to another implementation.

FIG. 9 is a block diagram of a plurality of power adapters and modules according to another implementation.

FIG. 10 is a block diagram of a plurality of power adapters and modules according to another implementation.

FIG. 11 is a block diagram of a power adapter arrangement showing alignment elements along a first side of a recess.

FIG. 12 is a block diagram of the power adapter arrangement of FIG. 11 showing alignment elements along a second side of a recess.

FIG. 13 is a block diagram of a plurality of power adapters and modules having visual aids for matching modules to power adapters that are capable of operating with certain modules.

FIG. 14 is a block diagram of a power adapter arrangement comprising a single pole switch having contact elements configured to receive wires of a junction box.

FIG. 15 is a block diagram of a power adapter arrangement according to another implementation.

FIG. 16 is a block diagram of a circuit for indicating an incorrect wiring condition of a power adapter.

FIG. 17 is a block diagram of another circuit for indicating an incorrect wiring condition of a power adapter.

FIG. 18 is a block diagram of a power adapter arrangement configured to control multiple wirelessly controlled outlets using a common toggle signal according to one implementation.

FIG. 19 is a block diagram of a power adapter arrangement configured to control multiple wirelessly controlled outlets using a common on/off state signal according to one implementation.

FIG. 20 is a block diagram of a power adapter arrangement configured to control multiple wirelessly controlled outlets using signaling between wirelessly controlled outlet control modules according to one implementation.

FIG. 21 is a block diagram of a power adapter arrangement configured to control multiple wirelessly controlled outlets using multiple transmitters of a control module according to one implementation.

FIG. 22 is a block diagram of power adapter arrangements in a multi-way wiring arrangement.

FIG. 23 is a block diagram of a power adapter configured to be implemented as a companion switch power adapter in a multi-way wiring arrangement.

FIG. 24 is a flow chart showing a method of implementing a power adapter as a companion switch power adapter in a multi-way wiring arrangement.

FIG. 25 is a block diagram of a power adapter implemented as a primary switch power adapter in a multi-way wiring arrangement.

FIG. 26 is a flow chart showing a method of implementing a power adapter as a primary switch power adapter in a multi-way wiring arrangement.

FIG. 27 is a block diagram of a pair of power adapters configured in a multi-way wiring arrangement according to one implementation.

FIG. 28 is a flow chart showing a method of implementing a pair of power adapters according to the multi-way wiring arrangement of FIG. 27.

FIG. 29 is a block diagram of a pair of power adapters configured in a multi-way wiring arrangement according to another implementation.

FIG. 30 is a flow chart showing a method of implementing a pair pf power adapters according to the multi-way wiring arrangement of FIG. 29.

FIG. 31 is a block diagram of a pair of power adapters configured in a multi-way wiring arrangement according to a further implementation.

FIG. 32 is a flow chart showing a method of implementing a pair of power adapters according to the multi-way wiring arrangement of FIG. 31.

FIG. 33 is a block diagram of a power adapter having an external indicator.

FIG. 34 is a block diagram of a power adapter having an internal indicator.

FIG. 35 is a block diagram of a power adapter configured to be implemented as a companion switch power adapter in a multi-way wiring arrangement and having an error detection circuit.

FIG. 36 is a block diagram of a power adapter configured to be implemented as a primary switch power adapter in a multi-way wiring arrangement and having an error detection circuit.

FIG. 37 is a block diagram of a high voltage detection circuit that may be implemented in the error detection circuit of FIG. 35 or 36.

FIG. 38 is a block diagram of a low voltage detection circuit that may be implemented in the error detection circuit of FIG. 35 or 36.

FIG. 39 is a block diagram of a power adapter comprising an error detection circuit and a switch for disabling the power adapter.

FIG. 40 is a block diagram of a power adapter arrangement having a control module comprising an error detection circuit and a switch for disabling the power adapter.

FIG. 41 is a block diagram of a power adapter having an error detection circuit and a switch for disabling the power adapter.

FIG. 42 is a block diagram of a control module having an error detection circuit and a switch for disabling the power adapter.

FIG. 43 is a block diagram of a primary power adapter and a companion power adapter connected in a first wiring configuration.

FIG. 44 is a block diagram of a primary power adapter and a companion power adapter connected in a second wiring configuration.

FIG. 45 is a block diagram of a primary power adapter and two companion power adapters connected in a first wiring configuration.

FIG. 46 is a block diagram of a primary power adapter and two companion power adapters connected in a second wiring configuration.

FIG. 47 is a block diagram of a primary power adapter and two companion power adapters connected in a third wiring configuration.

FIG. 48 is a block diagram of a circuit for detecting when a line voltage is connected to a traveler contact element of a power adapter.

FIG. 49 is a block diagram of another circuit for detecting when a line voltage is connected to a traveler contact element of a power adapter.

FIG. 50 is a block diagram of a circuit for detecting when a line voltage is connected to a traveler contact element and providing an error signal according to a first implementation.

FIG. 51 is a block diagram of a circuit for detecting when a line voltage is connected to a traveler contact element and providing an error signal according to a second implementation.

FIG. 52 is a block diagram of a circuit for detecting when a line voltage is connected to a traveler contact element and providing an error signal according to a third implementation.

FIG. 53 is a series of power adapters having two error indicator elements showing three different error states according to a first implementation.

FIG. 54 is a series of power adapters having two error indicator elements showing three different error states according to a second implementation.

FIG. 55 is a series of power adapters having two error indicator elements showing three different error states according to a third implementation.

FIG. 56 is a perspective view of a power adapter arrangement comprising a power adapter having a switch and a test module.

FIG. 57 is another perspective view of a power adapter arrangement comprising a power adapter and a test module.

FIG. 58 is a block diagram of the power adapter arrangement of FIG. 57 in a single pole arrangement.

FIG. 59 is a block diagram of a pair of power adapter arrangements in a 3-way wiring arrangement, where a test module is attached to a power adapter receiving a line voltage.

FIG. 60 is a block diagram of a pair of power adapter arrangements in a 3-way wiring arrangement, where a test module is attached to a power adapter coupled to a load.

FIG. 61 is a block diagram of a 4-way wiring arrangement having a test module in a first power adapter of the 4-way wiring arrangement.

FIG. 62 is a block diagram of a 4-way wiring arrangement having a test module in a second power adapter of the 4-way wiring arrangement.

FIG. 63 is a block diagram of a 4-way wiring arrangement having a test module in a third power adapter of the 4-way wiring arrangement.

FIG. 64 is a flow chart showing a method of testing a wiring error between power adapters in a wiring arrangement.

FIG. 65 is a perspective view of a temperature detector module.

FIG. 66 is a cross-sectional view of the temperature detection module of FIG. 66 taken at lines 66-66.

FIG. 67 is a cross-sectional view of the temperature detection module of FIG. 66 taken at lines 67-67.

FIG. 68 is a cross-sectional view of the temperature detection module of FIG. 66 taken at lines 68-68.

FIG. 69 is a block diagram of a circuit for the temperature detection module of FIG. 66.

FIG. 70 is a flow chart for a method of implementing a temperature module.

FIG. 71 is a user interface for a control module adapted to provide status information associated with a door, such as a garage door.

FIG. 72 is a user interface for a control module adapted to provide status information and a control interface associated with a door, such as a garage door.

FIG. 73 is a user interface for a control module adapted to provide status information associated with multiple doors, such as garage doors.

FIG. 74 is a user interface for a control module adapted to provide status information and a control interface associated with multiple doors, such as garage doors.

FIG. 75 is an example of a user interface of a door chime control module associated with a doorbell camera.

FIG. 76 is a user interface of a control module enabling determining status and providing control of an associated doorbell camera.

FIG. 77 is a user interface of a control module enabling controlling settings of an associated doorbell camera.

FIG. 78 is an example of a control module having a dedicated display.

FIG. 79 is a system for integrating control modules associated with different control functions associated with a building such as a residential building.

FIG. 80 is a system showing additional details for integrating control modules associated with different control functions associated with a building such as a residential building.

FIG. 81 is a flow chart showing a method of implementing an error detection module.

FIG. 82 is a flow chart showing a method of implementing an in-wall power adapter adapted to receive a module and adapted to provide power to a load.

FIG. 83 is a flow chart showing a method of implementing an in-wall power adapter configured to receive a module.

FIG. 84 is a flow chart showing a method of indicating compatibility of modules and power adapters adapted to receive modules.

FIG. 85 is a flow chart showing a method of implementing a module adapted to be attached to an in-wall power adapter.

### DETAILED DESCRIPTION

Conventional systems of home monitoring and control of various devices or appliances in the home are limited. It is also difficult to integrate a variety of different devices that control or monitor other devices or appliances. The circuits, devices, systems and methods for monitoring conditions and controlling devices of a building provide a benefit to homeowners and owners of buildings.

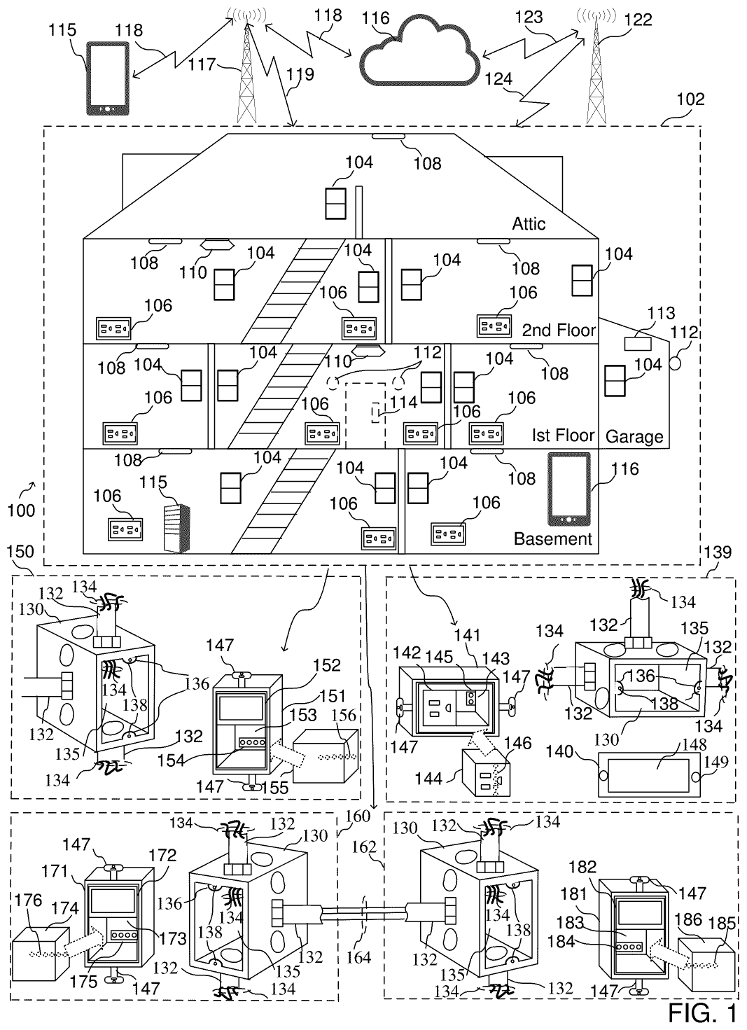

Turning first to FIG. 1, a block diagram of a system 100 for monitoring and controlling a building is shown. The system 100 comprises a building 102, which may be a residential building, a commercial building, a portion of a residential or commercial building, or some other structure having power adapters that control devices and appliances. The building 102 comprises a plurality of levels, shown here by way of example as a basement, a first floor, a second floor, and an attic. A garage, which is shown by way of example as being attached to the first floor, is also shown.

Each of the levels comprises various devices that may be controlled according to the system set forth in more detail below. The building 102 may comprise a variety of power adapters, including power adapters 104 that function as switches for controlling the application of power to a load, such as a light or appliance controlled by power adapters having a switch, or power adapters 106 having an outlet, also commonly called receptacles, shown by way of example here as comprising duplex outlets (i.e., an outlet adapted to receive two plugs). A power adapter having a switch, such as power adapter 104, may also be referred to as a switch power adapter and a power adapter having an outlet, such as power adapter 106, may also be referred to as an outlet power adapter. As will be described in more detail below, the power adapters may comprise integrated power adapters which include all the elements of the power adapter in a single device, or power adapter arrangements comprising a power adapter and a control module. According to some implementations, a power adapter may not have a switch, but the switching of power received at the power adapter and provided to the load may be controlled by a module attached to the power adapter, as will be described in more detail below. As will be described in more detail below, a control module may be an active control module that controls the application of power to a load or a passive control module that receives the line voltage at a contact element and routes the line voltage to another contact element or a circuit of the control module. By way of example, a passive control module may control the application of power to a device, such as a mobile phone, electrically connected to a charging connector, such as a USB connector, or provide some other functionality, such as light emitted by a night light control module for providing light based upon the level of ambient light in a room.

The building may also comprise various detector devices 108, such as a smoke detector, a carbon monoxide detector, particulate sensor, or some other type of air quality detector, which may be standalone devices or connected to a power adapter in a junction box. Described in more detail below, the detector devices may be adapted to receive a control module according to other implementations.

The building may also comprise various light fixtures, including both indoor light fixtures 110 and outdoor light fixtures 112. As will be described in more detail below, the light fixtures may also be adapted to receive a control module. A garage may also include a garage door opener 113.

A door lock 114 associated with the door, shown in dashed lines, may also be included. The door lock 114 may comprise a modular door lock and have various interfaces, both on the inside of the door and the outside of the door, enabling a user to receive or provide Information as will be described in more detail below.

The various devices of the building 102 may be adapted to communicate, using a wired arrangement or by way of a wireless communication link, with elements within the building, or outside the building. A communication device 115 is shown by way of example within the house. While the communication device is shown separate from the power adapters and other devices, the communication device 115 could be integrated into one of the devices. The communication device 115, or the communication capability of any of the other devices in the building 102, enables communication with one or more external devices or networks, such as another communication device 115 that is remote from the building 102. Another communication device 115 shown remote from the building 102 is adapted to communicate with a remote network 116 by way of a wireless network 117 and wireless communication links 118 as shown. The communication device 115 external to the building may also communicate with a device, network or system of the building 102 by way of the wireless communication link 119. The communication device 115 external to the building 102 may also communicate with a second network 122 by way of a communication link 123 and with a device, network or system of the building 102 by way of a communication link 124. The communication device could be any type of communication device, including a fixed or mobile communication device that is adapted to communicate using any communication protocol. The communication device may be adapted to enable communication between all of the devices of the building 102 and with other devices or communication networks external to the building. Examples of the communication device could be a fixed or mobile phone, a computer, a laptop, a tablet, or other wireless communication devices. According to some implementations, the communication device 115 shown in the basement, could be a computer functioning as a server.

The building also receives power by way of a line voltage, commonly known as line power, that is distributed to various power adapters that may be installed in junction boxes. More particularly, junction boxes 130 may be coupled to conduit 132 having wires 134 that may be used to provide power to power adapters by way of terminal portions of the wires 134 that extend into a recess 135 adapted to receive a power adapter. Flanges 136 receive a screw or other attachment element by way of a threaded portion 138 to enable attaching corresponding flanges of the power adapter to the flanges 136. Junction boxes 130 are commonly installed in residential and commercial buildings, such as attached to a stud behind wall board material for example.

In addition to power adapters that comprise single piece units (i.e., integrated power adapters), various power adapter arrangements having a power adapter adapted to be inserted into a junction box and to receive a control module may be used. More particularly, a first arrangement 139 of a power adapter arrangement and junction box comprises a power adapter 141 having an outlet 142 and a recess 143 adapted to receive a module 144. An electrical interface 145 positioned within the recess adapted to be coupled to a corresponding electrical interface 146 of the module 144. Flanges 147 are adapted to be coupled to the junction box, and may comprise a threaded opening adapted to receive screws of a faceplate 140, also known as a wall plate. A faceplate 140 comprises an opening 148 that is adapted to receive the outlet 142 and the module 144. The faceplate 140 also comprises openings 149 for receiving screws to couple the faceplate to the flanges 147 or a junction box. It should be understood that the faceplate 140 could be attached to the other power adapters of the system of FIG. 1. As will be described in more detail below, the module 144, shown here by way of example as an outlet module, may comprise different functionality.

A second arrangement 150 of a power adapter arrangement and associated junction box comprises a power adapter 151 having a switch 152. More particularly, the power adapter 151 comprises a recess 153 having an electrical interface 154 and is adapted to receive a module 155 having an electrical interface 156 adapted to be coupled to the electrical interface 154. As will be described in more detail below, the module 155 may comprise different user interface elements and provide additional functionality to the power adapter 151, including controlling the application of power to a load. It should be understood that the modules may be used interchangeably in a power adapter having an outlet and a power adapter having a switch, as will also be described in more detail below.

A third arrangement 160 of a power adapter and an associated junction box comprises a power adapter arrangement having a switch. More particularly, the arrangement 160 comprises a first power adapter 171 having a switch 172 and a recess 173 adapted to receive a module 174. An electrical interface 175 of the recess 173 is adapted to be coupled to an electrical interface 176 of the module. Similarly, a power adapter 181 having a switch 182 of a fourth arrangement 162 comprises a recess 183 having and an electrical interface 184 adapted to be coupled to an electrical interface 185 of a module 186. The junction box receiving the power adapter 171 and the junction box receiving the power adapter 181 are coupled by wires 164, which enable a multi way wiring arrangement, as shown by way of example here as a three-way wiring arrangement. According to some implementations, the power adapter 171 could be a primary power adapter that enables switching of power to a load and the power adapter 181 could be companion power adapter for sending signals, such as switching signals, to the primary power adapter. The operation of a multiway switch, such as a three-way switch, will be described in more detail below. Power adapters 141, 151, 171 and 181 as shown are in-wall power adapters that are adapted to be coupled to a junction box ant the wires of the junction box.

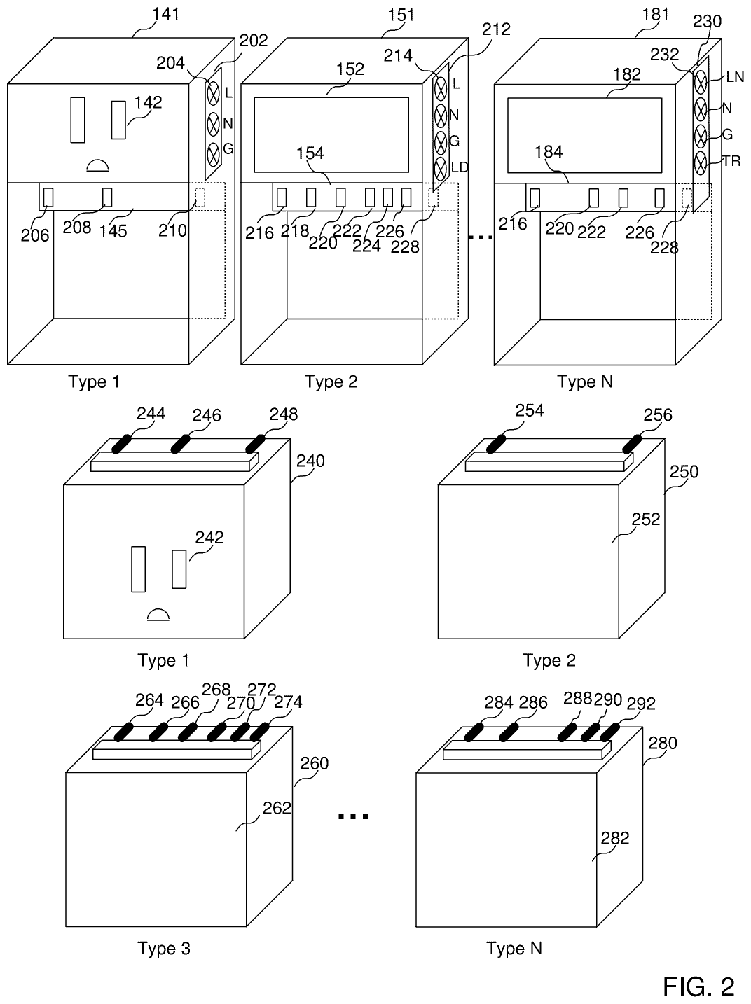

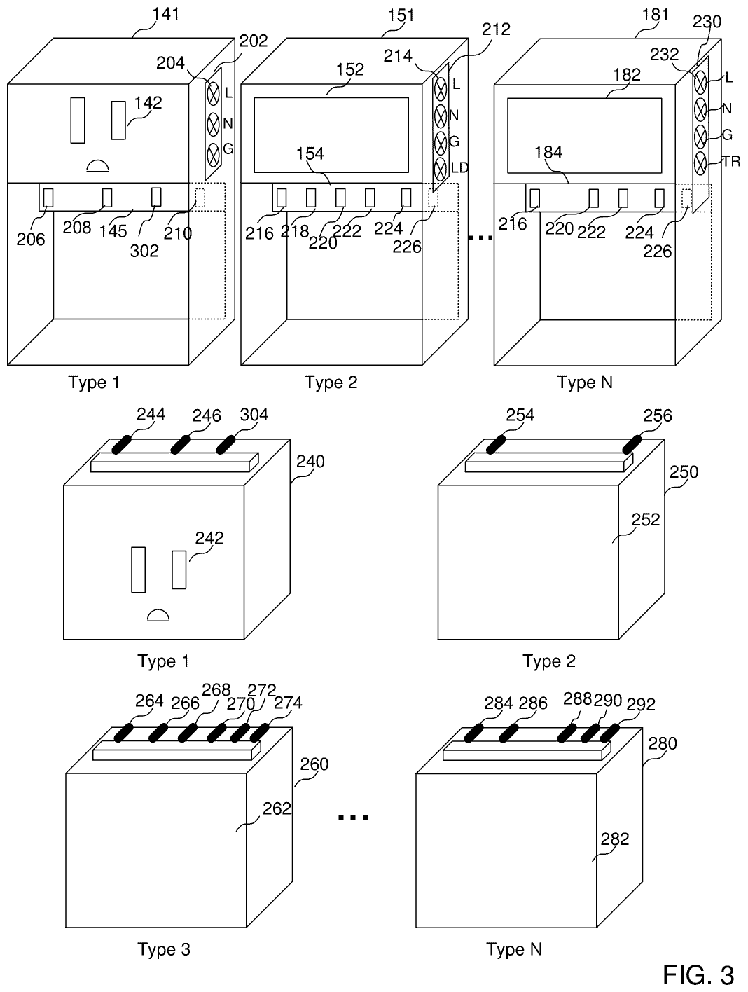

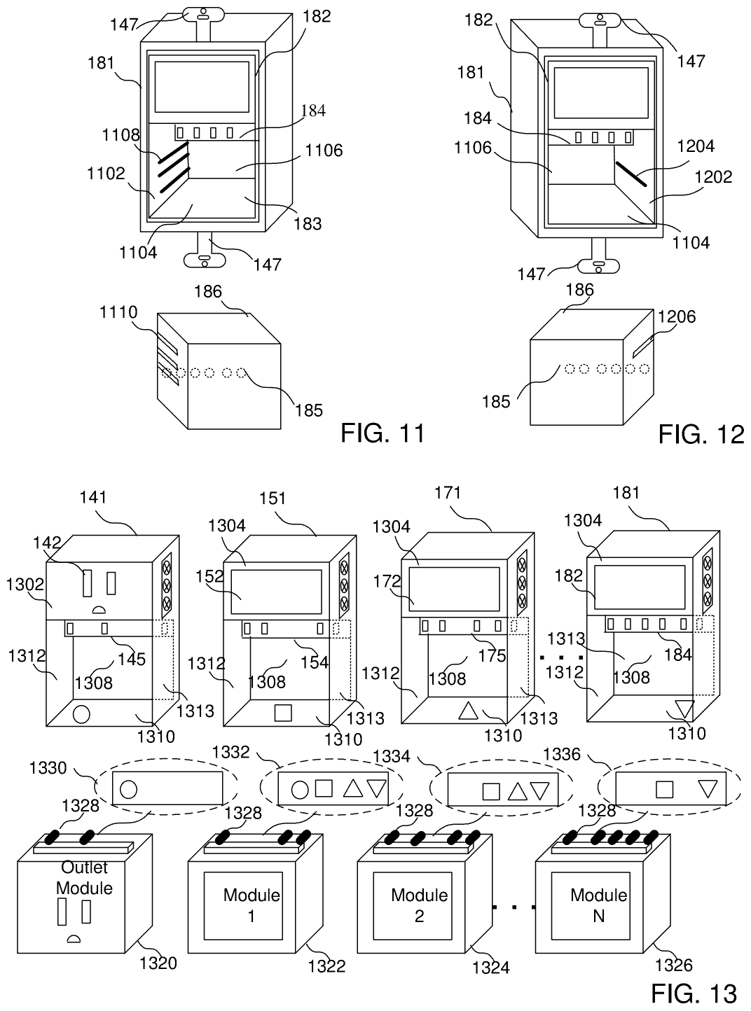

FIGS. 2-13 are directed to different ways that power adapters can be configured to receive or block modules, as well as the use of visual aids for enabling a user to place a module in a power adapter. According to some implementations, the location of contact elements of a power adapter can be used to enable or block a module from being placed in a power adapter. That is, the location of contact elements of the power adapter and the modules can be used as alignment elements to enable or block a given module from being inserted into a given power adapter. For example, FIGS. 3-10 are directed to various implementations of contact elements of the different power adapters and modules, where the contact elements may be used to enable or block a given module from being inserted into a given power adapter. According to other implementations, alignment elements separate from the contact elements could be used to enable or block a given module from being inserted into a given power adapter. For example, FIGS. 11-12 disclose an example of the use of alignment elements separate from the contact elements. According to other implementations, visual aids could be used to enable a user to insert a module into a compatible power adapter. For example, FIG. 13 is directed to the use of icons, colors, and/or shapes to enable a user to place a module into a compatible power adapter.

A first type of compatible power adapter could be a power adapter that is able to receive a module. A second type of compatible power adapter could be a power adapter that is able to receive a module which is able to operate in the power adapter. More particularly, a module may be compatible with a power adapter if the module is one or both of mechanically compatible (i.e., the module is able to be attached to a power adapter) and electrically mechanical (i.e., one or more contact elements of the module makes an electrical connection with one or more contact elements and is able to perform at least one function of the module). A module that is not mechanically compatible would not be electrically compatible. It should be understood that a module that is electrically compatible with a power adapter may have a greater or lesser number of contact elements than the number of contact elements of the power adapter. That is, not all of the contact elements of a module that is electrically compatible with a power adapter may be connected to corresponding contact elements of the power adapter. Alternatively, a module may have a greater number of contact elements than the number of contact elements of the power adapter, but one or more contact elements of the module that are electrically connected to corresponding contact elements of a power adapter may enable the module to implement one or more functions of the control module. As will be described in more detail below, a contact element that is not electrically coupled to a contact element of the power adapter may be received by a recess of the power adapter that allows the module to be inserted into a power adapter (i.e., the module would not be prevented from being inserted into the power adapter even though the power adapter does not have a corresponding contact element).

According to some implementations, a module that is mechanically compatible with a power adapter may not be electrically compatible with the power adapter. For example, the module may be received in a power adapter, but may not receive power and therefore would not be able to operate. It should be understood that the electrical and mechanical options for enabling a user to use certain modules in certain power adapters could be used alone or in combination. For example, a variety of electrical and mechanical implementations could be used to achieve or prevent compatibility between power adapters and modules. While alignment elements of power adapters and modules may affect the mechanical compatibility of a module and a power adapter, contact elements may also affect the electrical compatibility of a module and a power adapter, wherein one or more contact elements of a module may also affect mechanical compatibility. That is, a contact element of a module may prevent the module from being inserted into a power adapter, as will be described in more detail below.

According to another beneficial aspect of the use of both alignment elements and the placement of contact elements is that it may be possible to eliminate alignment elements in future generation implementations. While the use of alignment elements separate from contact elements may be beneficial, it may be beneficial to allow a module to be inserted into all power adapters. It may be possible to selectively place contact elements to enable mechanical compatibility but prevent electrical compatibility for some or all of the features of a module, as will be described in more detail below.

Turning now to FIG. 2, a block diagram of a plurality of power adapters and a plurality of modules according to one implementation is shown. The plurality of power adapters may have different types of contact elements, and therefore may have different contact arrangements, shown here by way of example as having different external contact elements and contact elements in the recess. The plurality of modules may also comprise different types of modules having different arrangements of contact elements. A given module may be either mechanically incompatible with certain power adapters, because of the placement of contact elements or the use of alignment elements, or may be electrically incompatible with certain power adapters based upon the location of contact elements of the power adapter or contact elements of the module, or both. In some cases, one or more power adapters may be a part of a category of power adapters, and or one or more modules may be a part of a category of modules.

According to the implementations of FIGS. 3-6, the arrangement of contact elements of the power adapter may be used to provide mechanical incompatibility, electrical incompatibility, or both mechanical and electrical incompatibility. One type of power adapter may comprise an outlet power adapter, and the remaining Type 2 through Type N power adapters may comprise switch power adapters. For example, the switch power adapters may include single pole switch power adapters and multiway switch power adapters, including for primary switch power adapters and companion switch power adapters. While only one type of outlet power adapter is shown, it should be understood that different outlet power adapters could be used, including power adapters that provide tamper resistance, wirelessly controlled outlets, arc fault circuit interrupter (AFCI) or ground fault circuit interrupter (GFCI) protection for example. According to some implementations, contact elements can be used as alignment elements. If there is no opening in a power adapter that corresponds to the contact elements of the module, regardless of whether a corresponding contact element of the power adapter is present behind the opening to receive a contact element of a module, the module will not be able to be inserted into the power adapter.

A first type of power adapter of the plurality of power adapters of FIG. 2 comprises the power adapter 141 having an outlet 142 comprising a plurality of contact elements 202 having contact elements 204. The contact elements 204 are shown here by way of example as screw terminal, but could be any type of contact elements, such as wires or friction contact elements accessible through openings that are adapted to receive and secure a wire of the junction box. The plurality of contact elements include line, neutral and ground contact elements for example, but could include other contact elements to enable the outlet to be wired as a switched outlet. That is, the line contact element and the neutral contact element could each comprise two contact elements to enable providing a separate line voltage connection to the outlet 142 and a module in the recess 143, and a separate neutral connection to the outlet 142 and the module in recess 143. The electrical interface 145 comprises a plurality of openings, shown by way of example as openings 206, 208 and 210. The electrical interface 145 may include contact elements for receiving corresponding contact elements of a module which may be behind some or all of the openings, and which may be connected to contact elements of the plurality of contact elements 202. An insulating receiving element may be located behind an opening of the electrical interface 145 not having a contact element to enable the power adapter to receive a module having a contact element at a particular location, but not make an electrical connection to that contact element of the module, as will be described in more detail below.

A second type of power adapter of the plurality of power adapters of FIG. 2 comprises a power adapter 151 having a switch 152. The power adapter 151 has a plurality of contact elements 212 comprising contact elements 214, shown here by way of example as a line (L) contact module, a neutral (N) contact element, a ground (G) contact element, and a load (LD) contact element. The electrical interface 154 comprises a plurality of openings, including a first opening 216, a second opening 218, a third opening 220, a fourth opening 222, a fifth opening 224, a sixth opening 226, and a seventh opening 228. As with the power adapter 141, the electrical interface 154 may include contact elements for receiving corresponding contact elements of a module behind some or all of the openings. An insulating receiving element may be located behind an opening not having a contact element to enable the power adapter to receive a module having a contact element at the particular location of the insulating receiving element, but not make an electrical connection to the contact element of the module.

A third type of power adapter of the plurality of power adapters of FIG. 2 comprises a power adapter 181 having a switch 182 and a plurality of contact elements 230 comprising contact elements 232, shown here by way of example as a line (LN) contact element, a neutral (N) contact element, a ground (G) contact element, and traveler (TR) contact element. As with the power adapters 141 and 151, the electrical interface 184 may include contact elements for receiving one or more corresponding contact elements of a module behind some or all of the openings. An insulating receiving element may be located behind an opening not having a contact element to enable the power adapter to receive a module having a contact element at a particular location, but not make an electrical connection to that contact element of the module.

The N types of power adapters may also comprise the power adapter 171 of FIG. 1, or other types of switch power adapters. Although the plurality of power adapters may comprise N types, they may comprise fewer than N categories or more than N categories. For example, two categories of power adapters may include outlet power adapters and switch power adapters. The switch power adapters may include categories of load switching power adapters (i.e., power adapters coupled to a load and configured to control power to a load), such as a single pole power adapter or a primary power adapter of a multiway switch, and signaling power adapters, such as a companion power adapter used in a multiway switching arrangement. Different combinations of the power adapters may result in more than N categories.

A first type of module of the plurality of modules of FIG. 2 comprises an outlet 242 on a front face of the module 240 and comprises contact elements 244, 246, and 248 which may comprise neutral, ground, and line contact elements and may be adapted to be received by corresponding contact elements of a power adapter. While no other elements are shown on the face of the outlet module 240, it should be understood that other elements, such as electrical interface elements or user interface elements, could be implemented on the face of the outlet module. Electrical interface elements may comprise a USB port for charging, a USB port for charging and data, a sensor, or a camera for example. Sensors could include for example any sensor that may be used in the control of the power adapter or may provide a sensor output to another system, such as an HVAC system. By way of example, a module may comprise a light sensor, motion sensor, microphone, a temperature sensor, humidity sensor, air quality sensor, or any other sensor that could provide information to the module or to a remote system. User interface elements may comprise for example, a button for controlling the application of power to the outlet 242, or any other element for controlling the outlet or any function of the outlet. Any of the modules may comprise internal circuits for providing additional functionality, such as one or more wireless communication circuits. The wireless communication circuit could include one or more of cellular, WiFI, Z-Wave, Zigbee, Bluetooth, Thread, or NFC circuits, for example, or circuits for implementing any other communication protocol, including propriety communication protocols.

A second type of module 250 of the plurality of modules of FIG. 2 comprises a front face 252 which may comprise electrical interface elements or user interface elements and may also comprise one or more wireless communications circuits. The plurality of contact elements may comprise a neutral contact element 254 and a line contact element 256.

A third type of module 260 of the plurality of modules of FIG. 2 comprises a front face 262 which may comprise electrical interface elements or user interface elements and may also comprise one or more wireless communications circuits. The plurality of contact elements may comprise contact elements 264, 266, 268, 270, 272, and 274, which may include a neutral contact element 264 and a line contact element 274.

The Nth type of module 280 of the plurality of modules of FIG. 2 comprises a front face 282 which may comprise electrical interface elements or user interface elements and may also comprise one or more wireless communications circuits. The plurality of contact elements may comprise contact elements 284, 286, 288, 290, and 292, which may comprise a neutral contact element 284 and a line contact element 292.

The second through Nth modules are shown by way of example as being modules having different functionality and interfaces and having different contact elements for being coupled to the plurality of contact elements of the power adapters. As described above with respect to the plurality of power adapters, the plurality of modules may also be associated with fewer than N categories or more than N categories. According to some implementations, the modules may include a category of passive modules (i.e., modules such as the Type 2 module that only receives power and neutral and therefore is not involved in any switching aspect of a switch power adapter). Another category of modules may include switching modules that route a line voltage to the power adapter, and therefore control the application of power to the load. Different dimmer modules may also fall into different categories, including those that perform a dimming function within the module (i.e., in a primary power adapter) and those that provide a dimming control signal (i.e., a module in a companion power adapter) to a dimming module that performs a dimming function within the module. Depending upon the functionality of the module, the modules may have a different number of contact elements, as shown.

The contact elements may act as alignment elements, where certain modules may have contact elements that would not be received by a corresponding contact element of the power adapters. For example, the power adapter 141 having an outlet could only receive the Type 1 and Type 2 modules, but not the Type 3 and Type N modules as shown. However, the power adapter 151 could receive any of the modules because it has openings to receive any of the contact elements of any of the modules shown.

More particularly, contact element 244, contact element 246, and contact element 248 of module 240 would align with opening 206, opening 208, and opening 210, respectively, and make electrical connections to contact elements behind the openings. The module 250 would also be able to be attached to the power adapter 141, where contact element 254 and contact element 256 of module 250 would align with opening 206 and opening 210, respectively, and make electrical connections to contact element behind the openings. The modules 240 and 250 would also be able to be attached to power adapters 151 and 181. That is, the contact elements 244, 246 and 248 could be electrically coupled to contact elements behind the openings 216, 220 and 228 of the power adapter 151 and the power adapter 181. Similarly, the contact elements 254 and 256 of module 250 could be electrically coupled to contact elements behind the openings 216 and 228 of the power adapter 151 and the power adapter 181.

The module 260 comprises a plurality of contact elements including a contact element 264 that is adapted to be received by opening 216 of power adapter 151, a contact element 266 that is adapted to be received by opening 218, a contact element 268 that is adapted to be received by opening 220, a contact element 270 that is adapted to be received by opening 224, a contact element 272 that is adapted to be received by opening 226, and a contact element 274 that is adapted to be received by opening 228. However, module 260 has a greater number of contact elements than openings of the electrical interface 184 of power adapter 181, and would therefore not be able to be inserted into power adapter 181.

The module 280 comprises a contact element 284, a contact element 286, a contact element 288, a contact element 290, and a contact element 292 that are configured to align with the openings 216, 218, 224, 226, and 228, Therefore, the module 280 can be inserted into the power adapter 151, but cannot be inserted into the power adapter 181 because power adapter 181 does not have an opening 218 to receive contact element 286. Further, because the module 260 and the module 280 each comprise a greater number of contact elements than openings of the power adapter 141, the module 260 and the module 280 would not be able to be inserted in the power adapter 141. By way of example, modules 260 and 280 may be modules that are intended to be used to control power to a light by way of a switch power adapter.

By selectively placing openings and contact elements in the modules, it may be possible to change the mechanical or electrical interchangeability of the power adapters and modules to achieve a desired interchangeability, as will be described in more detail in reference to FIGS. 3-6.

Turning first to FIG. 3, a block diagram of a plurality of power adapters and modules according to another implementation is shown. According to the implementation of FIG. 3, an opening 302 of the power adapter 141 having an outlet for providing access to a contact element having the line voltage may be added, and the contact element of a module having an outlet may only have a contact element 304 adapted to extend into the opening 302, and not a contact element for receiving the line voltage from a contact element behind opening 302. However, the outlet module 240 of FIG. 3 would not have the contact element 248 of FIG. 2 that would receive the line voltage from a contact element behind the opening 210. By retaining the opening 210 and a contact element behind the opening 210 for providing the line voltage to the other modules, the addition of the contact element receiving the line voltage behind opening 302 will enable the power adapter 141 having an outlet to receive the outlet module 240. However, as can be seen, neither of the power adapter 151 and power adapter 181 having a switch comprise an opening in the location of opening 302 of the outlet power adapter, and therefore the switch power adapters cannot receive the outlet module 240. That is, the absence of an opening 302 in the power adapters 151 and 181 of FIG. 3 would prevent the outlet module 240 of FIG. 3 from being inserted to the switch power adapter. Therefore, the placement of contact elements associated with a reference voltage can determine the types of power adapter that may receive certain modules. However, because the outlet power adapter also includes the contact element at opening 210, the other modules that have a contact element that would be received by the opening 210 could receive the line voltage. In the example of FIG. 3, module 250 would be able to be received by the power adapter 141 and receive power by way of access to a line contact element through the opening 210, and would not have contact elements that would otherwise prevent the module 250 from being inserted into the recess of the power adapter 141. In contrast, modules 260 and 280 would have contact elements that would prevent it from being received by the power adapter 141 as described above in reference to FIG. 2.

According to the implementation of FIG. 3, there may be 4 module types, 3 module categories, and 2 types of switch electrical interfaces (e.g., Type 1—load side (e.g. a primary switch power adapter) and Type 2—remote (a companion switch power adapter)). Module types may include for example: 1. Outlet, 2. Non-switching module, 3. Switching module, and 4. Companion communication module. 3 module categories may include for example: 1. Outlet, 2. Switching (actual switching or signaling), and 3. Passive. The 2 types of switch electrical interfaces may include for example: 1. load side (single pole or 3-way) and 2. companion in multi-way wiring arrangement.

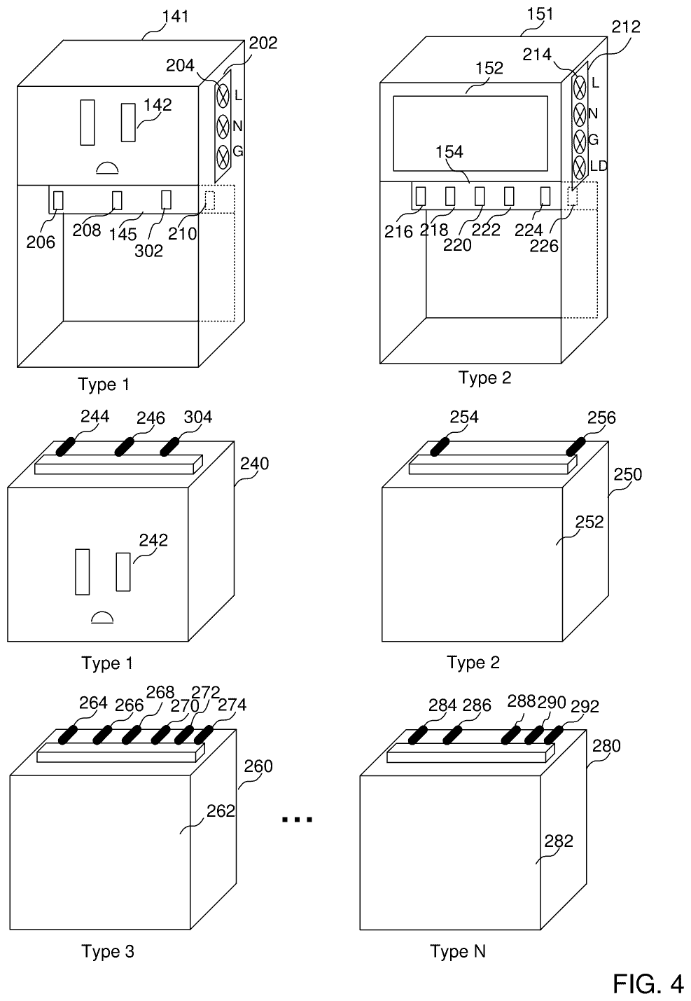

Turning now to FIG. 4, a block diagram of a plurality of power adapters and modules according to another implementation is shown. By providing a single arrangement of openings of the electrical interface of the switch power adapters (i.e., electrical interface 154), the switch power adapters may receive the same power adapters. However, it should be understood that electrical interfaces 154 of the switch power adapters may comprise different contact elements behind the openings of the electrical interface. For example, power adapter 151 implemented as a single pole power adapter, primary multiway power adapter, or companion power adapter may comprise different arrangements of contact elements behind the opening of the electrical interface 154 as shown in FIG. 3. According to the implementation of FIG. 4, modules having outlets, would only be able to be placed in the power adapter 141 having an outlet. The outlet module 240 would not be able to be placed in a switch power adapter because there would be no opening in the electrical interface 154 for receiving the contact element 304. However, the switch power adapters would be able to receive all other modules. It should be noted that the functionality of some modules may be limited in some of the switch power adapters. For example, a module that has switching capability may be used in a companion type switch power adapter, but it would not perform any switching of power to a load, rather only transferring signals that may control the switching of power, such as to a primary switch power adapter or a module in a primary switch power adapter.

According to FIG. 4, there may be 4 module types, 3 module categories, and 2 types of electrical interface openings. The module types may include for example: 1. Outlet, 2. Non-switching module, 3. Switching module, and 4. Companion communication module. The module categories may include for example: 1. Outlet, 2. Switching (actual switching or signaling), and 3. Passive. There may be 1 type of openings for switch electrical interfaces, where the switch electrical interfaces may comprise different contact elements behind the 1 type of electrical interface openings.

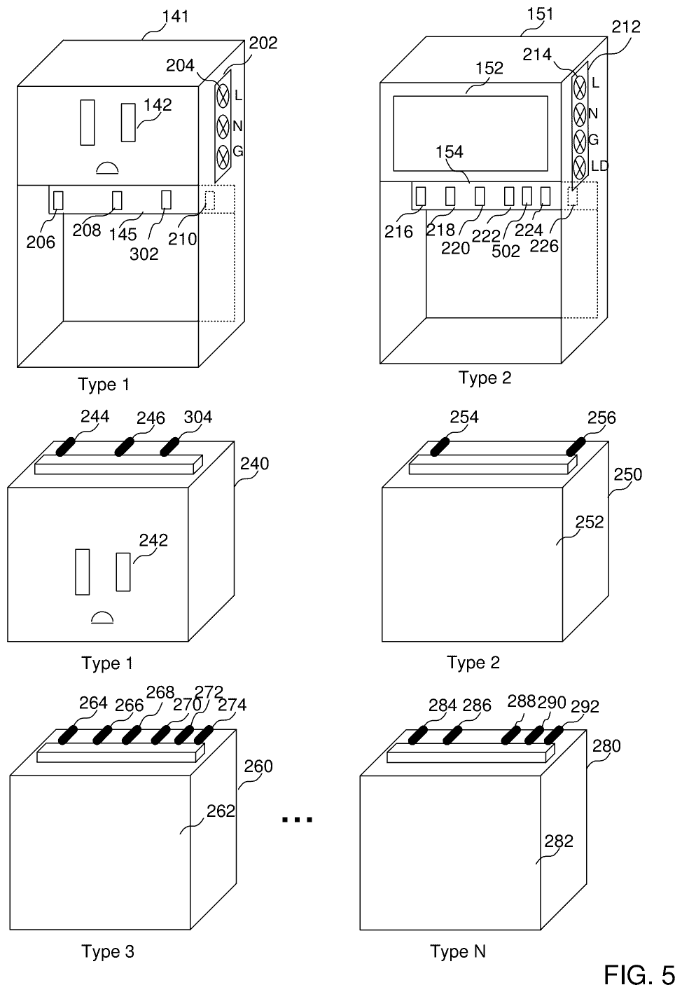

Turning now to FIG. 5, a block diagram of a plurality of power adapters and modules according to another implementation is shown. By adding an opening 502 to the power adapter 151, the power adapter 151 having a switch will be able to receive a module having a contact element 304, such as outlet module 240. However, the outlet module 240 will not receive power unless there is a contact element having the line voltage for example behind the opening 502. That is, the addition of the opening 502 would enable all of the modules to be inserted into the power adapter 151, but only some of the modules to be able to be inserted into the power adapter 141.

According to the implementation of FIG. 5, there may be 4 module types, 2 module categories, and 2 types of electrical interface openings. The module types may include: 1. Outlet, 2. Non-switching module, 3. Active Switching module, and 4. Companion communication module that may send switching signals. There may be 2 module categories including: 1. Outlet, 2. All other (e.g., switching (active switching or one that sends switching signals) and passive). One type of openings for the switch electrical interfaces is shown, where the openings of the switch electrical interface are different than the openings of the switch electrical interface of FIG. 4. That is, as described above in reference to FIG. 4, the switch electrical interfaces may comprise different contact elements behind the 1 type of electrical interface openings.

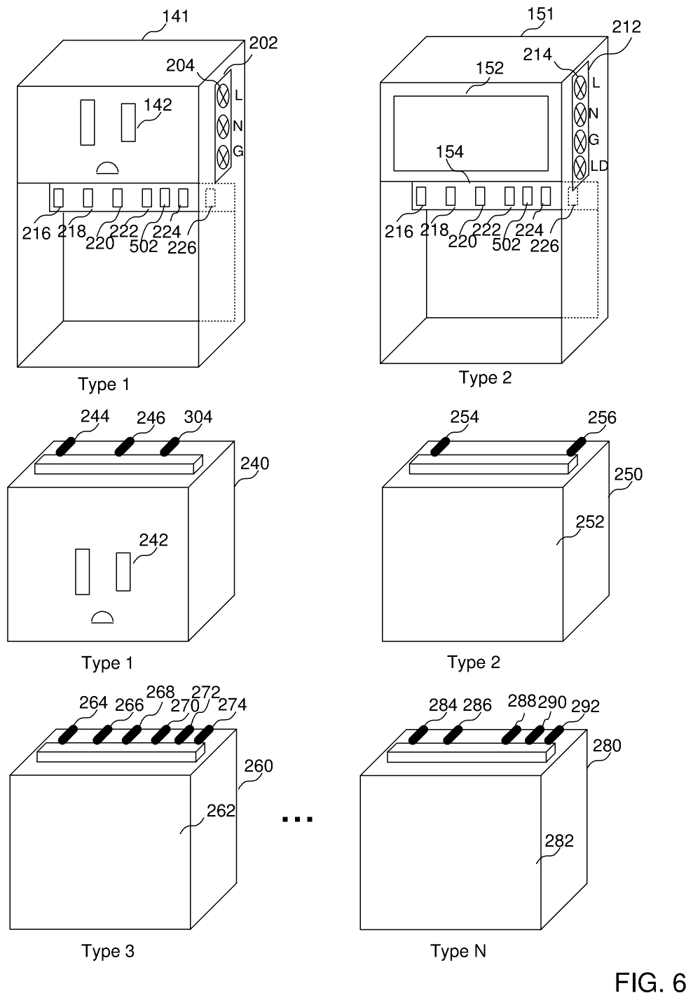

Turning now to FIG. 6, a block diagram of a plurality of power adapters and modules according to another implementation is shown. According to the implementation of FIG. 6, the power adapter 141 is provided with an electrical interface having the same openings as provided for the power adapter 151. While all of the power adapters may receive any module, only some or all of the functionality may be available for some modules depending on the placement of contact elements behind the openings.

According to the implementation of FIG. 6, there may be 4 module types, 1 module categories, and 1 type of electrical interface openings. Module types may include: 1. Outlet, 2. Non-switching module, 3. Switching module, and 4. Companion communication module. There may be 1 module category, where all modules may be attached to each of the power adapters (i.e., mechanically fit), but may or may not be electrically compatible, and 1 type of switch electrical interface openings.

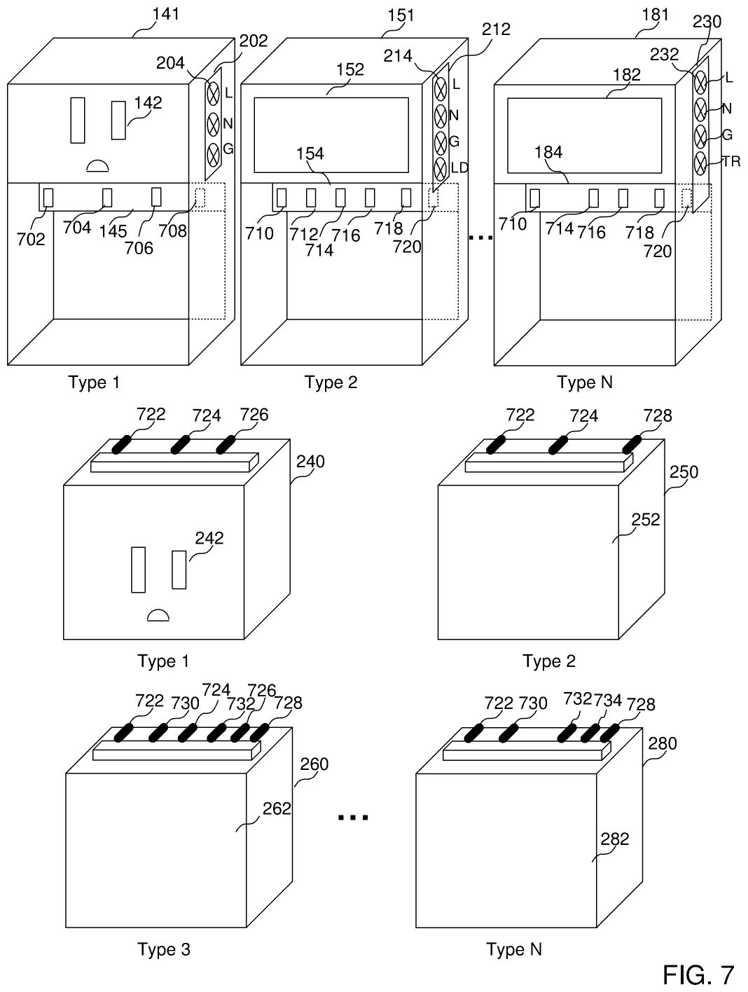

According to another implementation, rather than providing an additional contact element coupled to line in the power adapter 141 having an outlet, it may be beneficial to place the contact element of the power adapter 141 having an outlet that provides the line voltage to modules at a different location, as will be described in reference to FIGS. 7-10.

Turning first to FIG. 7, a block diagram of a plurality of power adapters and modules according to another implementation is shown. According to the implementation of FIG. 7, the electrical interface 145 of the power adapter 141 comprises a first opening 702, a second opening 704, third opening 706, and a fourth opening 708. According to some implementations, there would be contact elements behind the openings 702, 704 and 706 for receiving the neutral, ground and line voltages, respectively. It should be noted that there would be no contact element behind opening 708 according to the implementation of FIG. 7, and any module that would be electrically compatible with power adapter 141 having an outlet would have to have a contact element 726 that would align with the opening 706 and the contact element behind the opening 706 adapted to receive the line voltage. Therefore, only modules having a contact element that is adapted to align with the opening 706 would receive power. For example, the outlet module 240 of FIG. 7 could be received by the power adapter 141 and receive the line voltage, but the module 250 could be received by the power adapter 141 but would not receive the line voltage. That is, the module 250 does not comprise a contact element that would align with the opening 706 and the contact element behind the opening 706 to receive the line voltage from the contact element behind the opening 706.

The electrical interface 154 of the power adapter 151 may comprise a first opening 710, a second opening 712, a third opening 714, a fourth opening 716, a fifth opening 718, and a sixth opening 720. As can be seen, the electrical interface 184 of the power adapter 181 comprises the same openings as the electrical interface 154 except for the second opening 712, which is in electrical interface 154 but not in electrical interface 184. It should be noted that the openings of the electrical interfaces 154 and 184 of FIG. 7 are similar to the openings of the electrical interfaces 154 and 184 of FIG. 3 as described above,

The outlet module 240 of FIG. 7 comprises contact elements 722, 724 and 726 for receiving the neutral, ground and line voltages respectively from contact elements behind openings 702, 704 and 706. The module 250 comprises contact elements 722 and 724. But rather than having a contact element 726 at the location shown in module 240, a contact element 728 is provided to receive a line voltage. Accordingly, the module 250 will not receive the line voltage when inserted into the power adapter 141 but will receive the line voltage from a contact element behind the opening 720 in the power adapter 151 and the power adapter 181. The module 260 comprises contact elements 722, 724 726 and 728. Therefore, it would receive the line voltage from any of the power adapters. That is, module 260 comprises the contact element 726 adapted to receive the line voltage from a contact element behind opening 706 when the module 260 is attached to the power adapter 141 and also comprises the contact element 728 to receive the line voltage from the contact element behind the opening 720 when the module 260 is inserted into the power adapter 151 and 181. It also comprises contact elements 730 and 732, which may be used for routing signals, including power signals or communication signals, for example, to implement the power adapter arrangements as described in reference to FIGS. 22-47, for example, or other wiring arrangements of power adapters. The module 280 comprises contact element 728 (and not contact element 726), and therefore will only receive the line voltage from a contact element behind the opening 720 in the power adapter 151 and the power adapter 181 (and not from a contact behind opening 708 of power adapter 141). The module 280 also comprises contact elements 730 and 732, but also comprises a contact element 734 which may also be used for routing signals, including power signals or communication signal for example.

According to some implementations, contact element 722, contact element 724, and contact element 726 of module 240 may align with opening 702, opening 704, and opening 706, respectively, and make electrical connections to contact element behind the openings. The module 250 would also be able to be attached to the power adapter 141, where contact element 722, contact element 724 and contact element 728 of module 250 would align with opening 702, opening 704 and opening 708, respectively, and make electrical connections to two of the contact elements behind the openings. Unlike module 240 which would receive the line voltage from the contact element behind the opening 706, module 250 does not include the contact element 726 and would therefore not receive the line voltage from a contact element behind the opening 706. Although the module 250 comprises a contact element 728 adapted to receive the line voltage, it would not receive the line voltage because there is no contact element behind the opening 708 according to the implementation of FIG. 7. That is, module 250 may be mechanically compatible with power adapter 141, but not electrically compatible.

The module 240 would not be able to be attached to power adapters 151 and 181 because there is no opening 706 in either of the power adapters 151 and 181 to receive the contact element 726. While Module 250 could be received by the power adapter 141 but not receive power, it could be received by the power adapters 151 and 181 and receive power by way of a contact element behind the opening 720. That is, the contact element 728 would be electrically connected to a contact element that receives the line voltage and is accessible behind the opening 720.

The module 260 comprises a plurality of contact elements including a contact element 722 that is adapted to be received by opening 710, a contact element 730 that is adapted to be received by opening 712, the contact element 724 that is adapted to be received by opening 714, a contact element 732 that is adapted to be received by opening 716, a contact element 726 that is adapted to be received by opening 718, and a contact element 728 that is adapted to be received by opening 720. However, module 260 has a greater number of contact elements than openings of the electrical interface 184 of power adapter 181 of FIG. 7, and would therefore not be able to be inserted into power adapter 181.

The module 280 comprises contact element 722, contact element 732, a contact element 734, and contact element 728 that are configured to align with the openings 710, 714, 718, and 720, Therefore, the module 280 can be inserted into the power adapter 151, but cannot be inserted into the power adapter 181 because power adapter 181 does not have an opening 712 to receive contact element 730. Further, because the module 260 and the module 280 comprise a greater number of contact elements than openings of the power adapter 141, the module 260 and the module 280 would not be able to be inserted in the power adapter 141. By way of example, modules 260 and 280 of FIG. 7 may be modules that are intended to be used to control power to a light by way of a switch power adapter.

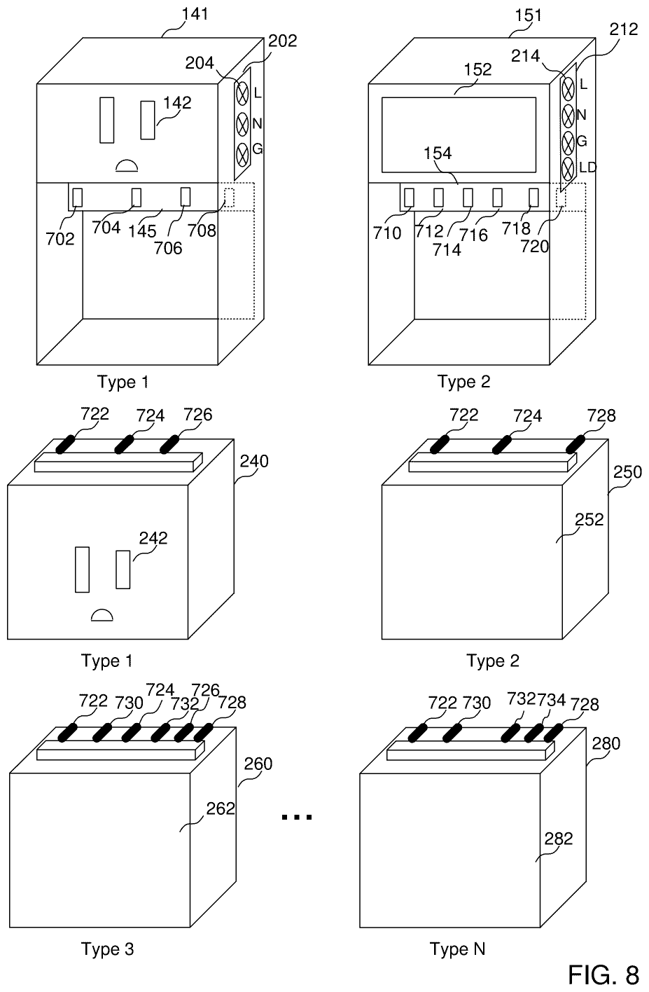

Turning now to FIG. 8, a block diagram of a plurality of power adapters and modules according to another implementation is shown. As shown in FIG. 8, a common arrangement of openings of an electrical interface is provided for switch power adapters. That is, even if different switch power adapters have different arrangements of contact elements behind the openings and provide different functionality, they would be able to receive the same modules, such as described above in reference to FIG. 4. While some or all of the functionality of a given module may not be available when inserted into a certain power adapter, the module can be received by all of the switch power adapters. For example, a primary power adapter and a companion power adapter may be able to receive the same modules but, depending upon the arrangement of contact elements behind the openings of the power adapters, the modules may provide different functionality. For example, a module having dimming capability or a module having a motion sensor may perform a function of switching power to a load when in a primary power adapter in a multiway wiring arrangement, but may only provide a control signal related to dimming or motion when the module is used in a companion power adapter in the multiway wiring arrangement.

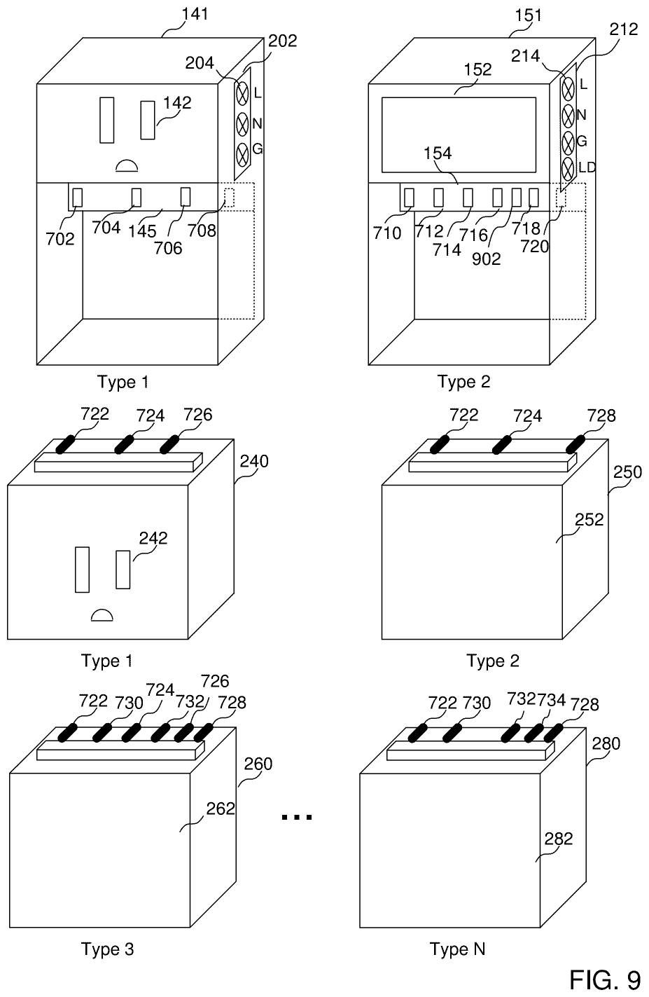

Turning now to FIG. 9, a block diagram of a plurality of power adapters and modules according to another implementation is shown. As shown in FIG. 9, an opening 902 can be provided in the electrical interface 154 (at the location of the opening 706 of the power adapter 141) to enable the switch power adapters to receive the outlet module 240, such as described above in relation to FIG. 5. If a contact element having the line voltage is not provided behind the opening 902, the outlet module would not receive power, and therefore not be able to provide power to a load plugged in to the outlet module 240. That is, the arrangement of openings of the electrical interface 154 enables mechanical compatibility of module 240 and the power adapter 151 of FIG. 9, but does not provide electrical compatibility.

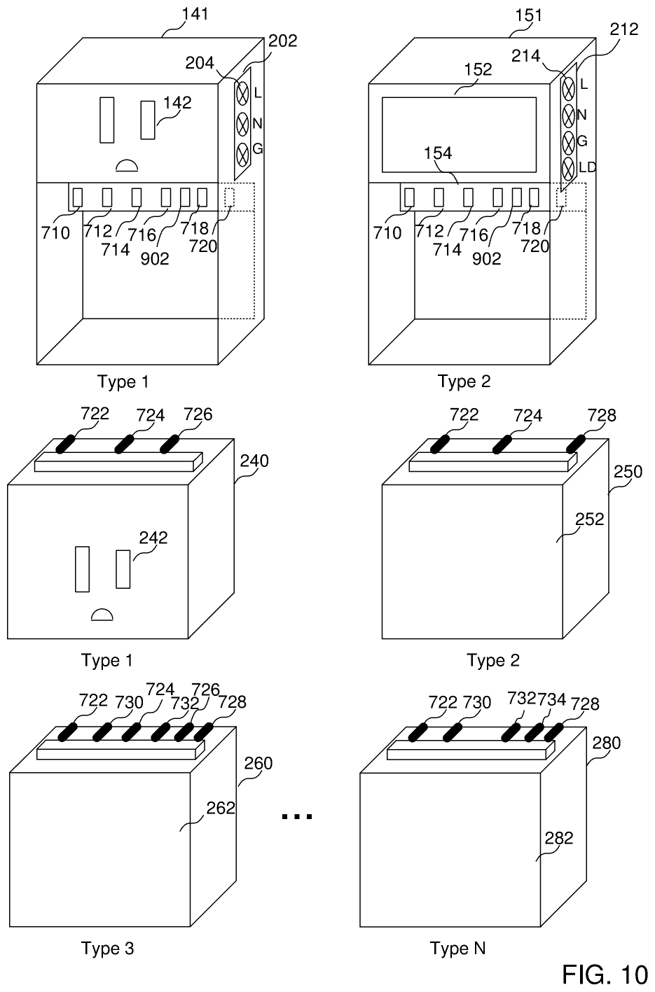

Turning now to FIG. 10, a block diagram of a plurality of power adapters and modules according to another implementation is shown. As shown in FIG. 10, the electrical interfaces have the same arrangement of openings to achieve mechanical interchangeability of modules, such as describe above in reference to FIG. 6. That is, unless alignment elements, such as the alignment elements of FIGS. 11 and 12, are used, each of the power adapters of FIG. 10 may be able to receive each of the modules. However, the arrangement of contact elements behind the opening can be selected to determine electrical compatibility of the different power adapters and modules. By way of example, a load contact element (adapted to be coupled to a load contact element of a module) may not be provided behind an opening of an electrical interface that may receive a load contact element because the power adapter (e.g., a companion power adapter) may not have a load contact element adapted to receive a wire of a junction box adapted to be coupled to a load, such as a light. As will be described in more detail below, alignment elements could initially be provided to enable or block certain modules from being inserted into certain power adapters, but later removed for backward compatibility of modules sold in the future if it becomes desirable to have each of the modules be mechanically compatible with each power adapter.

According to one implementation, an in-wall power adapter configured to receive a module may comprise a first plurality of contact elements adapted to be coupled to wires of a junction box, wherein the first plurality of contact elements comprises a first contact element adapted to receive a line voltage and a second contact element adapted to receive a neutral voltage; and a second plurality of contact elements adapted to be coupled to a module, wherein the second plurality of contact elements comprises a third contact element adapted to receive the line voltage and a fourth contact element adapted to receive the neutral voltage; wherein the third contact element is positioned to receive a line contact element of a first module of a plurality of modules of a system comprising the in-wall power adapter; and wherein the third contact element is not positioned to receive a line contact element of a second module of the plurality of modules.

According to another implementation, an in-wall power adapter configured to receive a module may comprise a first plurality of contact elements adapted to be coupled to wires of a junction box, wherein the first plurality of contact elements comprises a first contact element adapted to receive a line voltage and a second contact element adapted to receive a neutral voltage; and a second plurality of contact elements adapted to be coupled to a module, wherein the second plurality of contact elements comprises a third contact element adapted to receive the line voltage, a fourth contact element adapted to receive the line voltage, and a fifth contact element adapted to receive the neutral voltage; wherein the third contact element is positioned to receive a line contact element of a first module of a plurality of modules of a system comprising the in-wall power adapter; and wherein the fourth contact element is positioned to receive a line contact element of a second module of the plurality of modules.

Turning now to FIGS. 11 and 12, block diagrams of a power adapter arrangement show alignment elements along a first side of a recess in FIG. 11 and a second side of a recess in FIG. 12. The use of alignment elements may not only block or prevent a module from being inserted into a recess of a power adapter but may also help align the module to the power adapter when one or more alignment elements are present. The alignment elements could include any type of element of a module or a power adapter, and in some cases corresponding elements of a power adapter and a module, for preventing a module from being inserted into or attached to the power adapter. An alignment element could comprise a projection, a flange, a tab, a latch, a rail for aligning with a track, a track for receiving a rail, or any other element or combination of elements for blocking or preventing a module from being inserted into a power adapter. Multiple alignment elements could be used. The one or more alignment elements can be placed at different locations of the modules and power adapters. The use and placement of alignment elements can be at certain locations to create types and categories of modules and power adapters, as will be described in more detail below.

More particularly, the arrangement of alignment elements may comprise rails on one of a power adapter and a module, and a corresponding track or recess for receiving the rails on the other of the power adapter and the module, for example. The recess 183 of the power adapter 181 comprises a side wall 1102, a bottom wall 1104, a side wall 1202, and a rear wall 1106, as shown in FIGS. 11 and 12. The power adapter may comprise a first alignment element 1108, shown here by way of example as rails on the side wall 1102. The rails are adapted to mate with corresponding alignment elements 1110, shown here by way of example as tracks or recess guides adapted to mate with rails of the power adapter. The alignment elements may also comprise an alignment element 1204 of the power adapter adapted to mate with the alignment element 1206 of the module.

While the alignment elements are shown on two side walls, it should be understood that any combination of alignment elements on any of the walls of the recess could be implemented. It should also be understood that alignment elements, such as the alignment elements of FIGS. 11 and 12, could be implemented in addition to power adapters and modules having contact elements that would allow a module to be inserted or block a module from being inserted into a given power adapter. That is, both the placement of contact elements and the use of alignment elements can be used to allow or block the insertion of a module into a power adapter. However, it should also be understood that by making the locations of openings of electrical interfaces of power adapters the same in all power adapters, it is possible to allow a module to be inserted or block a module from being inserted into a given power adapter and later allow any module to be inserted in a power adapter if the alignment elements are removed from the power adapter. Some or all of the functionality of certain modules may not be available in certain power adapters, but the module would still be received by the power adapter. For example, a module with an outlet could be received by a switch power adapter but would never receive power to enable the outlet module to provide power to a load through the outlet module based upon the selection of contact elements behind the openings of the electrical interface of the power adapter, such as a switch power adapter. The power adapters of FIG. 1 and shown in more detail in reference to FIGS. 2-12 may be configured to implement the arrangements of power adapters of FIGS. 22-47, for example, or other wiring arrangements of power adapters.

Turning now to FIG. 13, a block diagram of a plurality of power adapters and modules having visual aids for matching modules to power adapters that are capable of operating with certain modules is shown. In a modular system for wiring devices (e.g., switches and outlets), there may be multiple different types of power adapters. In addition to an outlet power adapter, there may be different types of switch power adapters, for example a single pole power adapter, and primary and companion switch power adapters for a multiway system, as described above in reference to FIG. 1.

In some implementations, a given module may not function in a given power adapter. In some implementations, a module that may not function in a given power adapter may be prevented from being inserted into that power adapter. Regardless of whether a module may be prevented from being inserted into a given power adapter, it may be beneficial to a homeowner if an indication of whether a given module can be inserted into a given power adapter is provided. According to some implementations, each type of power adapter could have a separate designation indicating the type of power adapter that would be apparent to a user, and particularly when a wall plate is attached. For example, there could be 4 designations of the 4 types of power adapters described above in reference to FIG. 1. According to some implementations, there could be fewer designations for the types of power adapters, where one designation may be used for two different types of power adapters. According to some implementations, a power adapter may have multiple designations. Each module may also have one or more designations. The designation may be provided on any surface of a power adapter, and preferably may be visible when a faceplate is attached to the outlet power adapter or switch power adapter. The designation can include colors, shapes, icons, or any other designation for a power adapter or group of power adapters. The designation could include a combination of colors, shapes, icons, and words. The designation can include something attached to the power adapter or module, such as a sticker or an applied paint, or could be formed in the housing (e.g., molded into the housing (e.g., a raised designation which may have a different color than the housing) or a combination of both.

The colors could include colors associated with the manufacturer, or have some other significance (e.g., red could be used for an outlet indicating that the outlet is hot or has live power). Icons could be simple icons, such as shapes (e.g., square, circle, rectangles, triangle, etc.). According to some implementations, a combination of colors and shapes could be used to aid those who may have difficulty detecting differences in colors. For example, a red circle, could be used as a designation of one type of module, while a blue triangle could be used as a designation of another type of module. The location of the designation on the module may correspond to the location on the power adapter. For example, if the designation is on the rear surface of the recess of the power adapter and on the rear surface of the module, the designation could be in the same relative location on the power adapter and module. For example, the designation could be in the upper left corner, so that when a homeowner holds an outlet module looking at the rear surface of the module and the recess of the outlet power adapter, the user will see a red circle in the upper left corner for each). Modules may have more than one designation. For example, one module may have two designations for two types of switches (e.g., a single pole switch and a primary multi-way switch), while another module may have three designations for each of the three types of switches.

Referring specifically to FIG. 13, the power adapters 141, 151, 171, and 181 are shown, where each power adapter comprises surfaces for providing an indication of the type of module. The outlet power adapter comprises a front surface 1302 having the outlet 142 which would be visible with the faceplate attached. The switches may comprise a surface 1304 which surrounds the switch 152 which may also visible when a faceplate is attached. The recess also comprises various surfaces, including a rear wall 1308, a surface 1310 (shown here be way of example as a bottom wall or surface, which would have a corresponding top wall opposite the bottom wall and below the outlet or switch of the power adapter), and a side wall 1312 which would have a corresponding side wall 1313 opposite the side wall 1312. According to some implementations, the indication could be provided on one or more walls of the recess, such as the walls 1308, 1310, 1312, 1313, which would be visible when the wall plate is attached to the power adapter.

Four different types of modules 1320, 1322, 1324 and 1326 having contact elements 1328 are shown by way of example, and may have different functionality, different electrical and mechanical interfaces, and different user interfaces. According to one implementation, indications of the type of module could be shown on the power adapters and modules by placing the indication on the surface 1310 of the power adapter and on a top surface of the module, such as below the contact elements of the module. For example, a sticker having one or more selected colors and/or shapes could be placed on the surface 1310. For example, a designation for an outlet power adapter could be a red circle, a designation for a single pole switch power adapter could be a white square, a designation for a primary multiway switch power adapter could be a blue triangle, and a designation for a companion multiway switch power adapter could be a green inverted triangle. A sticker could be placed on each module to indicate in which power adapters that module can be placed. For example, the module 1320 could comprise an indication 1330 having a red circle indicating that the outlet module can only be placed or be placed and operate in the power adapter 141 having an outlet. That is, none of the switch power adapters could have a circle designation, so users would know that the outlet module 1320 could not be used in a switch power adapter. The module 1322 may comprise an indication 1332 having all four of the circle, square, triangle and inverted triangle, indicating that module 1322 could be received and operate in any of the power adapters 141, 151, 171 and 181. By way of example, module 1322 could comprise a night light module which may provide a function of providing light to a dark area or a charging module, such as a module having a USB connector which may provide a function of charging a device and/or communicating data such as in a USB-C device. Module 1324 may comprise an indication 1334 having the square, triangle and inverted triangle, indicating that the module could be placed in any of the switch power adapters. The module 1326 may comprise an indication 1336 having only the square and the inverted triangle, indicating that the module can be received and operate in a switch power adapter the controls the power to the load, such as a single pole switch power adapter and a primary multiway switch power adapter.

According to one implementation, a system for indicating compatibility of modules and power adapters adapted to receive modules may comprise a plurality of types of power adapters having a switch; and at least one type of power adapter having an outlet; wherein the plurality of types of power adapters having a switch comprises at least one designation and the at least one type of power adapter having an outlet comprises a second designation that is different than the at least one designation.

According to another implementation, a system for indicating compatibility of modules and power adapters adapted to receive modules may comprise a plurality of types of power adapters having a switch comprising a first type of power adapters configured to be coupled to a load and a second type of power adapter configured to provide signals to a power adapter of the first type of power adapters; and at least one type of power adapter having an outlet; wherein the system comprises at least a first designation for the first type of power adapter having a switch, a second designation for the second type of power adapter having a switch, and a third designation for power adapters having an outlet.

A variety of implementations of circuits for detecting errors in the wiring of a power adapter or multiple power adapters in a multiway wiring arrangement, either in a power adapter or a module or both, are now described. The error detection circuits can be used to provide an indication of an error, and in some or all cases, of the specific type of the error in the wiring. According to other implementations, a circuit of one or more of the power adapter or the module may be disabled if an error in the wiring is detected. For example, if a power adapter comprises a switch for controlling the application of power to a load, a control circuit of the power adapter may be coupled to the error detection circuit and disable the power adapter to prevent the application of power to a load. It should be understood that the control circuit may comprise any type of integrated circuit, such as a processor, microprocessor or programmable logic device, a circuit comprising discrete components for implementing a certain functionality, other suitable electronic device or group of electronic devices for implementing the functionality. By disabling the power adapter, a home builder or electrician will easily detect the error in the wiring before the home is transferred to a home buyer in the case of new construction.

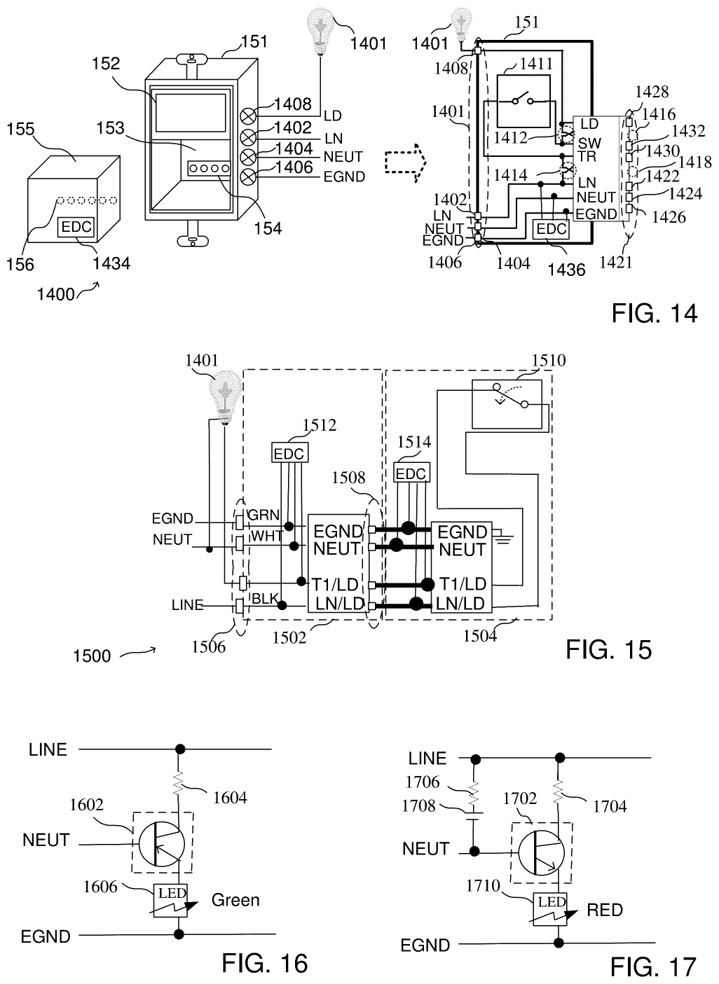

It may be beneficial to detect whether a power adapter has been wired correctly. According to some implementations, it may be necessary to determine whether a neutral wire has been attached to a power adapter. According to some implementations, it may be beneficial to include an error detection circuit (EDC) in one or both of the power adapter or a module that could provide an indication that an incorrect wiring condition exists. Examples of power adapters, modules and circuits for enabling the detection of an incorrect wiring condition are shown in FIGS. 14-17.

Turning now to FIG. 14, a block diagram of a power adapter arrangement comprising a single pole switch having contact elements configured to receive wires of a junction box. More particularly, in FIG. 14, a block diagram of a power adapter arrangement 1400 having contact elements adapted to receive wires of a junction box is shown. The power adapter 151 having a switch is adapted to control a load in a single pole wiring arrangement, also known as a one-way switching arrangement, where only one switch is adapted to control the load. In addition to the elements of the power adapter described in FIG. 1, the power adapter comprises a plurality of contact elements adapted to receive wires of a junction box. According to the implementation of FIG. 14, the plurality of contact elements comprises a first contact element 1402 adapted to receive a line voltage, a second contact element 1404 adapted to receive a neutral voltage, a third contact element 1406 adapted to receive a ground voltage, and fourth contact element 1408 adapted to be coupled to a load 1401.

Additional elements of the power adapter 151 are shown in circuit representation of the power adapter as shown on the right side of the dashed arrow in FIG. 14. More particularly, a switch 1411 is adapted to enable a user of the power adapter 151 to switch the application of power provided to the load. The power adapter 151 also comprises connectors 1412 and 1414 that enable connecting nodes of the power adapter, as will be described in more detail below. The connectors 1412 and 1414 enable control modules to change the operation of the power adapter based upon the type of control module used. The power adapter may also comprise openings 1416 and 1418 that receive actuators for controlling the connectors 1412 and 1414, as will be described in more detail below. The electrical interface 1421 comprises a plurality of contact elements, including a first contract element 1422 adapted to be coupled to a corresponding contact element of a control module, a second contract element 1424 adapted to be coupled to a corresponding contact element of a control module, a third contract element 1426 adapted to be coupled to a corresponding contact element of a control module, a fourth contract element 1428 adapted to be coupled to a corresponding contact element of a control module, a fifth contract element 1430 adapted to be coupled to a corresponding contact element of a control module, and a sixth contract element 1432 adapted to be coupled to a corresponding contact element of a control module. The contact elements 1422-1428 may be coupled to corresponding contact elements 1402-1408. The operation of the power adapter 151 will be described in more detail below with respect to different control modules. An error detection circuit 1436 may be coupled to contact elements of the module that receive signals, such as the line, ground and neutral voltages. An error detection circuit 1434, alone or in combination with the error detection circuit 1436 may detect a wiring error, where one or more wires of the junction box may be improperly connected to the power adapter or may not be connected to the power adapter. According to some implementations, the error detection circuit 1434 or 1436 may be coupled to one or more of the line neutral, ground, or load contacts.

Turning now to FIG. 15, a block diagram of a power adapter arrangement 1500 according to another implementation is shown. According to the implementation of FIG. 15, the module rather than the power adapter comprises a switch for controlling the application of power to a load, where a combination of the power adapter and the module control the application of power to the load. More particularly, a power adapter 1502 is adapted to be coupled to a module 1504 and comprises an electrical interface 1506 that is coupled to receive the line, ground and neutral voltages at contact elements and provide power to the load 1401. A second electrical interface 1508 comprises corresponding contact elements of the power adapter 1502 and the module 1504, where one or more contact elements of the control module are connected to a corresponding contact element of the power adapter. A switch 1510 enables the controlling of the application of the line voltage to the load 1401. One or both of an error detection circuit 1512 provided in the power adapter or an error detection circuit 1514 provided in the module can indicate whether an incorrect wiring condition exists.

One incorrect wiring condition could be that a neutral contact element of the electrical interface 1506 is not connected to a neutral wire of the junction box. Example circuits for detecting and providing an indication of a wiring error to a builder, electrician or a homeowner are shown in FIGS. 16 and 17. Turning first to FIG. 16, a block diagram of a circuit for indicating an incorrect wiring condition of a power adapter is shown. The error detection circuit of FIG. 16 comprises a low voltage detection circuit 1602, shown here by way of example as a PNP transistor. The low voltage detection circuit 1602 may be coupled between a resistor 1604 coupled to the line voltage and an indicator element 1606, which is shown by way of example as a light emitting diode (LED). However, the indicator element could be any type of device that provides an audible or visual indication. In operation, when the neutral line of a junction box is connected, the base of the emitter of the transistor will be pulled low, turning on the transistor and providing an indication, such as a green light from a green LED, that the neutral wire is connected.

Turning now to FIG. 17, a block diagram of another circuit for indicating an incorrect wiring condition of a power adapter is shown. According to the implementation of FIG. 17, a high voltage detection circuit 1702 may be implemented, where the connection of the neutral line of the junction box would pull the input to the high voltage detection circuit low, and therefore turn off a light. More particularly, the high voltage detection circuit 1702 may comprise a NPN transistor and be coupled to a resistor 1704 and having a control input coupled to a resistor 1706 and a capacitor 1708 coupled in series as shown. An indicator 1710 element, which may be a red LED for example, may be coupled to the high voltage detection circuit as shown. However, the indicator element could be any type of device that provides an audible or visual indication. Until the neutral wire junction box is connected to the power adapter, a DC voltage will be applied to the control terminal of the high voltage detection circuit 1702, causing current to flow in the high voltage detection circuit 1702 and turning on the indicator 1710. When the neutral wire is attached to the power adapter, the transistor will turn off and the red LED will turn off.

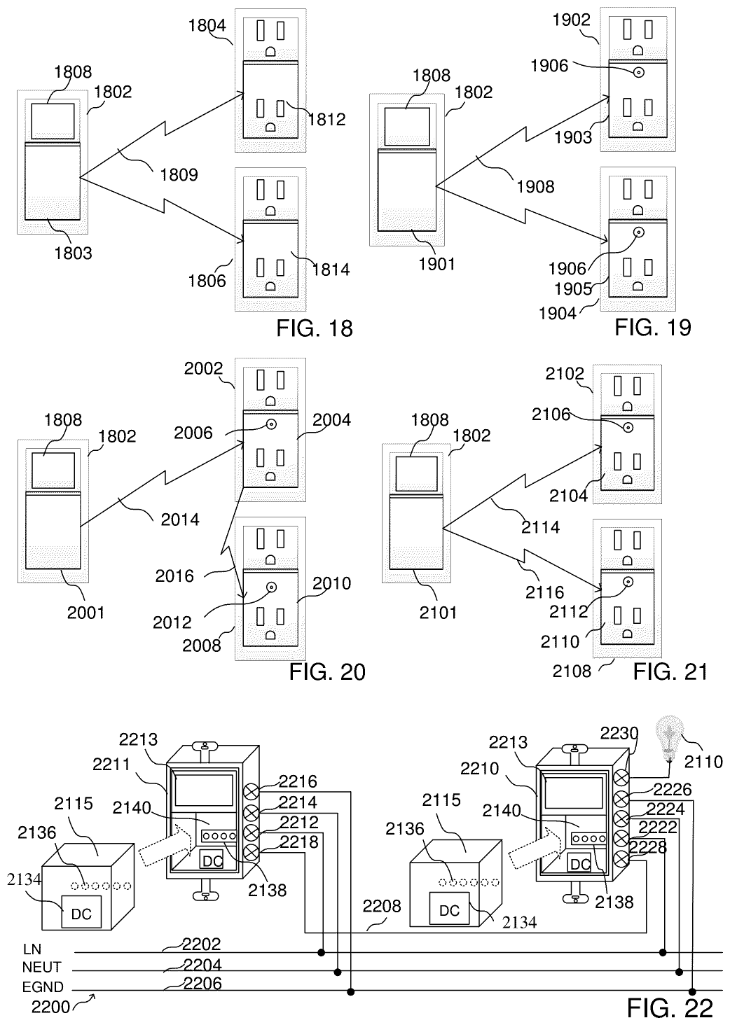

Turning now to FIG. 18, a block diagram of a power adapter configured to control multiple wirelessly controlled outlets using a common toggle signal according to one implementation is shown. A power adapter 1802 having a control module 1803 with a single transmitter is adapted to communicate with multiple wirelessly controlled outlet control modules, shown here by way of example in power adapters 1804 and 1806. The power adapter 1802 comprises a switch actuator 1808 and is configured to receive the control module 1803. According to some implementations, the control module is adapted to provide a single toggle signal 1809 to both a wirelessly controlled outlet module 1812 associated with the power adapter 1804 and a wireless controlled outlet module 1814 associated with the power adapter 1806.

Turning now to FIG. 19, a block diagram of a power adapter configured to control multiple wirelessly controlled outlets using a common on/off state signal according to one implementation is shown. A power adapter 1802 having a control module 1901 with a single transmitter is adapted to transmit a common on/off state signal to multiple wirelessly controlled outlet control modules, shown here by way of example as a power adapter 1902 having a wirelessly controlled outlet module 1903 and a power adapter 1904 having a wirelessly controlled outlet module 1905. That is, rather than sending a generic toggle signal, the control module 1901 sends specific signals 1908, such as “on” or “off” signals or other control commands. The control modules 1903 and 1905 have an on/off control element 1906 that would allow a user to change the state of the power applied to a device plugged into the power adapter, and therefore manually override the state of the power applied to a device.

Turning now to FIG. 20, a block diagram of a power adapter configured to control multiple wirelessly controlled outlets using signaling between wirelessly controlled outlet control modules according to one implementation is shown. According to the implementation of FIG. 20, a toggle or on/off signal may be sent to one control module, and transmitted from the one control module to one or more other control modules. More particularly, the wirelessly controlled outlet modules may be provided in pairs, where one primary wirelessly controlled outlet module is adapted to communicate with one or more remote wirelessly controlled outlet modules. By way of example, a power adapter 1802 having a control module 2001 with a single transmitter is adapted to communicate with at least one wirelessly controlled outlet control module, shown here by way of example in power adapter 2002. A power adapter 2002 is adapted to receive a wirelessly controlled outlet module 2004 having a control button 2006, which may comprise an on/off button for controlling/overriding the application of power to a device plugged into the wirelessly controlled outlet module 2004. A power adapter 2008 is adapted to receive a wirelessly controlled outlet module 2010 having a control button 2012, which may also comprise an on/off button for controlling/overriding the application of power to a device plugged into the wirelessly controlled outlet module 2010. Unlike the implementation of FIG. 19 where the control module in the power adapter having a switch directly communicates with multiple controlled outlet modules in power adapters having outlets, the control module in the switch power adapter communicates with one wirelessly controlled outlet module, which in turn communicates with one or more other wirelessly controlled outlets. More particularly, the control module 2001 communicates with the wirelessly controlled outlet module 2004 by way of a first communication link 2014, and the wirelessly controlled outlet module 2004 communicates with one or more other wirelessly controlled outlets, such as wirelessly controlled outlet module 2010, by way of a second communication link 2016.

Turning now to FIG. 21, a block diagram of a power adapter having a control module 2101 configured to control multiple wirelessly controlled outlets using multiple transmitters of the control module according to one implementation is shown. As can be seen, separate transmitters may be used to send different toggle signals, on/off signals, or other control signals to corresponding separate control modules. A power adapter 2102 is adapted to receive a wirelessly controlled outlet module 2104 having a control button 2106, which may comprise an on/off button for controlling/overriding the application of power to a device plugged into the wirelessly controlled outlet module 2104. A power adapter 2108 is adapted to receive a wirelessly controlled outlet module 2110 having a control button 2112, which may also comprise an on/off button for controlling/overriding the application of power to a device plugged into the wirelessly controlled outlet module 2110. More particularly, the control module 2101 communicates with the wirelessly controlled outlet module 2104 by way of a first communication link 2114, and the wirelessly controlled outlet module 2104 communicates with one or more other wirelessly controlled outlets, shown here by way of example as wirelessly controlled outlet module 2110, by way of a second communication link 2116. According to some implementations, a user interface may comprise separate control elements for controlling the separate signals on the separate communication links.

Turning now to FIG. 22, a block diagram of power adapter arrangements in a multi-way wiring arrangement 2200 is shown. According to the implementation of FIG. 22, a plurality of power adapters are coupled to wires accessible in junction boxes, including a line wire 2202 having a line (LN) voltage, a neutral (NEUT) wire 2204 having a neutral voltage, and a ground wire 2206 having a ground (EGND) voltage in a similar manner as wires of a junction box would be attached to the power adapter of FIG. 1. A power adapter 2210 implemented as a primary switch power adapter that controls the application of power to the load may be coupled to one or more power adapters 2211 implemented as a companion switch power adapter by a traveler wire 2208. While the power adapter 2210 may be implemented to control the load without the use of companion switches, the traveler wire enables the transfer of communication signals between the primary switch power adapter and the one or more companion switch power adapters.

The power adapter 2211 implemented as a companion switch power adapter having a switch actuator 2213 comprises a plurality of contact elements adapted to be coupled to wires of a junction box, including a first contact element 2212 adapted to receive a line voltage, a second contact element 2214 adapted to receive a neutral voltage, a third contact element 2216 adapted to receive a ground voltage, and a fourth contact element 2218 adapted to provide signals to the power adapter 2210 over the traveler wire 2208. The contact elements are coupled to corresponding wires accessible in a junction box as shown. Although a single power adapter 2211 implemented as a companion switch is shown, it should be understood that additional power adapters 2211 implemented as companion switch power adapters could be wired in the same manner that power adapter 2211 is wired. The contact elements 2212-2218 are also adapted to be coupled to corresponding wires accessible in a junction box as shown.

The power adapter 2210 implemented as a primary switch comprises a plurality of contact elements adapted to be coupled to wires of a junction box, including a first contact element 2222 adapted to receive a line voltage, a second contact element 2224 adapted to receive a neutral voltage, a third contact element 2226 adapted to receive a ground voltage, a fourth contact element 2228 adapted to be coupled to a traveler wire 2208, and a fifth contact element 2230 adapted to be coupled to the load by a wire in a junction box. The contact elements 2222-2228 are also adapted to be coupled to corresponding wires accessible in a junction box as shown.

As will be described in more detail below, one or more of the switch power adapters or modules shown in FIG. 22 may comprise a detection circuit (DC) 2134 enabling the module to detect the type of switch power adapter into which it is installed or enabling a switch power adapter to detect the type of module which it has received. The detection circuit 2134 of the control module 2115 of FIG. 22 comprises a plurality of contact elements 2136 adapted to be coupled to a plurality of contact elements of the electrical interface 2138 in a recess 2140 adapted to the receive the control module 2115. It should be understood that the detection circuit 2134 may provide different functionality depending upon the module or power adapter in which it is installed, as will be described in more detail below. When implemented in a switch power adapter, the detection circuit may be implemented using the control circuit of the switch power adapter. The power adapter arrangements of FIG. 22 could be implemented in a building, such as a building shown in FIG. 1 or other similar environments.

Both the primary switch power adapter and any switching control module (i.e., a control module comprising a switch such as a relay or TRIAC for switching power to a load) may operate under certain conditions where the switch (e.g., a relay or TRIAC) of the primary switch power adapter (e.g., power adapter 2210) does not control the application of power to the load. Because current may be driven through a coil to hold the relay in a given state, such as when turning on the relay, power may be consumed unnecessarily when a relay is turned on when no current is driven through it to drive a load. This condition may occur in at least two instances. A first instance may occur when a switching control module is used in a primary switch power adapter and performs the switching, in which case a switch (e.g., a relay or TRIAC) in the primary switch power adapter should remain open (i.e., does not switch power to the load and does not drive current). That is, the switching of power to the load is accomplished through and controlled by a switching element such as a relay or TRIAC of a switching control module. A second instance may occur when a switching control module is used in a companion switch power adapter, where the switching control module only needs to send a switching signal to the primary switch power adapter (e.g., over the traveler line or by way of a wireless communication signal where the switching of power to the load is performed in the primary switch power adapter or module), but does not need to switch its own relay and therefore can be held in an idle state to avoid unnecessarily turning on the relay when the control module is not driving current or not being used to directly control the application of power to a load.

In order to prevent unnecessary current draw in the first instance, it may be necessary for the primary switch power adapter to detect or be informed that a switching control module is being used in the primary switch power adapter. In order to prevent unnecessary current draw in the second instance, it may be necessary for the switching control module to detect or be informed that it is in a companion switch power adapter.

According to some implementations, the ability to use a switching control module by itself in any type of switch power adapter may be accomplished by having a default operational mode for a switching control module, (e.g., the switching control module will switch its relay to control the application of power to a load as a default), where the operational mode of the switching control module may change based upon the detection of the type of switch power adapter that it is in (e.g., it will enter an operational mode of not switching the relay when the switching control module determines or is informed that it is in a companion switch, and may therefore operate in a signal only mode).

The following solutions not only reduce power consumption, but also enable the use of a switching control module in any of the three switch power adapter types: a single pole switch power adapter, a primary switch power adapter which performs the switching of power to a load in a multi-way switching arrangement, or a companion switch power adapter in a multi-way switching arrangement, where the switching control module provides control signals to the primary switch power adapter.

Considering first a primary switch power adapter, it is beneficial if the primary switch power adapter detects when it receives a switching control module, in which case the control circuit of the primary switch power adapter may maintain its power switch (e.g., relay or TRIAC) in an idle state (i.e., in an open state and not drawing current through the coil that controls the relay). According to one implementation, a control circuit of the primary switch power adapter may have a voltage comparator, in which case it would only be necessary for a control circuit to detect the presence of a switching control module.

One example of detecting the presence of a switching control module includes detecting a voltage signal, such as a voltage signal (e.g., 5 Volt DC signal) generated on a switch (SW) contact element of any switching control module and provided to the power adapter by way of a corresponding SW contact element of the electrical interface 2138 of the switch power adapter. That is, the voltage signal is provided on the SW contact provided by the switching control module (i.e., a DC Switch Signal) to enable the single pole switch to detect a toggling of the switch of the single pole switch power adapter such as the power adapter shown in FIG. 1. According to one implementation, the voltage on the SW contact of the primary switch power adapter could be detected, such as by using the control circuit of the primary switch power adapter. If the DC Switch Signal is detected by the control circuit of the primary switch power adapter, it will know that the primary switch power adapter has received a switching control module, where the switching element (e.g., a relay or TRIAC) of the primary switch power adapter may be kept in an idle mode to avoid drawing any current, such as by disabling the operation of the switching element because the switching element of the primary switch power adapter is not used for providing controlling the application of power to the load.

According to another example, because a switching control module may include a projection that will open a connector (e.g., electrically separate two contact elements of a “break connector”), a comparator, such as a comparator of a control circuit of the power adapter, can be used to detect when the two contact elements are at the same voltage (e.g., when they are connected), or when they are at a different voltage (e.g., when a projection of the switching control module “opens” the connector and the two contact elements may be at a different voltage (e.g., the SW contact will be at 5 V DC and the LD contact will be floating, or at 120V AC or some other AC or DC voltage)). Accordingly, when a primary switch power adapter detects the presence of a switching control module, it will maintain the state of its relay in a fixed state, such as an open state (i.e., non-conducting), because it will not control the application of power to a load.

Considering now a switching control module, a switching control module may function to switch power to a load in two cases (i.e., when a switching control module is used in a single pole switch power adapter, or in a primary switch power adapter of a multi-way switching arrangement), but will not function to switch power to a load in a third case when the switching control module is used in a companion switch power adapter. In this case, the switching control module would only need to detect when the switching control module is in the companion switch power adapter. That is, the default mode of the switching control module would be to perform the switching of the power to the load, and the switching control module would enter a non-default mode of providing signaling on the traveler when it is in a companion power adapter, but not switching its relay.

One way to accomplish this would be to put a voltage signal (e.g., a 1 or 2 V DC signal (i.e., a “DC Offset Signal”)) on the SW contact element of the companion power adapter that is different than the voltage signal (e.g., the 5 V DC signal) applied to SW contact by the switching control module as described above, where the 5 V DC signal may be used to indicate a switching operation of the switching element of the power adapter. That is, before the voltage signal (e.g., the 5 V DC signal) is applied to the SW contact by the switching control module, the control circuit of the switching control module may enter a start-up mode when the switching control module is placed in a power adapter and the switching control module receives power (or after a loss of power and the switching control module receives power again). If the switching control module detects the DC Offset signal placed on the SW contact by the companion power adapter, it may change from the default operating mode that would allow its relay to switch to an inactive operating mode (a signal only mode) where the relay or the switching control module would be held in an idle state (i.e., not conduct any current in the coil or through the relay), but would send signals on a traveler.

Alternatively, a voltage signal could be provided on the load (LD) contact, rather than on the SW contact. It should be noted that the SW and LD contacts may not otherwise be required in the companion switch power adapter but could be included to enable a detection by a switching module that it is in a companion power adapter as will be described below.

As will be described in more detail below, a signal could be provided on the traveler to detect a wiring error. While the voltage signal could be provided on the traveler (TR) contact element, it may be beneficial to put a DC Offset Signal on the TR contact element for enabling the identification of a wiring error, as will be described below.

When the switching control module detects the DC Offset Signal, the switching control module will determine that it is in a companion switch power adapter. That is, there will never be a 1 or 2 V DC signal (i.e., a DC Offset Signal) on the SW contact of the single pole switch because it is a switching control module itself that applies a voltage to the SW contact, which would only occur after a start-up mode. Also, a voltage will only be placed on the SW contact of a companion switch power adapter, but not a primary switch power adapter to enable the control module to determine that it is in the companion switch power adapter.

According to some implementations, in the default mode, a switching control module may not need to put a control signal on the traveler. There is no need to place a switching signal of a contact of the power adapter when a switching control module is used in a single pole switch application. When a switching control module is used in a primary switch power adapter, there may also be no need to place a switching signal on the traveler when the control module in the primary switch power adapter performs the switching. When the switching control module is used in a companion switch power adapter (i.e., the non-default condition) it may be beneficial for the switching control module to place a switching signal on the traveler to be detected by the control circuit of the primary switch power adapter. Therefore, according to some implementations, a control module will act as a switching module in a default mode (e.g., such as when in a single pole switch or a companion multi-way switch), or a signaling module in a secondary mode (e.g., a non-default mode, such as when in a companion switch power adapter).

It should be understood that a second default case could be implemented where the relay of the switching control module could be in an idle mode as a default mode (i.e., always in an open state to not provide a current path or otherwise draw current), and only be switched to an active mode when it is determined that it is in either a single pole switch power adapter or a primary switch power adapter.

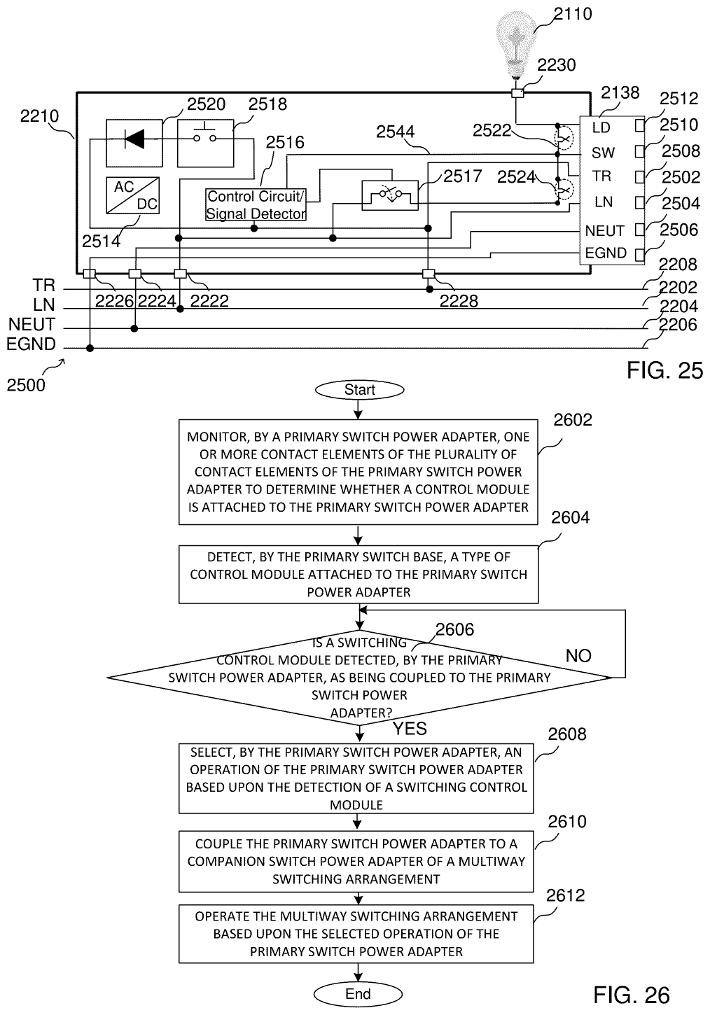

According to another implementation, the relay of a primary switch power adapter may perform the switching when a switching control module is in the primary switch power adapter, where the relay in the switching control module would be held in an idle state (i.e., non-conducting), as will be described in more detail below in reference to FIGS. 25-28.

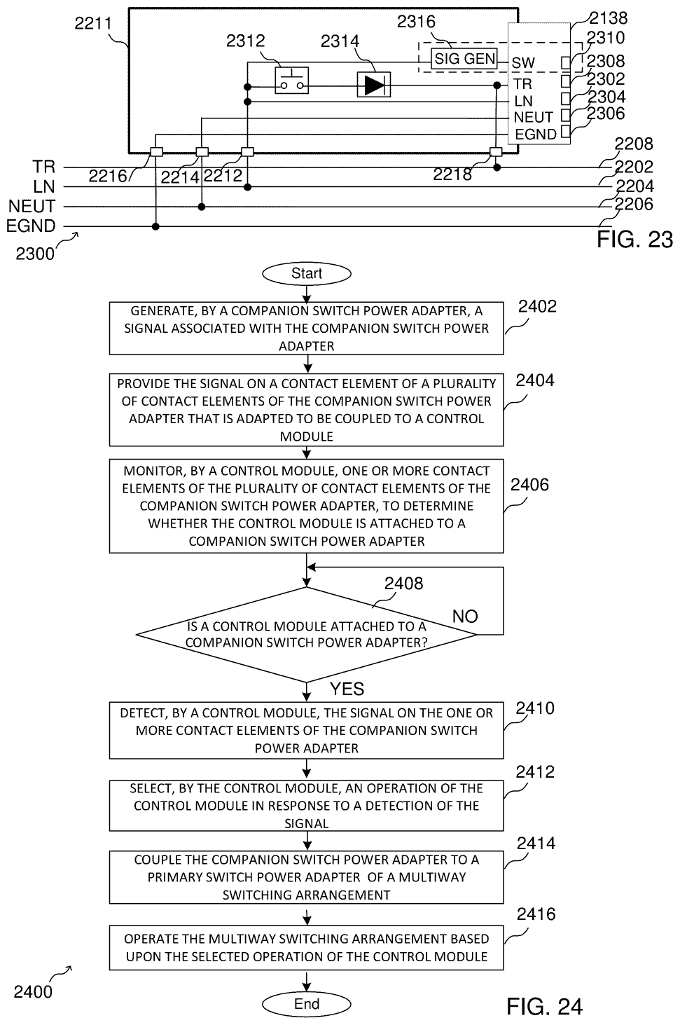

Turning now to FIG. 23, a block diagram of a power adapter 2211 configured to be implemented as a companion switch power adapter as a part of a multi-way wiring arrangement 2300 is shown. More particularly, the electrical interface 2138 comprises a plurality of contact elements adapted to receive one or more corresponding contact elements of a control module, and include a first contact element 2302 adapted to be coupled to a line (LN) contact element of a control module, a second contact element 2304 adapted to be coupled to a neutral (NEUT) contact element of a control module, a third contact element 2306 adapted to be coupled to a ground (EGND) contact element of a control module, a fourth contact element 2308 adapted to be coupled to a traveler (TR) contact element of a control module, and a fifth contact element 2310 adapted to be coupled to a switch (SW) contact element of a control module. The contact elements 2302-2308 are also coupled to corresponding contact elements 2212-2218 to receive the line, neutral, ground and traveler signals as shown.

The power adapter 2211 also comprises a switch 2312, which may be accessible by a user, and provides a signal to a diode 2314. The diode 2314 generates a signal in response to the actuation of the switch 2312. The signal is provided on the traveler contact element 2218 and the contact element 2308, which may also be a traveler contact element. Signal generator 2316 is adapted to generate a signal on the contact element 2310, enabling a control module coupled to the electrical interface 2138 to determine that it is coupled to a companion switch power adapter, as will be described in more detail below.

Turning now to FIG. 24, a flow chart 2400 shows a method of implementing a power adapter as a companion switch power adapter in a multi-way wiring arrangement, such as the power adapter of FIG. 23. More particularly, a signal associated with a companion switch power adapter is generated by the companion switch power adapter, such as by the signal generator 2316, at a block 2402. The signal is provided on a contact element, such as the contact element 2310 of FIG. 23, of a plurality of contact elements of the companion switch power adapter that is adapted to be coupled to a control module at a block 2404. One or more contact elements of the plurality of contact elements of the companion switch power adapter is monitored by a control module to determine whether the control module is attached to a companion switch power adapter at a block 2406. It is then determined whether a control module is attached to a companion switch power adapter at a block 2408. If a control module is attached, the signal on the one or more contact elements of the companion switch power adapter is then detected by a control module at a block 2410. An operation of the control module is selected by the control module, such as by a control circuit of the control module in response to a detection of the signal at a block 2412. The companion switch power adapter is coupled to a primary switch power adapter of a multi-way switching arrangement at a block 2414. The multi-way switching arrangement is operated based upon the selected operation of the control module at a block 2416.

Turning now to FIG. 25, a block diagram of a power adapter 2500 implemented as a primary switch power adapter in a multi-way wiring arrangement is shown. More particularly, the electrical interface 2138 comprises a plurality of contact elements adapted to be coupled to contact elements of a control module, including for example a first contact element 2502 adapted to be coupled to a line contact element of a control module, a second contact element 2504 adapted to be coupled to a neutral contact element of a control module, a third contact element 2506 adapted to be coupled to a ground contact element of a control module, a fourth contact element 2508 adapted to be coupled to a traveler contact element of a control module, a fifth contact element 2510 adapted to be coupled to a switch contact element of a control module, and a sixth contact element 2512 adapted to be coupled to a load contact element of a control module. The contact elements 2502-2508 are coupled to corresponding contact elements 2222-2228 to provide the line, neutral, ground and traveler signals to the control module.

The power adapter 2210 comprises a power supply 2514, shown by way of example as an AC-to-DC converter. The DC signal generated by the power supply 2514 is adapted to provide power to the elements of the power adapter 2210. The power adapter also comprises a control circuit/signal detector 2516 adapted to detect signals from a switch 2518 that are routed through a diode 2520 as shown. The signal may indicate that a user desires to change the state of the power to the load for example. The control circuit controls a switch 2517 for routing the line voltage to the load. The switch 2517 may be a relay or a TRIAC for example. Connectors 2522 and 2524 enable different operations of the power adapter 2210 depending upon the type of control module coupled to the power adapter, as will be described in more detail below. A signal line 2544 is provided from the contact element 2510 to the control circuit to enable the control circuit/signal detector 2516 to determine a type of control module, such as a switching control module, that is coupled to the electrical interface 2138. While a combined control circuit/signal detector 2516 is shown by way of example, it should be understood that a separate control circuit and signal detector could be implemented. Implementations for detecting a type of control module will be described in more detail below.

Turning now to FIG. 26, a flow chart shows a method of implementing a power adapter as a primary switch power adapter in a multi-way wiring arrangement. The method may be implemented by the circuit of FIG. 25 or some other suitable circuit. More particularly, one or more contact elements of the plurality of contact elements of the primary switch power adapter is monitored by the primary switch power adapter, such as by a control circuit/signal detector of the power adapter, to determine whether a control module is attached to the primary switch power adapter at a block 2602. A type of control module attached to the primary switch power adapter is detected by a primary switch power adapter at a block 2604. It is then determined whether a switching control module is detected, by the primary switch power adapter, as being coupled to the primary switch power adapter at a block 2606. An operation of the primary switch power adapter is selected by the primary switch power adapter based upon the detection of a switching control module at a block 2608. The primary switch power adapter is coupled to a companion switch power adapter of a multi-way switching arrangement at a block 2610. The multi-way switching arrangement is operated based upon the selected operation of the primary switch power adapter at a block 2612.

According to one implementation, a switching circuit of one of the primary switch power adapters and a switching module will remain idle and allow the switching circuit of the other of the primary switch power adapter and a switching module to control the application of power to the load. For example, when the primary switch power adapter detects that it is coupled to a switching module, the control circuit of the primary switch power adapter may maintain the switching circuit (e.g., relay or TRIAC) of the primary switch power adapter in an idle state and allow the control module to control the application of the power signal to the load. Alternatively, when the primary switch power adapter detects that it is coupled to a switching module, the control circuit of primary switch power adapter may instruct the switching circuit (e.g., relay or TRIAC) of the control module to remain idle. By way of example, the processer of the primary switch power adapter may provide an instruction on the traveler line and any switching control module attached to any power adapter of multi-way wiring arrangement would hold its switching circuit in an idle state, and allow the switching circuit of the primary power adapter to control the application of power to the load.

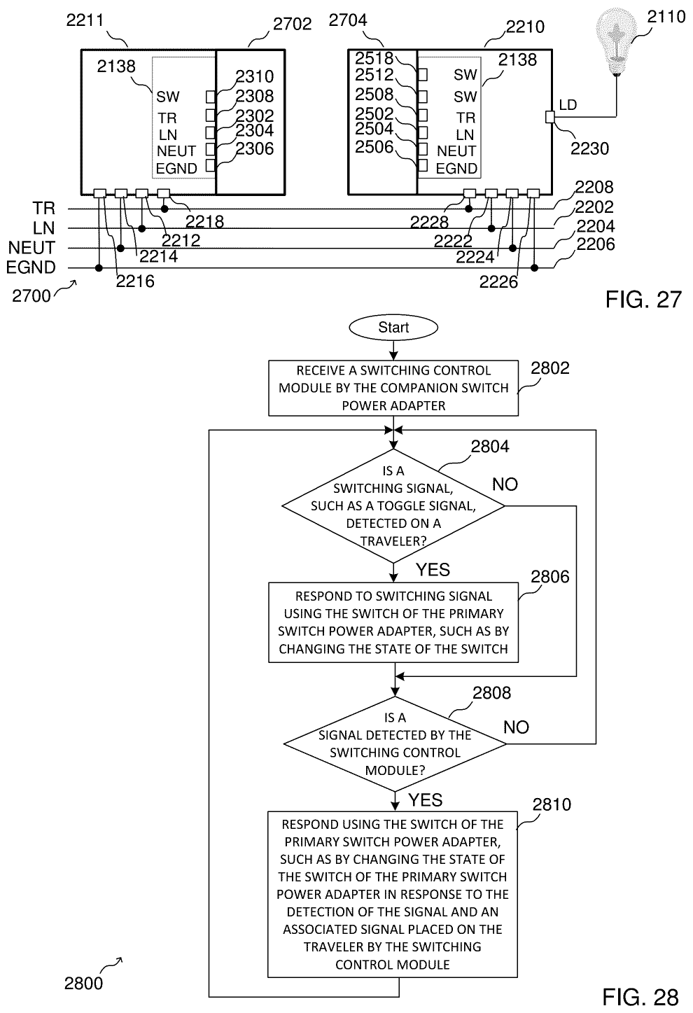

Turning now to FIG. 27, a block diagram of a pair of power adapter arrangements 2700 configured in a multi-way wiring arrangement according to one implementation is shown. According to the example of FIG. 27, a switching control module 2702, which may be adapted to route line voltage to the load in some power adapters, is coupled to the power adapter 2211, and a non-switching control module 2704, which may be a control module that draws power from the power adapter but does not directly control the application of power to a load by routing the power to the load, is coupled to the power adapter 2210. According to the implementation of FIGS. 27-30, the power adapter arrangement may only comprise a switching control module as shown where the non-switching control module is not present, which would not affect the operation of the power adapter arrangement.

Turning now to FIG. 28, a flow chart 2800 shows a method of implementing a pair of power adapter arrangements according to the multi-way wiring arrangement of FIG. 27. More particularly, a switching control module is received by the companion switch power adapter at a block 2802. It is then determined whether a switching signal, such as a toggle signal or some other control signal, is detected on a traveler at a block 2804. If so, the primary switch power adapter responds to a switching signal using the switch of the primary switch power adapter, such as by changing the state of the switch to apply or block power applied to the load at a block 2806. If a switching signal is not detected at block 2804 or after responding to the switching signal at block 2806, it is then determined whether a signal is detected by the switching control module attached to the companion switch power adapter at a block 2808. If so, the primary switch power adapter responds using the switch of the primary switch power adapter, such as by changing the state of the switch (e.g., using the relay or TRIAC) of the primary switch power adapter in response to the detection of the signal and an associated signal placed on the traveler by the switching control module at a block 2810. By way of example, the signal detected by a switching control module would be a signal generated in response to a user actuation of a user interface element of the control module or a signal, such as a wireless signal, received by the switching control module. If a signal is not detected by the switching control module at block 2808 or after a response at block 2810, it will again be determined whether a switching signal is detected on a traveler at block 2804.

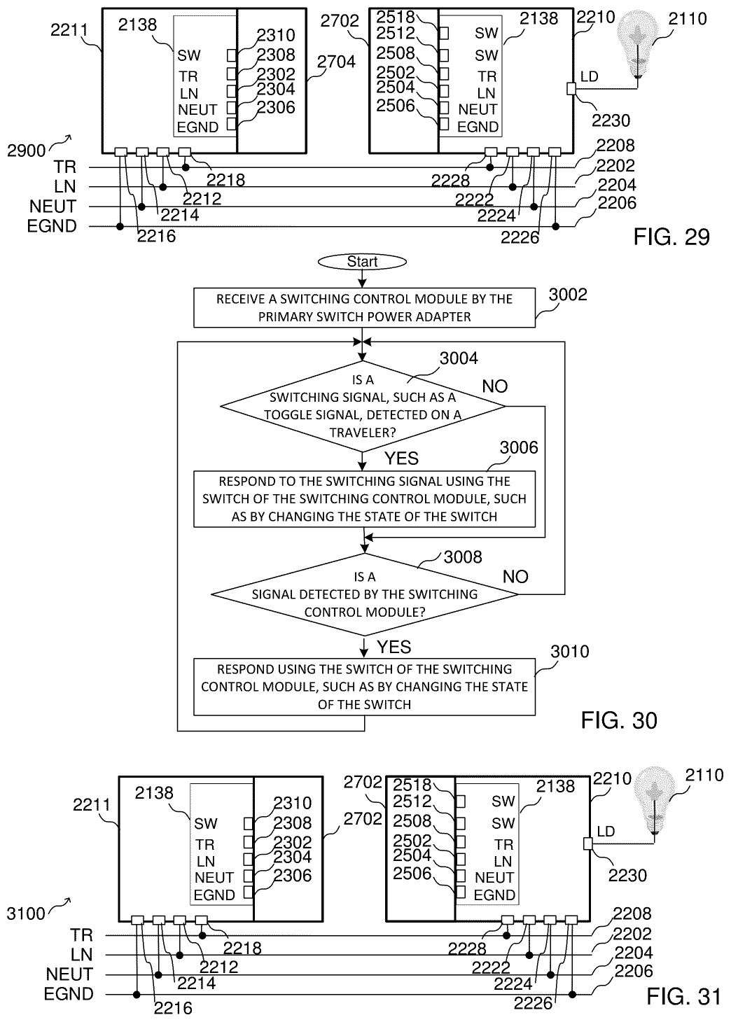

Turning now to FIG. 29, a block diagram of a pair of power adapter arrangements 2900 configured in a multi-way wiring arrangement according to another implementation is shown. According to the example of FIG. 29, a switching control module 2702 is coupled to the power adapter 2210, and a non-switching control module 2704 is coupled to the power adapter 2211. As will be described in more detail below, unlike when a switching control module is attached to the power adapter 2211, the switching control module 2702 may route power to a load when coupled to a primary switch power adapter.

Turning now to FIG. 30, a flow chart shows a method of implementing a pair of power adapter arrangements according to the multi-way wiring arrangement of FIG. 29. More particularly, a switching control module is received by the primary switch power adapter at a block 3002. It is then determined if a switching signal, such as a toggle signal, is detected on a traveler at a block 3004. If so, a response to a switching signal using the switch (e.g., relay or TRIAC) of the switching control module, such as by changing the state of the switch of the switching control module, is made at a block 3006. If a switching signal is not detected on the traveler at block 3004 or a response is made at block 3006, it is then determined whether a signal, such as a wireless signal for example, is detected by the switching control module at a block 3008. If so, a response using the switch of the switching control module, such as by changing the state of the switch, is made at a block 3010. If no signal is detected at block 3008 or a response is made at block 3010, it is again determined if a switching signal is detected on a traveler at a block 3004.

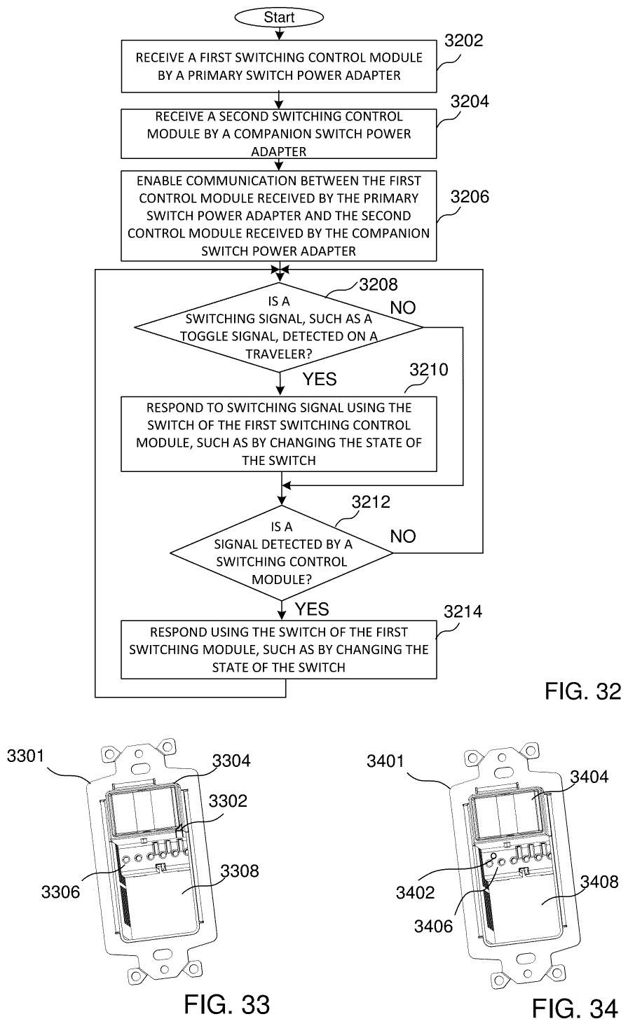

Turning now to FIG. 31, a block diagram 3100 of a pair of power adapter arrangements configured in a multi-way wiring arrangement according to a further implementation is shown. According to the implementation of FIG. 31, switching control modules 2702 are coupled to both the power adapter 2210 operating as a primary switch power adapter and the power adapter 2211 operating as a companion switch power adapter. The operation of and communication between the two switching control modules will be described in more detail below in reference to FIG. 32.

Turning now to FIG. 32, a flow chart shows a method of implementing a pair of power adapter arrangements according to the multi-way wiring arrangement of FIG. 31. More particularly, a first switching control module is received by the primary switch power adapter at a block 3202. A second switching control module is received by the companion switch power adapter at a block 3204. Communication between the first control module received by the primary switch power adapter and the second control module received by the companion switch power adapter is enabled at a block 3206. According to some implementations, the communication between the switching control modules could be accomplished using wireless communication circuits or over the traveler. It is then determined whether a switching signal, such as a toggle signal or other control signal (e.g., a dimming signal), is detected on a traveler at a block 3208. If so, a response to the switching signal is performed using the switch of the first switching control module, such as by changing the state of the switch is made at a block 3210. If no signal is detected at block 3210 or a response is generated at block 3210, it is then determined whether a signal, such as a wireless signal detected by one or both of the switching control modules, is detected by a switching control module at a block 3212. If so, a response using the switch of the first switching control module, such as by changing the state of the switch, is made at a block 3214. If no signal is detected at block 3212 or a response is generated at block 3214, it is again determined whether a switching signal is detected on a traveler at a block 3208. While only a single power adapter 2211 which is not connected directly to the load is shown in FIGS. 27, 29, and 31, it should be understood that additional power adapters 2211 could be implemented in a multi-way arrangement (beyond the 3-way wiring arrangement shown in FIGS. 27, 29, and 31). For example, additional power adapters 2211 could be coupled the line wire 2202, the neutral wire 2204, the ground (EGND) wire 2206 and the traveler wire 2208 to expand the wiring arrangement to control the application of power to a load using additional power adapters.

According to some implementations, regardless of the default mode of a control module, a switching control module may operate in a passive mode (i.e., where the relay does not switch, but may still transmit communication signals), but the relay of the primary switch power adapter controls the application of the power to a load. The control module may still send control signals to a control circuit of the primary switch power adapter which would control the application of power to the load, such as in the circuit arrangements of FIGS. 29 and 31. The signal could be sent over the traveler for example from the control module to the control circuit of the primary switch power adapter to which the control module is attached, allowing the power switch of the power adapter to control the application of power to the load, such as in response to a wireless signal received by the control module.

According to some implementations, the primary switch power adapter may communicate over the traveler wire 2208. The primary switch power adapter, whenever it receives a signal from a switching control module, may instruct the switching control module to enter into a passive mode. Any switching control module may function to control the application of power to a load in a power adapter that is adapted to control the application of power to a load in a single pole switch application, such as the single pole switch application of FIG. 1 because the switching control module will not receive an instruction from the power adapter of FIG. 1 as shown to enter a passive mode.

According to other implementations, the primary switch power adapter and the switching control module may communicate in a “startup mode” when the switching control module is first inserted in the primary switch power adapter. For example, when a switching control module is first inserted into the primary switch power adapter, the control circuit of the primary switch power adapter will send a signal over a contact element, such as the SW contact element, to indicate that it is in a primary switch power adapter, and that the control module should operate in a passive mode. This operation would be consistent with a switching control module placed in a companion switch power adapter, where the switching control module would detect a voltage on a contact element, such as on the SW contact element as described above in reference to FIG. 23. That is, the switching control module would operate as a passive control module (i.e., the control module would not control the application of power to the load through its power switch) in either a primary switch control module or a companion switch control module in a multi-way switching arrangement according to this implementation.

Rather than or in addition to (i) a primary switch power adapter of a multi-way switching arrangement identifying the type of control module (and more particularly when a switching control module is placed in the primary switch power adapter), and (ii) a switching control module determining when it is in a companion switch power adapter of a multi-way switching arrangement, some implementations could include communication between primary and companion power adapters, where different signaling may be used based upon the elements of a multi-way switching arrangement. For example, different signals may be generated by a switch power adapter or a control module used in a switch power adapter, where the signal would identify that it is generated by certain element (e.g., signals could have an identification field that could identify that the signal is generated by a primary switch power adapter or a certain type of control module).

According to some implementations, different signals may be sent (i) between a switch power adapter and a control module, and (ii) between different types of switch power adapters (e.g., a primary switch power adapter and a companion switch power adapter).

One consideration for sending different signals from different elements of a multi-way wiring arrangement may be that the primary switch power adapter or a switching control module may need to determine whether a toggle signal is generated by a user toggling the switch on the switch power adapter (which may be an override signal) or a toggle signal is generated from another control module (e.g., a motion detection signal from a motion sensor on a control module in a companion switch power adapter) to correctly decide whether to change the state of the power to the load.

By having the same toggle signal from the switch of a switch power adapter in a multi-way switch power adapter arrangement and a toggle signal generated by a control module, it may be beneficial that any control module that toggles the state of power to the load be used on the primary switch power adapter. This placement may be beneficial when implementing motion sensor control modules and any type of timer control module, including a countdown timer, an astronomic timer, and a smart timer for example. That is, a control circuit of the switch power adapter would not be able to distinguish between a toggle signal generated by the control module and a toggle signal generated by a switch actuator on the switch power adapter.

A switching control module could be any control module that switches line power to a load, such as a motion sensor, an astronomical timer, a countdown timer, a wireless controlled outlet or a smart switch having a load switching element, such as a relay or a TRIAC for example. In some cases, the line power may be the line voltage. In other cases, such as with a dimmer, the line power may be the line voltage which is attenuated or otherwise altered to apply a different power signal to the load. Considering a motion sensor control module, a motion sensor control module may change the state of the light to the wrong state if the control module merely provides a toggle signal (i.e., change of state signal associated with the application of power to a load) that is no different than the toggle signal generated by the actuation of a switch of a switch power adapter by a user of the switch power adapter.

A motion sensor may be set to keep a light on for a predetermined time (e.g., 10 minutes) after detecting motion in a room. If a motion sensor control module is in a companion switch power adapter and detects motion, it may send a toggle signal to the primary switch power adapter or the control module in a primary switch power adapter over the traveler line or by way of a wireless communication link. That is, it will send a first toggle signal to the primary switch power adapter or a control module in the primary switch power adapter to turn the light on and a second signal after the predetermined time to turn the light off. The same is true if the motion sensor control module is in the primary switch power adapter, and it sends a toggle signal on the traveler to the control circuit of the primary switch power adapter allowing the primary switch power adapter (or a switching module in the primary switch power adapter) to control the application of power to a load according to some implementations. However, if the signal generated based upon a detection of motion is the same as a toggle signal generated by an actuation of the switch by a user of a switch power adapter, the motion sensor control module may change the state of the light to the wrong state.

For example, if the light is on, and the motion sensor detects motion, it may incorrectly turn the light off if it does not know the state of the switch and just sends a toggle signal because it is in the companion switch power adapter (i.e., by sending a toggle signal to the primary switch power adapter or another switching control module in the primary switch power adapter). A switching control module may know the state of power applied to the light when used in either a single pole switch or a primary switch power adapter when a control circuit of the control module controls the switch (e.g., relay or TRIAC) through which power applied to a load is driven. For example, according to some implementations, the control module may know the state of the power to the load because it controls its relay which applies the power to the load when it is in a single pole switch power adapter or the primary switch power adapter (i.e., when the control module is operating in the default state where the control module controls the application of power to the load as described above).

Further, if a toggle signal is received by a control circuit of the primary switch power adapter, it may need to know that the toggle signal was from the control module (i.e., at the end of a timeout period), rather than from a toggling of the switch of the switch power adapter).

If the user changes a state of a switch using a switch actuator of the power adapter during a timeout period (i.e., the period from turning the light on to turning the light off in response to the detection of a motion), a toggle signal at the end of the timeout period which is intended to turn the light off will actually turn the light on. If the control circuit of the primary switch power adapter knows that the light was turned off during the timeout period and receives a toggle from the timer control module, it may not know to maintain the off state, but rather may toggle the switch on. Although examples have been given for a motion detector control module, the same switching issues may apply to any timer control module. When switching control modules are placed in both the primary switch power adapter and a companion switch power adapter, the switching control modules can communicate to control switching and provide user interface information.

According to other implementations, it may be beneficial for a toggle signal from a switch of a power adapter (i.e. a switch that generates a signal in response to an activation initiated by a user) to be distinguishable from a toggle signal from a control module. According to some implementations, distinct signals can be transmitted for a toggle signal from the switch of a switch power adapter (e.g., a single pulse) and a toggle signal of a control module (e.g., multiple pulses, such as 2 or 3 pulses, and particularly pulses that are faster than someone could toggle a switch of a switch power adapter). Because a control module may have a printed circuit board and a control circuit, it can send a signal that may be different from a simple signal generated by a single pole switch power adapter in response to an actuation of a switch actuator by a user or generated by a switch of a primary switch power adapter or companion switch power adapter in response to an actuation of a switch by a user.

According to some implementations, different toggle signals can be generated by a toggle switch based upon the type of power adapter in a multi-way arrangement, where toggle signals generated by the power adapters are also different than the signals generated by the control module. For example, a primary switch power adapter could generate two pulses in response to a selection of a switch actuator by a user on a primary switch power adapter, and a companion switch power adapter could generate three pulses in response to a selection of a switch actuator on a companion switch power adapter. Separate signal patterns could also be sent for distinct ON or OFF signals for the different types of switch power adapters.

According to some implementations, distinct toggle signals can be provided from the switch of the switch power adapter and a control module, where the toggle signal from a control module provides an indication whether the primary switch power adapter is to turn the light on or turn the light off. When a switching control module is used in any of the switch power adapters to control the switching of power applied to the load, it is possible to send a toggle signal generated by the power adapter, and more particularly, an ON toggle signal or an OFF toggle signal in some circumstances.

According to some implementations, a switching control module can be operated in the same way regardless of the type of switching power adapter in which it is placed (e.g., a control circuit of the control module could send a switching signal on the traveler and switch the switch (i.e., the relay or the TRIAC) of the control module itself). Alternatively, it may be beneficial to not switch a relay when the switching control module is used in a companion switch power adapter, because it will not switch power to the load and may unnecessarily draw current through the coil that controls the relay.

According to some implementations, a multi-way switching arrangement can be implemented to enable a control module to identify where it is located, which may affect the operation of the control module, particularly where the control module sends a signal or performs a switching of a switch of the control module based upon where it is located (i.e., in what type of switch power adapter it is located).

For example, in the case of a control module in a single pole switch power adapter, it may not be necessary that the switching control module know that it is in the single pole switch power adapter. According to one implementation, a switching control module can have a default mode, where the switching control module will both send a switching signal on the traveler and control the switch of the control module (i.e., the relay or the TRIAC) to route current through the control module. Alternatively, in a default mode, the switching control module may only switch its relay, but not send a control signal. As will be described in more detail below, multiple switching control modules that operate in a default mode can be used in a multi-way switching arrangement. According to other implementations, a switch of a control module in a multi-way switching arrangement can operate based upon the type of switch power adapter in which it is placed.

When considering a multi-way switching arrangement according to some implementations, in addition to the default condition being that a switching control module will both switch a relay of the control module and send a switching signal, only one condition may need to be identified, which is when the control module is in the primary switch power adapter. That is, because the primary switch power adapter has a control circuit, it may detect whether a switching control module is coupled to the primary switch power adapter.

According to some implementations, a switch power adapter may detect a switching control module based upon an electrical condition. For example, a control circuit of a power adapter may detect when a switching control module is inserted based upon the use of projections that will break an electrical connection (e.g., a break connector as will be described in more detail below).

According to some implementations, a control circuit of a power adapter may detect a switching control module based upon a mechanical condition. For example, a switching control module and a primary switch power adapter may be coupled such that a switching control module may engage a switch of the primary switch power adapter to indicate to the control circuit of the primary switch power adapter that the control module is a switching control module, or conversely a non-switching control module may engage a switch to indicate that the control module is not a switching control module. For example, a button-type actuator may be positioned in the recess of the power adapter, where either one of the switching control module or the non-switching control module will make contact with the button to indicate the type of control module.

It may be beneficial for a control circuit in a primary switch power adapter to determine that it is receiving control signals from a switching control module that is in a companion switch power adapter such as described above in reference to FIG. 1. If a control circuit of the primary switch power adapter does not determine that a switching control module is in the primary switch power adapter, it can communicate over the traveler to the switching control module and indicate that the switching control module is in a companion switch power adapter, in which case the switching control module would not need to toggle its switch (i.e. TRIAC or relay). Whenever the switching control module is removed or power is lost, it could return to a default state. When power is returned, the control circuit of the primary switch power adapter would again determine the location of the switching control module.

If switching control modules are in both the primary switch power adapter and a companion switch power adapter as described in FIG. 31, the switching control modules can communicate with each other. If a switching control module determines that it is in the primary switch power adapter, it can send a signal on the traveler to the other switching control modules to indicate that they are companion switching control modules. According to some implementations, if the switching control module is in a primary switch power adapter, it can provide signals to the other control modules that it is the master control module, and the other control modules are controlled by the master control module. The other control modules may then operate only for transmitting signals. For example, if the other control module is a switching control module, it may hold its relay in a fixed state, such as in an open circuit state.

The switching control modules could also include circuits which could detect currents or voltages to determine whether current is being driven by the relay when the relay is closed (i.e., able to drive current). If the switching control module is not driving current, it can determine that it is in a companion switch power adapter, and therefore would only send command signals and keep the relay in an idle state (i.e., the relay is open and therefore not driving current to a load or driving current to maintain a relay in a certain state).

A control module can send its own signals that identifies it as the sender of a signal, which would help identify whether a switching signal is received from another control module than the control module that is in the primary switch power adapter and performing the switching.

The control modules can be implemented to determine the state of power applied to a load. For example, a control module that determines that it is used for switching the power to the load (i.e., in a single pole power adapter or in a primary switch power adapter) can toggle its switch (e.g., a relay or TRIAC) rather than just sending a switching signal on the traveler (i.e., as a control module in a companion switch power adapter would operate). The switch on the power adapter could also send dedicated ON or OFF signals rather than a simple toggle (i.e., change of state signal).

A user can set whether a switching control module is in a primary switch power adapter or companion switch power adapter on the control module itself, for example using a manual slide switch on the control module (i.e., slide between a primary switch setting or a companion switch setting) enabling a user to select a master functionality or a companion functionality for the switching control module.

According to another implementation, the switch control modules can detect current passing through the relay when the relay is closed, enabling the switching control module to determine that it is in a primary switching power adapter.

Turning now to FIGS. 33-38, various power adapters may be implemented to enable a user of the power adapter to identify the type of power adapter, which may be necessary for the user to place a control module in the correct power adapter for the control module to operate properly. According to some implementations, it may be beneficial to place a certain type of control module in a certain type of power adapter. That is, both a manufacturer of power adapters and control modules and a homeowner may benefit from an inexpensive and reliable designation of a power adapter type for single pole, primary and companion switch power adapters, and the flexibility in using control modules.

Because all three types of switch power adapters (i.e., a single pole power adapter and a primary switch power adapter and companion switch power adapter of a multi-way system) are different, a manufacturer can provide an indication on the power adapter of the type of power adapter, which benefits both an electrician during the installation process and a homeowner in using a system having modular switches and outlets. According to one implementation, the manufacturer can apply a sticker or other designation such as through the use of a printing technique on the switch power adapter that would be visible to the homeowner to indicate the type of switch power adapter. It should be noted that, if the switch power adapters were not different or not designated as being different, it would be necessary for a home builder to rely upon an electrician installing the switch power adapters to indicate the function of the switch power adapter. According to another implementation, if the inside of the switch power adapter is white plastic, the type of power adapter could be in raised black letters for example, which would make it clear what type of power adapter it is.

According to some implementations, an indicator element, such as an LED could provide light to a light guide in the housing of a switch power adapter. A single pole switch power adapter may not have any type of LED because of the expense associated with implementing the LED. However, an LED could be more easily implemented in a primary or companion switch power adapter if they have a printed circuit board. The LED may provide a certain color indicating the type of switch power adapter, or lead to a clear or translucent piece of material or lens, such as a plastic material, that will indicate “Primary” or “Companion” for example. That is, rather than having a light guide from an LED to a small lens on the power adapter housing, a larger lens with “Primary” or “Companion” written on it could be used. For example, the lens could be clear plastic with black lettering indicating “Primary” or “Companion”. The LED may be different color LED to indicate the type of switch power adapter. The switch power adapter manufacturer benefits by being able to provide a clear indication that a switch power adapter in a multi-way circuit is a primary switch power adapter or a secondary switch power adapter. A lighted “power adapter-type lens” is not only permanent, but very clear to a homeowner.

By providing a lighted power adapter-type lens, the manufacturer can provide a single control module in a situation where a control module is to be used in the primary switch power adapter (e.g., a dimmer in a primary switch power adapter). For example, the manufacturer can provide low-cost simple dimmer control modules. If the manufacturer is able to easily and reliably provide an indication of the type of power adapter to the homeowner, the manufacturer may determine that it is beneficial to the homeowner to provide the homeowner with different dimmer control modules that would be inserted in each of the bases of a multi-way switching arrangement (e.g., a first dimmer module to be used in a primary switch power adapter that controls power to the load and a second dimmer module for a companion switch power adapter that provides dimming control signals to the first dimmer module). However, such a solution may be costly for both the manufacturer to stock separate modules and inconvenient for the homeowner who would lose the flexibility of being able to move dimmer modules to different locations. If the manufacturer can provide a cheap, reliable, homeowner-friendly indicator of the primary switch power adapter and companion switch power adapters, the manufacturer may be confident that there will be no customer confusion for placing the dimmer module at a particular location in a multi-way circuit.

Further, the homeowner benefits by only having to buy one control module, rather than a pair of control modules, when a control module is required to be placed in a certain location (e.g., a dimmer control module that needs to be in a primary switch power adapter). This solution also relates to a 4-way switching arrangement for a dimmer control module for example. If the manufacturer does not provide a designation of the primary switch power adapter, it would be necessary for the manufacturer to rely upon a homeowner to move the dimmer control module around to find the actual location of the primary switch power adapter to receive the dimmer control module, or to buy the same number of dimmer control modules as the number of power adapters (e.g., 3 dimmers for a 4-way switch).

According to some implementations, the multi-way switch designation and an error detection indicator can be a part of the same LED/Light guide (e.g., the light guide to the power adapter-type lens, where the error detection would be indicated by color of the LED, such as green for correctly wired and red for incorrectly wired for example), as will be described in more detail below.

According to one implementation, a low-cost option would be to put one or more LEDs (e.g., separate error detection and power adapter-type designation or one LED for combined error detection) in the primary switch power adapter only. In this case, it may be beneficial to provide a clear indication of the type of power adapter for a single and companion switch, even if it is just with a sticker or some other marking. Optimally, an LED would only be lit when there is an error.

Turning first to FIG. 33, a perspective view of a power adapter 3301 having an external indicator element 3302 is shown. The power adapter may comprise a switch actuator element 3304 and a plurality of contact elements 3306 in a recess 3308 adapted to receive a control module. According to the implementation of FIG. 33, an indicator element 3302, which may be an LED or a light guide for routing light from an LED of the power adapter, may be included to provide a status signal, including for example a status signal associated with a correct or an incorrect wiring condition. It should be understood that the indicator element 3302 may be visible when both a control module is inserted into the recess and the wall plate is attached to the power adapter.

Turning now to FIG. 34, a perspective view of a power adapter 3401 having an internal indicator is shown. According to the implementation of FIG. 33, an indicator element 3402, which may also be an LED or a light guide for routing light from an LED of the power adapter, may be provided in a location that is not visible to the user, such as in a recess adapted to receive a control module, where the indicator element would only be visible when the control module is removed from the recess. The indicator element may be included to provide a status signal, including for example a status signal associated with a correct or an incorrect wiring condition. The power adapter 3401 may also comprise a switch actuator element 3404 and a plurality of contact elements 3406 adapted to receive contact elements of a control module received in a recess 3408. While the power adapters 3301 and 3401 are shown by way of example, it should be understood that the implementation and the features of the power adapters could be implemented differently.

Most electricians may be familiar with wiring conventional 3-way switches, where power signals are transmitted over 2 travelers, but may not be as familiar with wiring a 3-way switch or other multi-way switch using a single traveler to send communication signals. Unlike wiring a conventional 3-way switch where the 2 travelers can be connected to either of the 2 traveler contacts of the switches, in an arrangement having a single traveler, such as in the 3-way switching arrangement of FIG. 22 for example, the single traveler wire must be connected to the single traveler contact on each of the primary switch power adapter and the companion switch power adapter in the multi-way switching arrangement. A potential wiring error may arise because of the color of the wires in a wiring bundle used by an electrician. That is, it may be the case that both the wire for routing the line voltage to the primary switch power adapter and to the companion switch power adapter and the wire for connecting the traveler contact elements may be the same (e.g., both may be black).

According to some implementations, circuits can be provided in one or both of the primary switch power adapter and the companion switch power adapter for detecting an improper wiring condition.

According to some implementations, circuits can be provided in one or both of the primary switch power adapter and the companion switch power adapter for detecting a high voltage condition where the traveler contact element is connected to the line voltage.

According to some implementations, circuits can be provided in one or both of the primary switch power adapter and the companion switch power adapter for detecting a low voltage condition where the traveler contact element is connected to a neutral or ground voltage.

According to some implementations, a DC signal can be provided on the traveler to enable detecting when the traveler is grounded. That is, unless the DC signal is detected, the traveler contact element may be determined to be grounded.

According to some implementations, circuits can be provided in the primary switch power adapter that will detect a wiring error on the traveler and send a signal to the companion switch power adapter indicating an error. The error signal could be sent wirelessly or as a sub-carrier signal on the traveler wire.

According to some implementations, a common wiring error may be on the traveler, where the traveler is pulled to 120 V or 0 V (e.g. ground/neutral). However, circuits could also be provided for detecting other wiring errors.

According to some implementations, an indicator element, such as an LED, could be provided to indicate an error. The LED could be on the switch portion so that it is visible to a homeowner when the control module is attached, or could be inside the recess for receiving the control module and visible only when the control module is removed, as described above in reference to FIGS. 33 and 34. The LED could be a multi-color LED, where the color of the light emitted when there is a wiring error could indicate the type of wiring error, and/or could blink in a certain pattern to indicate the type of wiring error.

According to some implementations, separate primary and companion switch power adapter error detection solutions could be provided. According to this implementation, the voltage detection circuits in the primary switch power adapter and the companion switch power adapter may act independently. The circuits in each power adapter will independently detect an improper wiring condition, such as based upon a detected voltage of the traveler. That is, the primary switch power adapter does not need to be connected to the companion switch power adapter by the traveler for either of the power adapters to detect a wiring error.

According to some implementations, the circuits for detecting high voltage or low voltage conditions could be the same in both the primary switch power adapter and the companion switch power adapter.

According to some implementations, a high voltage detection circuit may be implemented. For example, a high voltage detection circuit may include a circuit coupled between the traveler and ground or neutral, where current would only flow and turn on an LED when the voltage on the traveler is greater than a predetermined value, indicating that the traveler is improperly wired (e.g., near 120 V or 220 V). The traveler voltage range for sending signals on the traveler may be set to be below 120 V to ensure that an abnormally high voltage on the traveler is detected.

According to some implementations, a low voltage detection circuit may be implemented in place of or in addition to a high voltage detection circuit. For example, a DC voltage applied to the traveler may be set at a level high enough that a low voltage condition (e.g., the voltage level of ground or neutral, which may vary by approximately 1 volt), can be detected. That is, a fixed DC voltage applied to the traveler (i.e., a DC offset) can be selected to ensure that a connection of the traveler to either the ground potential or neutral potential can be detected, and a circuit provided to detect when the traveler is at an abnormally low value.

The traveler voltage range may be set above the voltage that may be detected on either the ground or neutral contact to ensure that an abnormally low voltage on the traveler range would be detected. If the difference between the ground and the neutral contact is 1 V or less, the DC offset on the traveler could be set at 2 V for example. Therefore, when the voltage on the traveler is between 0 and 1 V, it could be determined that the traveler contact element of the power adapter is improperly coupled to either the ground or neutral line rather than the traveler line between the primary switch power adapter and a companion switch power adapter.

According to some implementations, a primary switch power adapter could control the detection of a wiring error. According to this implementation, a voltage detection circuit in the primary switch power adapter may send a signal to the companion switch power adapter by way of the traveler if there is an error. Multiple error detection circuits (e.g., both abnormal high voltage and low voltage detection circuits) may be provided in the primary switch power adapter.

A detection circuit (for either or both high and low voltage detection) of the companion switch power adapter may not be necessary, but rather a simple detection circuit for detecting an error signal from the primary switch power adapter on the traveler may be provided. That is, if there is an error detected at the primary switch power adapter, there may be a wiring error for both the primary switch power adapter and the companion switch power adapter. The error detected at the primary switch power adapter can be transmitted to the companion switch power adapter, and displayed on both the primary switch power adapter and the companion switch power adapter.

According to some implementations, an error indication (e.g., an LED emitting red light) could be provided on the companion switch power adapter if the traveler contacts of the primary switch power adapter and the companion switch power adapter are not connected to each other. That is, the companion switch power adapter will not receive the steady state signal (e.g., a DC offset) if the traveler contact elements are not connected by the traveler wire, and therefore an error indication will be provided on the LED.

For example, the primary switch power adapter may provide a signal on the traveler to the companion switch power adapter when the travelers are connected (e.g., 1 or 2 V DC Offset). For example, if an error is detected by one or more detection circuits on the primary switch power adapter, the error signal on the traveler can be provided (e.g., where the traveler is pulled high or low, and an error detection circuit in the companion switch power adapter will detect that signal (i.e., either a high or low signal generated by the primary switch power adapter)). The selection of pulling the traveler low or high could be selected based upon which detection circuit is easier to implement. It should also be noted that a voltage detection circuit in the primary switch power adapter may send a signal, other than just pulling the traveler to a high voltage or a low voltage, to the companion switch power adapter.

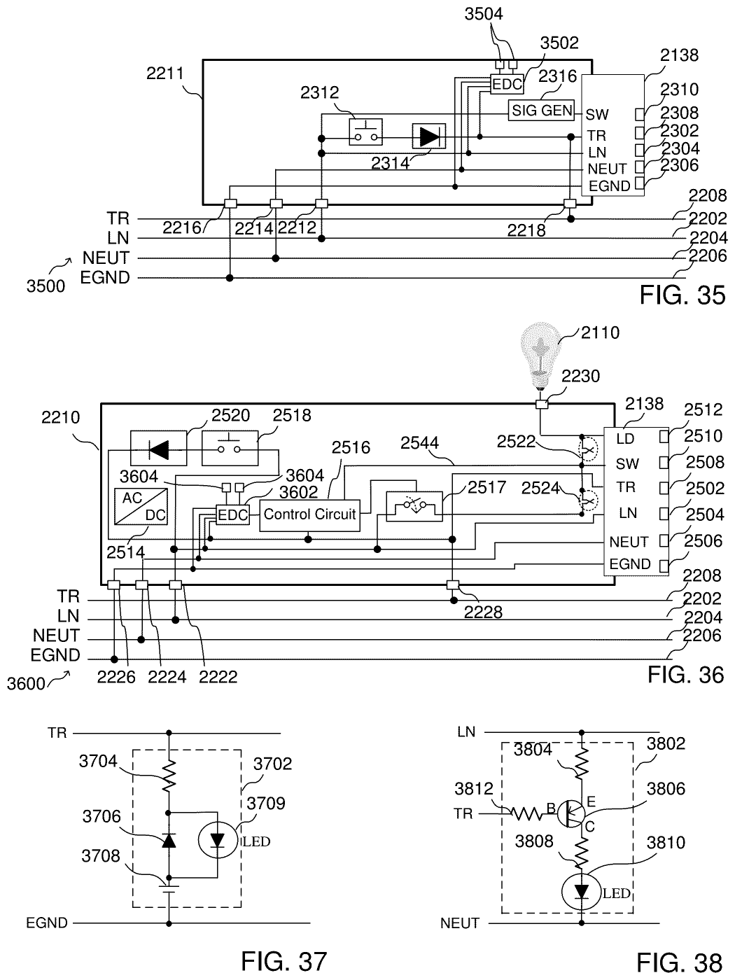

Turning now to FIG. 35, a block diagram of a power adapter 3500 configured to be implemented as a companion switch power adapter in a multi-way wiring arrangement and having an error detection circuit (EDC) is shown. According to the implementation of FIG. 35, an error detection circuit 3502, which may detect a wiring error condition, will be described in more detail below. The error detection circuit may be coupled to indicator elements 3504, which may be implemented as indicator elements 3302 and 3402 as described above, such as any audible or visual indicators. Example functions of the error detection circuit 3502 will be described in more detail below.

Turning now to FIG. 36, a block diagram of a power adapter 3600 configured to be implemented as a primary switch power adapter in a multi-way wiring arrangement and having an error detection circuit is shown. The power adapter 3600 comprises, according to the implementation of FIG. 36, an error detection circuit 3602, that may detect a wiring error condition as will be described in more detail below. The error detection circuit may be coupled to indicator elements 3604, which may be implemented as indicator elements 3302 and 3402 as described above. While two indicator elements 3604 are shown by way of example and may be used to show different error conditions, additional indicator elements could be implemented, or a single indicator element could be implemented, where different colors of a multicolor LED and different flashing patterns could be used to indicate different errors. Example functions of the error detection circuit 3602 will be described in more detail below.

While shown for both the power adapter 2210 in FIG. 35 and power adapter 2211 in FIG. 35, it should be understood that the error detection circuit may be implemented in both or in only one of the two types of switch power adapters in a multi-way wiring arrangement to indicate an error in the wiring of the multi-way switching arrangement. According to some implementations, an error detection circuit may send a signal on a traveler line to disable a power adapter. According to some implementations, by disabling a power adapter, the power adapter may not function properly, such as preventing power from being applied to a load.

Turning now to FIG. 37, a block diagram of a high voltage detection circuit 3702 that may be implemented in the error detection circuit of FIG. 34 or 35 is shown. The high voltage detection circuit 3702 comprises a series of elements coupled between the traveler and a reference voltage, such as a neutral or ground voltage, and may include a resistor 3704, a diode 3706 and a capacitor 3708 as shown. An indicator element 3709, shown here by way of example as a light emitting diode (LED) is coupled across the diode 3706.

According to some implementations, the values of the components can be selected so that the current only flows and the LED emits light when the voltage on the TR contact element of the power adapter exceeds a certain value. While the circuit of FIG. 37 is shown by way of example, it should be understood that other high voltage detection circuits could be implemented.

Turning now to FIG. 38, a block diagram of a low voltage detection circuit 3802 that may be implemented in the error detection circuit of FIG. 34 or 35 is shown. A series of elements is coupled between the line contact element and a reference contact element, which may be a neutral or ground contact element, for example. More particularly, a resistor 3804, a transistor 3806, shown here by way of example as a bipolar junction transistor (BJT), a resistor 3808, and an indicator element 3810 are coupled in series between the line contact element and a reference voltage. A resistor 3812 is coupled between the traveler (TR) contact element and a base of the transistor 3806. The values of the components of FIG. 38 could be selected so that if the voltage on the TR contact element that is coupled to the base of the transistor is low, the transistor would turn on and the current in the LED will cause light to be admitted by the LED. That is, the circuit of FIG. 38 could be used to indicate if the traveler is unintentionally pulled to a ground voltage or a neutral voltage.

While the circuits of FIGS. 37 and 38 are provided by way of example to show circuits for detecting a low voltage or high voltage respectively, it should be understood that other suitable circuits could be implemented. It should also be understood that the high voltage and low voltage detection circuits can be implemented together with respect to a given node or contact element and can be implemented with multiple contact elements to enable a comparison of a contact element to a number of different other contact elements to detect any possible wiring error.

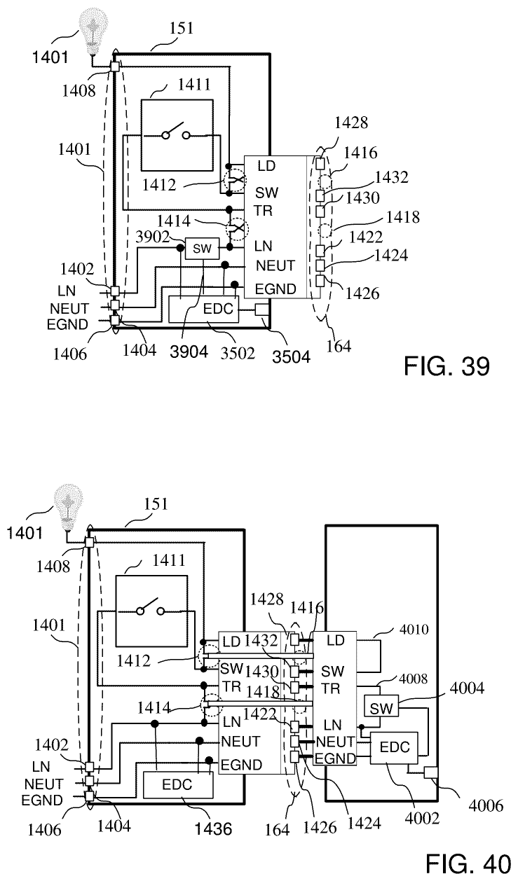

Turning now to FIG. 39, a block diagram of a power adapter comprising an error detection circuit and a switch for disabling the power adapter is shown. The implementation of the circuit of FIG. 39 is similar to FIG. 14 and may include an indicator element 3504 such as an LED coupled to the error detection circuit 3502. A switch 3902 is provided to prevent the line voltage from being supplied to other parts of the circuit, and particularly the contact element 1408 coupled to a load. The error detection circuit 3502 provides a control signal to the switch 3902 by way of a control signal line 3904. By disabling the load (i.e., preventing the application of power to the load), an electrician, builder or homeowner will not only see the error indicator associated with the wiring of the power adapter, but also be aware of a wiring error because the light (i.e., load) does not receive power (i.e., is not lit).

Turning now to FIG. 40, a block diagram of a power adapter arrangement having a control module comprising an error detection circuit and a switch for disabling the power adapter is shown. According to the implementation of FIG. 40, the error detection circuit and switch for disabling the load are located in the control module. More particularly, the error detection circuit 4002 is coupled to the line, neutral and ground contacts to determine if there is a wiring error based upon detected voltages. The error detection circuit 4002 is coupled to a switch 4004 to disable the power adapter 151 by preventing the application of power to a load by preventing the line voltage from being provided to the traveler contact element by way of the line 4008, and to an error indicator element 4006 to indicate the existence of a wiring error to a user of the power adapter. The control module further comprises a line connect from the switch 4004 to the traveler contact element. According to the implementation of FIG. 40, a line connector 4010, which may be a jumper or a trace on a printed circuit board for example, is provided between the switch and the load contact element.

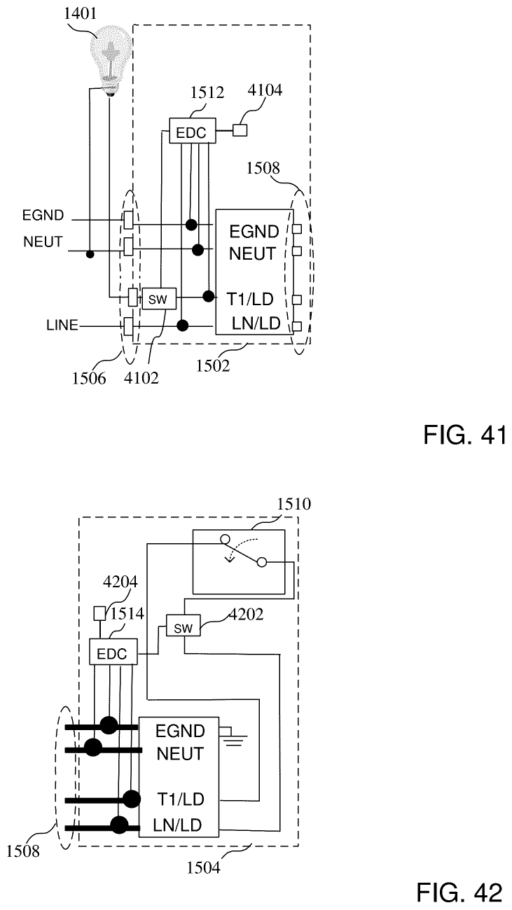

FIGS. 41 and 42 are directed to the use of switches to disable the power adapter (i.e., block the application of power to a load) in a power adapter that, unlike the power adapter of FIG. 39 having a switch 1411, does not have a switch for controlling the application of power to a load, but relies upon a switch in the control module for controlling the application of power to a load. As will be described in detail in reference to FIGS. 41 and 42, an error detection circuit and corresponding switch and error indicator element can be implemented in either the power adapter or the control module. Turning first to FIGS. 41, a block diagram of a power adapter having an error detection circuit 1512 coupled to a switch 4102 for disabling the power adapter and an error indictor element 4104, such as an LED, is shown. As can be seen in FIG. 41, the error detection circuit may be coupled to each of the line, neutral, ground, and load contact elements and is adapted to control the switch 4102 to prevent the application of power to the load. The error indicator element may also be used to provide visual indication to the user of the power adapter.

Turning now to FIG. 42, a block diagram of a control module adapted to be attached to the power adapter of FIG. 41, having an error detection circuit and a switch for disabling the power adapter is shown. More particularly, a switch 4202 is controlled by the error detection circuit 1514 and controls the application of power to the switch 1510, and thereby disabling the application of power to a load in the event of the detection of an error, such as a wiring error. An error indicator element 4204, such as an LED for example, may also be used to provide an indication to the user of the power adapter. The error detection circuits of FIGS. 14-17 and 35-42 may be used to detect various wiring error conditions, such as a neutral connection missing, line and neutral wires swapped, line and load wires swapped, line and traveler wires swapped, neutral and load wires swapped, neutral and traveler wires swapped, load and traveler wires swapped, for example, as described in more detail below.

According to one implementation, an in-wall power adapter adapted to receive a module and adapted to provide power to a load may comprise a plurality of contact elements adapted to be coupled to wires of a junction box; an error detection circuit coupled to one or more contact elements of the plurality of contact elements, wherein the error detection circuit is adapted to detect a wiring error; and a user interface adapted to provide an indication of a detected wiring error.

According to another implementation, an in-wall power adapter adapted to receive a module and adapted to provide power to a load may comprise a plurality of contact elements adapted to be coupled to wires of a junction box; a switch element configured to route a line voltage to a load; an error detection circuit coupled to one or more contact elements of the plurality of contact elements, wherein the error detection circuit is adapted to detect a wiring error; and a user interface adapted to provide an indication of a detected wiring error.

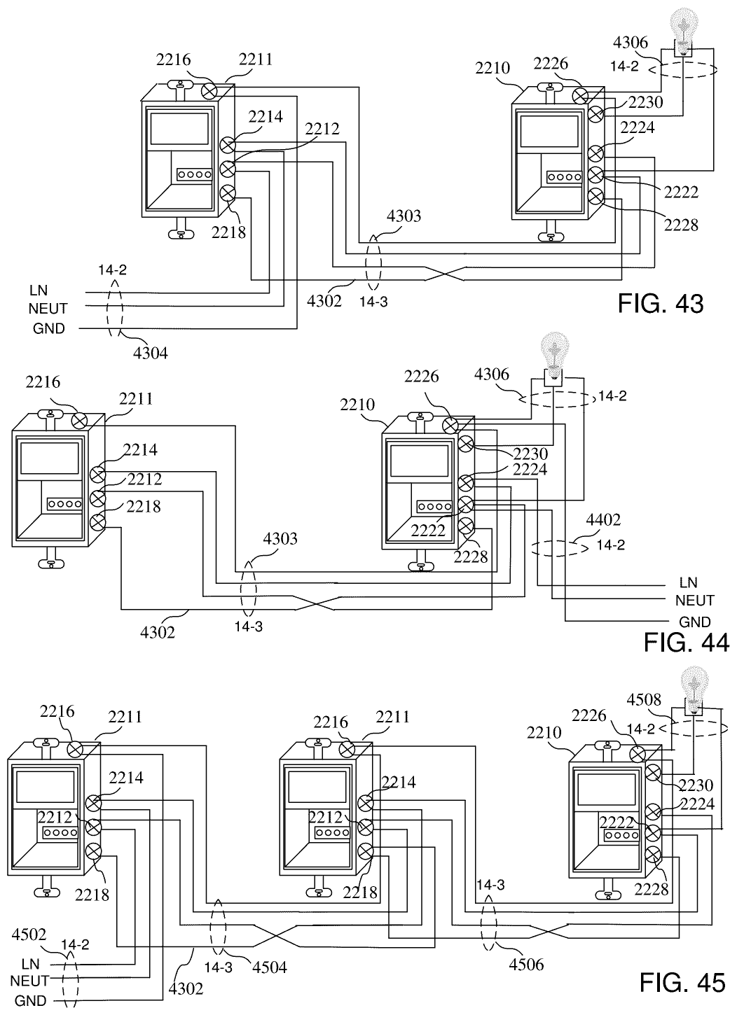

FIGS. 43-44 are provided to show examples of crossed line and traveler wires between power adapters, such as between a primary power adapter and a companion power adapter, where the line voltage is provided to a companion switch power adapter and a primary switch power adapter in a 3-way switching arrangement. Turning first to FIG. 43, a block diagram of a primary power adapter and a companion power adapter connected in a first wiring configuration is shown. More particularly, the power adapter 2210 that controls the application of power to the load and the power adapter 2211 that provides control signals for controlling the application of power to a load to the primary power adapter may communicate by way of a traveler connection 4302 of a group of wires 4303. The type of wires into and out of the elements of FIG. 43 are provided by way of example in FIG. 43, and include a first group of wires 4304, designated as a 14-2 group of wires, a second group of wires 4303, designated as 14-3 group of wires, and a third group of wires 4306, designated as 14-2 group of wires. A designation of 14-2 generally indicates 14 American Wire Guage (AWG) wire and 2 wires (other than a ground wire which is also a part of the group and may be an unshielded wire for example) for line and neutral connections. A designation of 12-3 generally indicates 12 AWG wire and 3 wires (other than a ground wire which is also a part of the group) for line, neutral and traveler connections. That is, some wiring applications may require that 12 AWG wire is used, such as for outlets rated at 20 Amps. Although not shown in FIGS. 43-47, 12 AWG wire may be used in some of the groups of wires. Because the line and traveler wires are “crossed,” the line voltage from the companion power adapter (that is brought into the power adapter 2211 at the line contact element 2212) is routed to the primary power adapter by way of the group of wires 4303 is provided to the traveler contact element 2228 (rather than the line contact element 2222) of the primary power adapter. According to this wiring configuration, not only will the primary power adapter be able to detect the line voltage on the traveler contact element, using for example a circuit as shown in FIGS. 37 and 38, but the primary power adapter will not be able to provide power to the load, providing a second indication of a wiring error (in addition to an LED indicator for example) to alert an electrician, builder or homeowner that there is a wiring error. That is, an error detection circuit of a power adapter may show that a wiring error exists and the type of error. Alternatively, a test module having an error detection circuit may show that a wiring error exists and the type of error.

Turning now to FIG. 44, a block diagram of a primary power adapter and a companion power adapter connected in a second wiring configuration is shown. According to the implementation of FIG. 44, the line voltage is routed to the primary power adapter by way of a group of wires 4402 and routed to the companion power adapter by way of the group of wires 4303. Because the primary power adapter will receive the line voltage at the line contact element 2222, the primary power adapter will be able to provide power to the load. Accordingly, the arrangement of FIG. 44 may not be preferred because the second indication of a wiring error (i.e., the disabling of power provided to the load) for a swapped line/traveler in the wiring configuration of FIG. 43 is not present. However, the line voltage can be provided to the traveler contact element 2218 of the companion power adapter of the implementation of FIG. 44, and therefore an error detection circuit of the companion power adapter, such as the error detection circuit of FIGS. 37 and 38 or some other appropriate circuit, will provide an indication that there is a wiring error in the wiring of the 3-way switch, and particularly in the wiring of the companion power adapter. An error indicator light may indicate the location of the wiring error (i.e., in either the primary power adapter, the companion power adapter, or both) because a test module in a given power adapter will detect a wiring error associated with that power adapter.

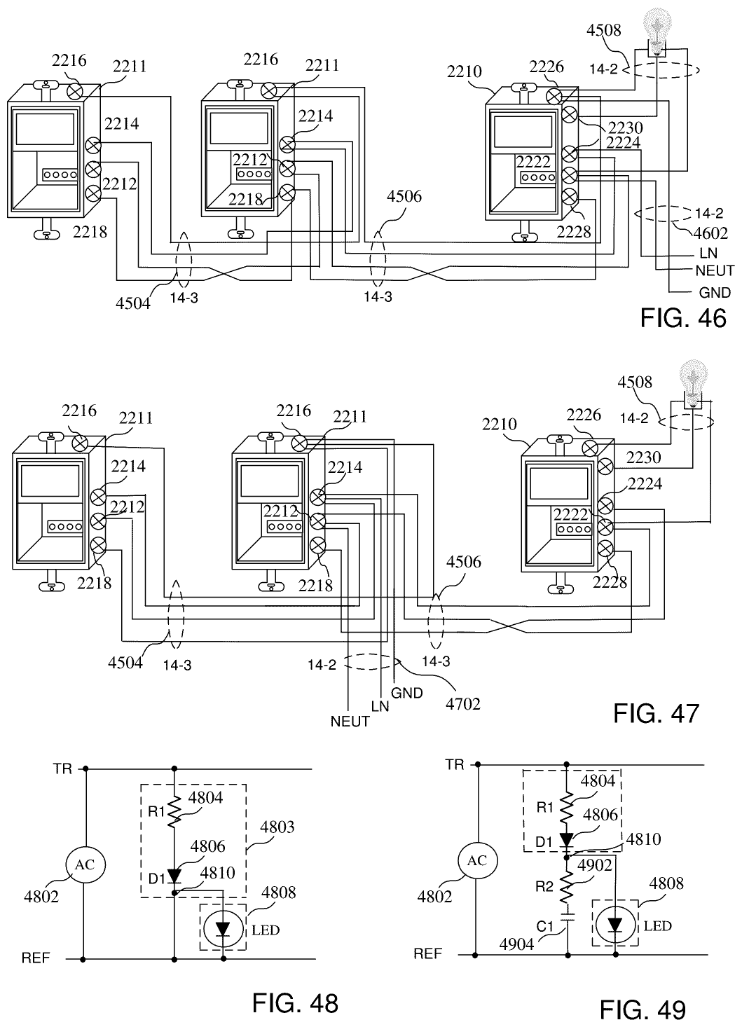

FIGS. 45-47 are provided to show examples of crossed line and traveler wires between power adapters where the line voltage is provided to a companion switch base or a primary switch base in a 4-way switching arrangement. Turning first to FIG. 45, a block diagram of a primary power adapter and two companion power adapters connected in a first wiring configuration is shown. According to this wiring configuration, the line voltage is routed to the power adapters at the first companion power adapter by way of the group of wires 4502 as shown, which is similar to the arrangement of FIG. 43. In this wiring arrangement, there may also be swapped line and traveler wires at two locations. If only one of the groups of wires 4504 and 4506 have swapped line and traveler wires, the line voltage will be provided to the traveler contact element 2228 of the primary power adapter, in which case the primary power adapter will not operate. Also shown in FIG. 45 is a group of wires 4508 providing line power to the load. In addition to the possibility that the primary power adapter may be disabled if a line and traveler are swapped in one of the groups of wires, this arrangement is also the preferred wiring arrangement compared to the wiring arrangements of FIGS. 46 and 47 because only two wires ever need to be electrically connected to a given terminal (e.g., a screw terminal or wire) of the power adapter. An error detection circuit and corresponding LED will also provide an indication of the location of the wiring error (i.e., which power adapters wired incorrectly).

Turning now to 46, a block diagram of a primary power adapter and two companion power adapters connected in a second wiring configuration is shown. According to the implementation of FIG. 46, the line voltage is routed to the plurality of power adapters by way of the group of wires 4602 as shown. If the line and traveler are swapped in the first group of wires 4506, the line voltage will be provided to the traveler terminal of the middle power adapter 2211 and an error detection circuit will indicate an error in the wiring to that terminal. If the line and traveler are swapped in the second group of wires 4504, the line signal will be provided to the first power adapter in the string of power adapters 2211 as shown and an error detection circuit will provide an indication of the error. If the line and travelers are swapped, the middle power adapter will indicate a wiring error, such as by way of an error indicator element.

Turning now to 47, a block diagram of a primary power adapter and two companion power adapters connected in a third wiring configuration is shown. In this configuration, the line voltage is brought in through a group of wires 4702. In this arrangement, if the line and traveler wires are swapped in either of the groups of wires 4504 and 4506, the line voltage will not be applied to the line terminal of the power adapter 2210 and line voltage cannot be applied to the load. An error detection circuit of one of the power adapters 2211 will indicate the location of the error. If the line and traveler are swapped in both the groups of wires 4504 and 4506, the line voltage may be applied to the line terminal of the power adapter 2210, but an error indicator circuit of each of the companion power adapters will indicate an error. It should be understood that the wiring errors of FIGS. 43-47 are provided by way of example to describe some types of wiring errors for purposes of describing how wiring errors may occur and how a test module may detect a wiring error, and it should be understood that other wiring errors could occur and be detected by a test module, as will be described in more detail below.

Turning now to 48, a block diagram of a circuit for detecting when a line voltage is connected to a traveler contact element of a power adapter is shown. The circuit for detecting when the line voltage generator 4802, shown by way of example as an AC source between line and a reference voltage, such as neutral or ground, is applied to the traveler contact element of a power adapter comprises a detection circuit 4803 which may generate a DC voltage that can be used to turn on an error indicator element that may provide an audible or visual indication of the wiring error (e.g., line voltage being unintentionally applied to a traveler). The detection circuit 4803 may comprise a resistor 4804 coupled in series with the rectifier diode 4806 to provide a DC voltage at an input of an error detection element 4808. The value of the resistor is selected to ensure that the voltage at the node 4810 will turn on the error detection element over an expected range of line voltage values (e.g. between 105 V and 135 V for an expected 120V signal).

According to the implementation of FIG. 49, a resistor 4902 may be added to select the correct voltage at the node 4810 and a capacitor 4904 may be added to prevent any current from being drawn when the line voltage is applied to the traveler terminal. That is, when a control signal is normally applied to the traveler, the voltage generated at node 4810 will not turn on the error detection circuit and no current will flow in the circuit. Therefore, while the circuit will provide the benefit of indicating an error, no current will be drawn and no power will be consumed when the error is detected.

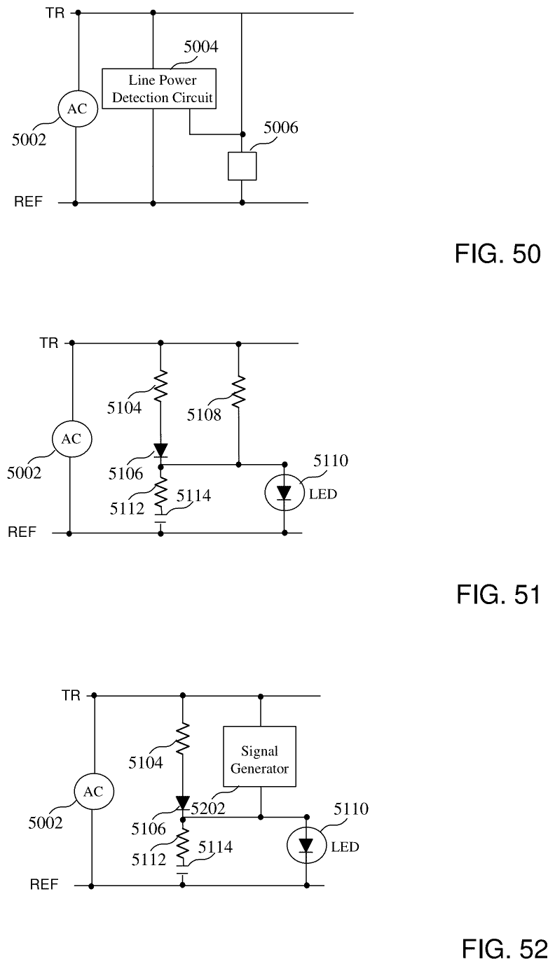

Turning now to FIG. 50, a block diagram of a circuit for detecting when a line voltage is connected to a traveler contact element and for providing an error signal according to a first implementation is shown. According to the circuit of FIG. 50, line voltage 5002, shown by way of example as an AC source between line and a reference generator voltage such as ground, is unintentionally provided to the traveler contact element. A line power detection circuit 5004 is coupled to the traveler contact element and provides an output to an error detection element 5006. The line power detection circuit 5004 may comprise a device that will provide an audible or visual indication of the error or some other user feedback signal in response to the detection of the line voltage. The signal generated by the line power detection circuit 5004 may also be applied to the traveler to provide an indication of the error to other power adapters in a multiway wiring arrangement, and particularly a primary power adapter that applies power to a load. By way of example, the signal provided on the traveler could be a signal that is superimposed on the line voltage signal that is unintentionally on the traveler wire.

Turning now to FIG. 51, a block diagram of a circuit for detecting when a line voltage is connected to a traveler contact element and providing an error signal according to a second implementation is shown. The line power detection circuit 5004 may comprise a resistor 5104 and a diode 5106 to generate the DC voltage that may be applied to a resistor 5108 to provide a traveler feedback signal and to the error detection element 5006, shown here by way of example as a light emitting diode (LED) 5110. A resistor 5112 and a capacitor 5114 can be added to select a desired voltage to the light emitting diode and prevent any flow of current in the circuit when the LED is not on.

Turning now to FIG. 52, a block diagram of a circuit for detecting when a line voltage is connected to a traveler contact element and providing an error signal according to a third implementation is shown. According to the implementation of FIG. 52, a signal generator 5202 may be included to provide a traveler signal that provides information beyond the presence of an error and may include for example the identity of the power adapter or other information that may be used by another power adapter, such as a primary power adapter.

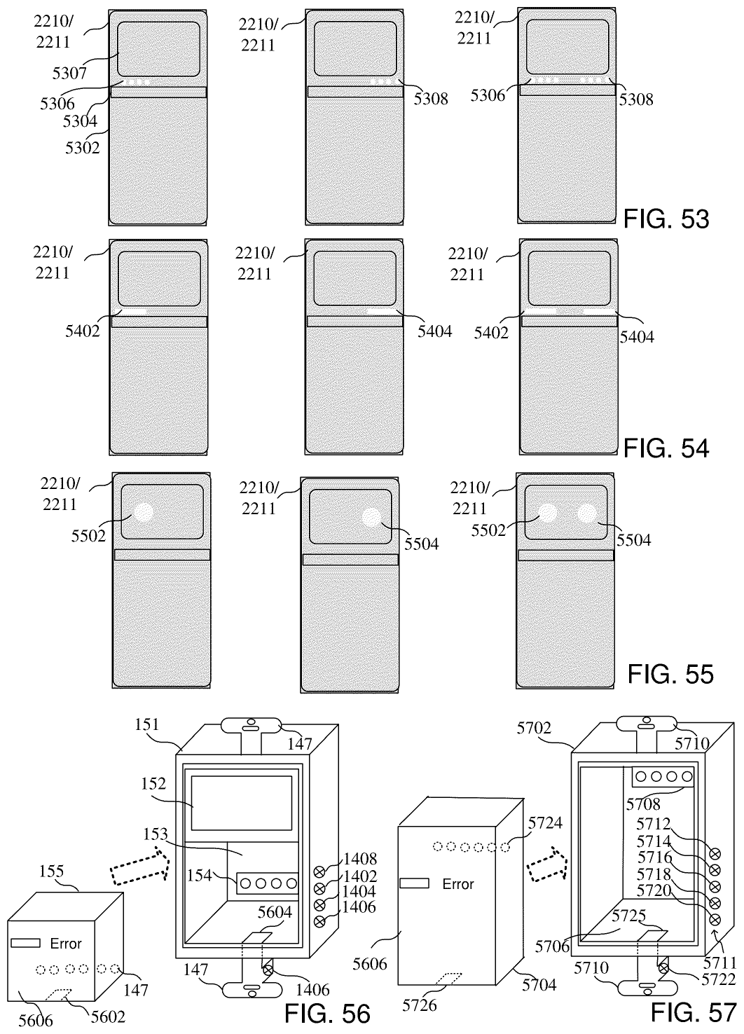

Turning now to FIG. 53, a series of power adapters having two error indicator elements showing three different error states according to a first implementation is shown. The power adapters of FIG. 53 may comprise a power adapter 2210 implemented as a primary power adapter or a power adapter 2211 implemented as a companion power adapter, and may be coupled to a control module 5302 and a latch 5304. The power adapter may include one or more error detector indicators to provide an indication of one or more errors, such as no neutral wire connection or a connection of line voltage to a traveler contact element as a result of a line/traveler swap condition. The error indicator element 5306 may be used to show a “no neutral connection” error in the first power adapter of the series. In the second power adapter of the series of power adapters, an error indicator element 5308 on the right side may be used to indicate a “line/traveler swap” error. The third power adapter in the series is provided to show an indication of both types of errors. According to the implementation of FIG. 53, the circles of error indicator elements 5306 and 5308 may be formed by a thinner plastic material to enable the light to emit through the plastic of the housing of the power adapter in that region. That is, the housing can be modified, eliminating the need for an additional element, such as a light guide. While the error indicators are shown below the switch actuator 5307 it should be understood that the error indicator elements could be placed above the switch element or on either side of the switch element. Also, a single error indicator could be used, where different errors could be provided by different colors emitted by an LED or a different type of flashing pattern signal for example. According to one implementation, a solid lit LED would indicate an error condition where the error needs to be corrected but the switch will still work, such as for a no neutral connection condition. Similarly, a flashing LED would indicate an error where the switch will not operate, such as a line/traveler swap condition.

Turning now to FIG. 54, a series of power adapters having two error indicator elements showing three different error states according to a second implementation is shown. According to the implementation of FIG. 54, light guides may be attached to or incorporated in the housing. As shown in the first power adapter of the series of power adapters, an error detection indicator 5402 is provided on the left side to indicate a first type of error, such as a no neutral connection error. As shown in the second power adapter of the series of power adapters, an error detection indicator 5404 is provided on the right side to indicate a second type of error, such as a line/traveler swap error. As shown in the third power adapter of the series of power adapters, the error detection indicators 5402 and 5404 are lit on both sides to indicate that both types of error exist.

Turning now to FIG. 55, a series of power adapters having two error indicator elements showing three different error states according to a third implementation is shown. According to the implementation of FIG. 55, LEDs may be provided behind the switch actuator and may be visible when lit. As shown in the first power adapter of the series of power adapters, an error detection indicator 5502 is provided on the left side to indicate a first type of error, such as a no neutral connection error. As shown in the second power adapter of the series of power adapters, an error detection indicator 5504 is provided on the right side to indicate a second type of error, such as a line/traveler swap error. As shown in the third power adapter of the series of power adapters, the error detection indicators 5502 and 5504 are lit on both sides to indicate that both types of error exist.

According to some implementations, fan/shade/awning control modules may provide information to or interact with one or more of the home security/monitoring systems (generally referred to as a home monitoring system), HVAC, air quality, intercom/audio systems and interior and exterior lighting systems, for example. By way of example, the shades or awnings may be operated based upon the time of day or a weather forecast and may allow the HVAC system to modify its operation (e.g., lower a fan speed) because a reduced impact of sun on the internal temperature of the house.

Turning now to FIG. 56, a perspective view of a power adapter arrangement comprising a power adapter having a switch and a test module is shown. According to some implementations, the electrical interface may not include a ground contact element because it may not be necessary to provide a ground contact element to the control module. However, it may be beneficial to have a ground contact of the power adapter accessible to enable a test module to have a reference voltage to enable the detection of a no-neutral wiring condition. That is, when testing for a condition where the neutral wire is not connected to the power adapter (in which case a test module would not have a reference voltage for a circuit attempting to test for a no-neutral wiring condition), it may be beneficial to have access to a ground contact, which would provide a reference voltage. As shown in FIG. 56, module 155, which may be implemented with an error detection circuit (such as an error detection circuit described above in reference to FIGS. 37-38 and 48-52 for example or some other suitable error detection circuit), comprises a ground contact element 5602 that is adapted to be coupled to a ground contact element 5604 of a power adapter, shown here by way of example as power adapter 151. However, it should be understood that the ground contact element 5602 could be implemented in any type of module and the ground contact element 5604 could be implemented in any type of power adapter. A user interface 5606 is provided to show a correct wiring condition and one or more wiring errors that may be present. The presence of a wiring error may be indicated by an LED for example. The test module may also comprise a wireless communication circuit and provide error indications to a mobile device, such as a mobile phone for example. Although some wiring error conditions are shown, it should be understood that other wiring errors could be provided, as described below in reference to FIG. 64.

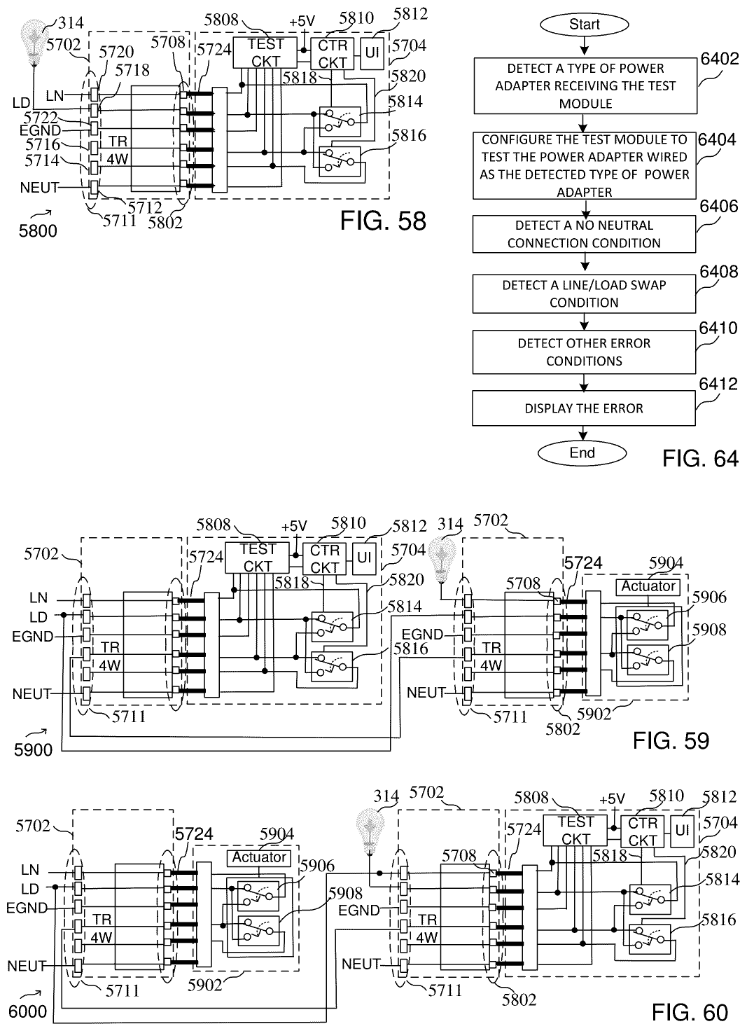

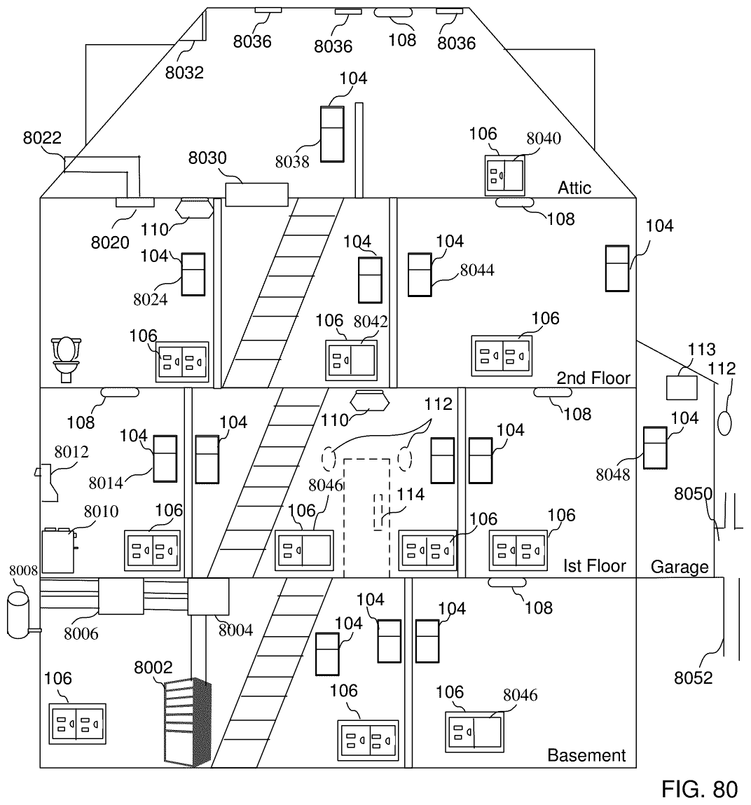

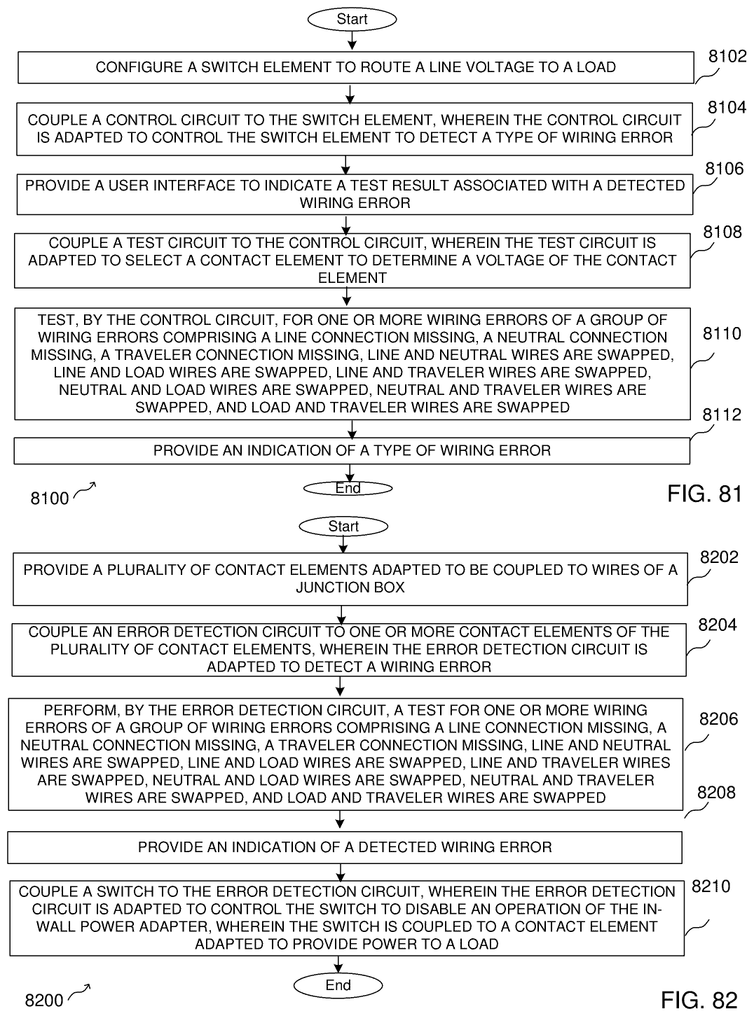

Turning now to FIG. 57, another perspective view of a power adapter arrangement comprising a power adapter and a test module is shown. The implementation of FIG. 57 is directed to a power adapter 5702 that does not comprise a switch actuator, but rather the switch actuator is a part of the control module 5704 that is adapted to be coupled to the power adapter 5702, such as is described above in reference to FIG. 41-42. The power adapter 5702 comprises a recess 5706 adapted to receive the control module 5704 and an electrical interface 5708 comprising a plurality of contact elements adapted to be electrically coupled to corresponding contact elements of the control module 5704. By way of example, a control module 5704 may comprise a control module having any functionality as described in reference to FIG. 1 or below in reference to FIGS. 80 and 81. The power adapter 5702 may also comprise flange elements 5710 adapted to being coupled to a junction box as described above, and a plurality of contact elements 5711 adapted to receive wires of a junction box. The plurality of contact elements 5711 may comprise a first contact element 5712 adapted to receive a neutral voltage, a second contact element 5714 adapted to receive a signal in a multiway wiring arrangement, a third contact element 5716 adapted to receive a traveler signal in a 3-way wiring arrangement, a fourth contact element 5718 adapted to be coupled to a load, a fifth contact element 5720 adapted to receive a line voltage, and a sixth contact element 5722 adapted to receive a ground voltage. The control module may comprise having an electrical interface 5724 comprising one or more contact elements adapted to be coupled to contact elements of the electrical interface 5708. However, it should be understood that the contact elements of the plurality of contact elements 5711 is shown by way of example, and a different number or combination of contact elements may be implemented. As described above in reference to FIG. 56, a contact element 5725 coupled to the ground voltage may be adapted to be coupled to a contact element 5726 of the control module 5704 to provide the ground voltage to the control module. Additional details related to the operation of a power adapter arrangement having a power adapter 5702 and a control module 5704 will be described in more detail in reference to FIG. 58.

Turning now to FIG. 58, a block diagram of the power adapter arrangement 5800 of FIG. 57 in a single pole arrangement is shown. More particularly, an electrical interface 5802 comprises the connection of the electrical interfaces 5708 and 5724 as shown. The control module 5704 comprises a test circuit coupled to each of the contact elements of the control module and may comprise a transformer to generate a DC voltage, shown here by way of example as a 5V DC voltage. A control circuit 5810 is coupled to the test circuit 5808 and a user interface 5812 and is adapted to control a first switch 5814 and a second switch 5816. The control circuit 5810 may comprise a processor for example, and may control the test circuit to detect a voltage on a given contact element of the power adapter (i.e., on a contact element of the electrical interface 5802). By way of example, the test circuit could be a multiplexer to route one or more selected signals to the control circuit. For example, the test circuit could be a 6-to-1 multiplexer to route a selected signal to an input of the control circuit or a 6-to-2 multiplexer to route two signals to two separate inputs of the control circuit. According to some implementations, the test circuit could be a logic device that is configurable to select one or more inputs as an output. According to other implementations, the control circuit may be coupled to each of the contact elements of the electrical interface 5802, eliminating the need for a test circuit. The user interface 5812 is also provided to enable a technician testing the wiring to perform certain tests and/or receive feedback related to the tests. A first signal line 5818 is coupled from the control circuit 5810 to the first switch 5814 to control the state of the first switch, which is adapted to receive the line signal at an input, and a second signal line 5820 is coupled from the control circuit 5810 to the second switch 5816 to control the state of the second switch, which is adapted to receive the signal on the contact element 5714.

The first switch 5814 and the second switch 5816 are configured to enable operation of a power adapter in a single pole wiring arrangement and are configured as a standard control module without a test circuit is configured, as will be described in more detail in reference to FIG. 60. In the first mode of operation, the first switch 5814 and the second switch 5816 are configured as shown, and in a second mode of operation, the first switch 5814 and the second switch 5816 are configured where both switches are in the other configuration (i.e., where both switches 5814 and 5816 are in the opposite state). That is, the switch element of both the first switch 5814 and the second switch 5816 would be toggled down from the current toggled up state as shown in FIG. 58. During a test operation, the first switch 5814 and the second switch 5816 can be separately controlled by the control circuit 5810 to (i) detect the type of power adapter into which the test module is inserted (e.g., a power adapter wired in a single pole wiring arrangement or in any location of a multiway wiring arrangement, as will be described in more detail below), and (ii) test for certain conditions based upon the detected type of power adapter.

Turning now to FIGS. 59 and 60, a block diagram of a pair of power adapter arrangements 5900 and 6000 in a 3-way wiring arrangement, where a test module is attached to a power adapter on the left receiving a line voltage is shown and a control module 5902 comprising a switch is attached to the power adapter on the right that provides power to the load. The control module 5902 operates as a switching element in a 3-way or 4-way wiring arrangement, and comprises an actuator 5904 that enables a user of the control module to change the state of the power applied to the load by controlling a first switching element 5906 and a second switching element 5908. According to the implementation of FIG. 59, the power adapter receiving the line voltage on the left as shown may be considered a companion power adapter and the power adapter on the right configured to provide power to the load may be considered the primary power adapter. As will be described in more detail below, a test module may be configured to detect which type of power adapter in which it is inserted and to identify any wiring errors.

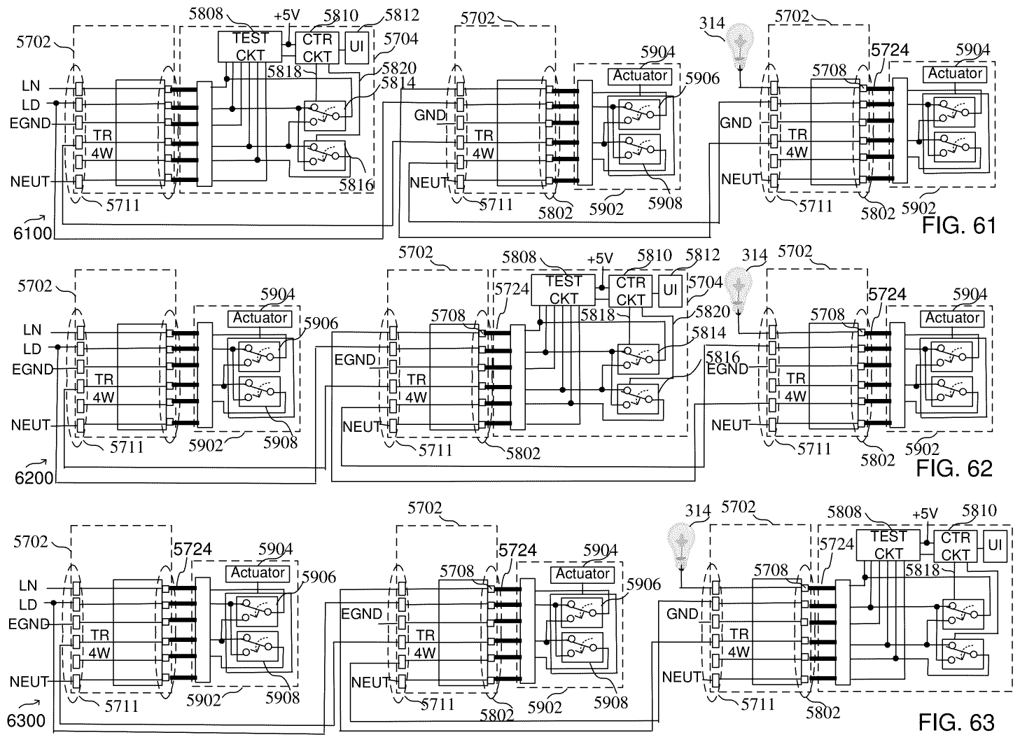

Turning now to FIGS. 61-63, block diagrams of 4-way wiring arrangements 6100, 6200, and 6300 having a test module 6002 in a first power adapter of the 4-way wiring arrangement are shown. The test module 6002 is placed in the companion power adapter in the wiring arrangement of FIG. 61, in the 4-way power adapter that is wired between the companion power adapter and the primary power adapter in the wiring arrangement of FIG. 62, and in the primary power adapter in the wiring arrangement of FIG. 63. According to some implementations, a power adapter may be determined to be a power adapter wired as a 4-way power adapter by detecting one or both of a voltage or a current on the 4-way (4 W) contact element of a power adapter. While a 4-way wiring arrangement is shown by way of example, it should be understood that any number of additional power adapters wired as a 4-way power adapter may be wired between the companion power adapter and the primary power adapter.

According to one implementation, an error detection module adapted to be attached to an in-wall power adapter may comprise a switch element configured to route a line voltage to a load; a control circuit coupled to the switch element, wherein the control circuit is adapted to control the switch element; and a user interface adapted to provide a test result associated with a detected error; wherein the control circuit controls the switch element to detect a type of wiring error.

According to another implementation, an error detection module adapted to be attached to an in-wall power adapter may comprises a switch element configured to connect a line voltage to one of a load contact element and a traveler contact element; a control circuit coupled to the switch element, wherein the control circuit is adapted to control the switch element; and a user interface adapted to provide a test result associated with a detected wiring error; wherein the control circuit controls the switch element to detect a type of wiring error.

Turning now to FIG. 64, a flow chart showing a method of detecting a wiring error is shown. A type of power adapter may be determined at a block 6402. According to some implementations, a control circuit, such as the control circuit of FIG. 58 as described above, may determine a voltage on one or more contact elements of the electrical interface 5802 For example, a sequence of tests may be performed, such as by the control circuit 5810 controlling the signals detected by the test circuit 5808, to determine the type of base into which the test module is inserted. According to one implementation, a power adapter wired in a single pole wiring arrangement may be detected by determining whether the voltage on the load contact changes in response to the toggling of the switch 5814 and 5816, but never detecting a change in the current on the traveler (TR) contact element when the switch 5816 is toggled between the up position (as shown in FIG. 58) and the down position by the control circuit 5810 of the test module.

If a single pole power adapter is not detected, a test can be performed to determine whether the power adapter is a primary multiway power adapter or companion multiway power adapter. According to one implementation, the line contact element, which is wired as a common contact element in a multiway wiring arrangement, can be monitored to determine if the line contact element is maintained at a constant line voltage even with a toggling of one or both of switch 5814 and switch 5816. If the line contact element is maintained at a line voltage with a toggling of one or both of switch 5814 and switch 5816, the power adapter could be detected as a companion power adapter. That is, because the line contact element is connected to the load for a primary power adapter (i.e., a primary power adapter is a power adapter connected to the load in a multiway wiring arrangement), a power adapter could be determined to be (i) a companion power adapter in a multiway wiring arrangement if the line contact element maintains a constant line voltage, and (ii) a primary power adapter in a multiway wiring arrangement if the voltage on the line contact element changes in response to a toggling of one or both switch 5814 and switch 5816.

If the power adapter is not determined to be a single pole power adapter or a primary or companion multiway power adapter, it can be determined whether the power adapter is a 4-way power adapter that is wired in a multiway power adapter arrangement between a companion power adapter and a primary power adapter. According to one implementation, a power adapter may be determined to be a 4-way power adapter wired between a companion power adapter and a primary power adapter by detecting current flowing by way of the 4 W contact element in response to a toggling of one or both switch 5814 and switch 5816 a toggling of one or both switch 5814 and switch 5816 of a test module in the power adapter. After detecting the type of power adapter in a given wiring arrangement, voltages on contact elements can be detected, such as in response to the switching of one or both switch 5814 and switch 5816 to determine a wiring error.

The test module may be configured to test a power adapter, based upon the type of power adapter detected, at a block 6404, such as by monitoring the voltage on the line contact as described above. A no neutral connection condition may be detected at a block 6406. According to one implementation, the control circuit, which is coupled to each contact element of the power adapter, could compare the voltage on the ground contact element. If the voltages are within approximately one volt or some other suitable voltage of one another, it could be determined that the neutral contact element is connected to the neutral wire of the junction box. That is, the neutral voltage and the line voltage are usually within approximately one volt of one another. The voltage threshold could be established to be some other voltage based upon known or tested system considerations. A line/load wire swap condition may be detected at a block 6408. Depending upon the type of power adapter detected, the voltages on the line and load can be monitored in response to switching of one or both switch 5814 and switch 5816. In the case of a power adapter wired in a single pole wiring arrangement or as a companion power adapter in a multiway wiring arrangement, the voltage on the line contact element should not change in response to a toggling of power to the load, such as by changing the state of switch 5814. Additional tests may be performed at a block 6410. That is, while the tests set forth in blocks 6404-6410 represent common wiring error conditions, it should be understood that there may be other wiring errors that could be detected. Other wiring errors that may be detected may include a neutral connection missing, line and neutral wires swapped, line and load wires swapped, line and traveler wires swapped, neutral and load wires swapped, neutral and traveler wires swapped, load and traveler wires swapped, for example. Errors may then be displayed at a block 6412. Specific error conditions could be provided and/or an indication of a correct wiring condition could be provided.

According to some implementations, a condition when line and neutral wires are swapped may be detected by detecting either a line voltage on the neutral contact element or detecting a voltage near ground on a line contact element. According to some implementations, a condition when line and load wires are swapped may be detected (i) when a line contact element is not maintained at the line voltage in response to a changing a state of a test module applying the line voltage to the load or (ii) when the voltage on the load contact element is not changed (but rather maintained at the line voltage) in response to a changing of a state of a test module applying the line voltage to the load. A swapping of the line and load wires may also be detected when the line voltage is not detected on the line contact element, but it is determined that the line voltage is applied to the load contact element. It may also be beneficial to detect current being conducted on the load contact element when the line voltage is not detected on the line contact element when detecting a line/load swap condition. According to some implementations, a condition when line and traveler wires are swapped may be detected by detecting (i) different voltage levels associated with the line and traveler contact elements or (ii) detecting signaling normally provided on a traveler contact element on the line contact element or failing to detect signaling normally provided on a traveler contact element. According to some implementations, a condition when neutral and load wires are swapped can be determined by detecting a neutral voltage on the load contact element when the line voltage should be provided to the load. According to some implementations, a condition when a neutral and traveler wires are swapped could be detected by determining when either a neutral voltage is detected on the traveler contact element or when a voltage or signal normally transmitted on a traveler contact element is detected on the neutral contact element. According to some implementations, a condition when a load and traveler wires are swapped could be detected when either a load voltage is detected on the traveler contact element or when a voltage or signal normally transmitted on a traveler contact element is detected on the load contact element.

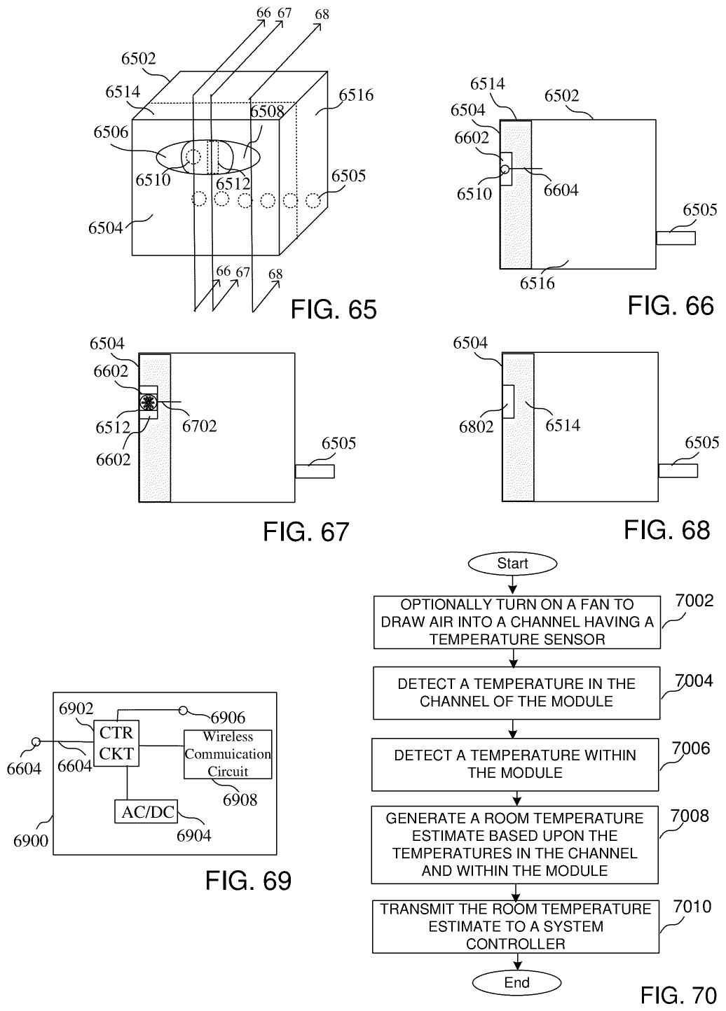

Turning now to FIG. 65, a perspective view of a temperature detection module 6502 is shown. More particularly, the temperature detection module 6502 may provide temperature compensation for the module by employing multiple temperature sensors to detect temperatures at different locations of the module that may impact the temperature detected by a temperature sensor that is detecting the temperature of the air in the room. For example, the temperature detection module may be in a multi-gang junction box, where heat may be generated by a dimmer circuit in a different gang of the multi-gang junction box for example may impact the temperature reading associated with the air in the room. The temperature detected by the temperature sensor module may vary based upon when the dimmer is being used and the dimming state of the lights that the dimmer is controlling. Further, the junction box having the power adapter and temperature detection module may be on an outer wall that may not be well insulated. In contrast to the heat generated by dimmer circuit in another gang of the multiway junction box, the temperature detection module may be affected by cold temperatures from the outside. In some circumstances, a temperature detection module may be affected by sources of both hot air and cold air. In addition to the use of multiple temperature sensors, insulation may be provided between the body of the module and the temperature sensor, as will be described in more detail below. Therefore, the module may provide temperature compensation by generating an estimated temperature that takes into account the influence of air that is generated within the module or comes into contact with the module that may affect a temperature sensor that is determining a room temperature.

The temperature detection module 6502 comprises a surface 6504 having a channel extending from an opening 6506 to an exit 6508. The temperature detection module comprises contact elements 6505 that are adapted to be coupled to one or more contact elements of a power adapter. A temperature sensor 6510 may be placed within the channel to detect an ambient temperature of a room. The temperature detection module 6502 may comprise a fan 6512 to draw air through the channel to achieve a more accurate reading of the ambient room temperature. The temperature detection module may also comprise an insulating material 6514 between the channel and a rear portion 6516 of the temperature detection module. FIGS. 66-68 are cross-sectional views that show the channel, the temperature sensor and insulation to improve the accuracy of the temperature sensor module.

Turning first to FIG. 66, a cross-sectional view of the temperature detection module of FIG. 66 taken at lines 66-66 is shown. As shown in FIG. 66, the temperature sensor 6510 is in a channel 6602 that extends between the opening 6506 to the exit 6508. A wire terminal 6604 extends from the temperature sensor 6510 and through the insulation material 6514 to the rear portion 6516. The fan 6512 is shown in the cross-sectional view of the temperature detection module of FIG. 67 taken at lines 67-67, where a control signal line 6702 is provided to the fan. The exit portion 6802 of the channel 6602 is shown in the cross-sectional view of the temperature detection module of FIG. 65 taken at lines 68-68.

Turning now to 69, a block diagram of a temperature compensation circuit 6900 for the temperature detection module of FIG. 65 is shown. More particularly, a control circuit 6902 is coupled to the temperature sensor 6510 by way of the wire terminal 6604. The control circuit 6902 is coupled to a transformer 6904, shown here by way of example as an AC/DC converter, and may be coupled to a second temperature sensor 6906. The temperature detection module may also comprise a wireless communication circuit 6908 to transmit or receive signals with a system using the detected temperature, such as an HVAC or air quality system. According to some implementations, the temperature detection module may be a stand-alone detection module for providing information related to the ambient temperature in a room for a homeowner. While two temperature sensors are shown by way of example, it should be understood that additional temperature sensors could be implemented in different parts of the module to improve the accuracy of a generated estimated ambient temperature.

According to some implementations, a module adapted to be attached to an in-wall power adapter may comprise a plurality of contact elements adapted to be coupled to contact elements of an in-wall power adapter, wherein the plurality of contact elements comprises a first contact element adapted to receive a line voltage and a second contact element adapted to receive a neutral voltage; and a temperature sensor in a portion of the module extending through an opening of a wall plate and adapted to receive air from a room; wherein the temperature sensor determines a first temperature representing a room temperature of the room having the module.

According to another implementation, a module adapted to be attached to an in-wall power adapter may comprise a plurality of contact elements adapted to be coupled to contact elements of an in-wall power adapter, wherein the plurality of contact elements comprises a first contact element adapted to receive a line voltage and a second contact element adapted to receive a neutral voltage; an opening on a surface of a module adapted to receive air; and a temperature sensor on the module having a portion extending through an opening of a wall plate attached to an in-wall power adapter; wherein the temperature sensor determines a first temperature representing a room temperature of a room having the module.

Turning now to FIG. 70, a flow chart for a method of implementing a temperature module is shown. The method could be implemented with the temperature detection module 6502, for example, or another suitable temperature sensor module. A fan is optionally turned on at a block 7002 to enable the temperature sensor module to more accurately detect the ambient temperature of a room. A temperature is detected for the room, such as by detecting the temperature of the air in the channel of the module, at a block 7004. A temperature may also be detected at another location associated with the module at a block 7006. By way of example, the temperature detected by one or more temperature sensors may be detected periodically or in response to a signal generated by a control circuit of the temperature detection module or received by the temperature detection module. If a fan is implemented, the fan may be turned on at a predetermined time before detecting the temperature. A room temperature may be generated based upon the temperature detected within the channel and the temperature detected at some other location associated with the module by one or more additional temperature sensors at a block 7008. According to some implementations, the control module may be calibrated in a given room by setting a temperature for the module based upon an actual temperature in the room to improve the accuracy of the temperature readings. For example, a technician setting up an HVAC system for example may provide a current temperature for a room by way of a wired or wireless connection to the temperature detection module. During operation of the temperature detection module, the room temperature estimate may be transmitted to a system controller at a block 7010.

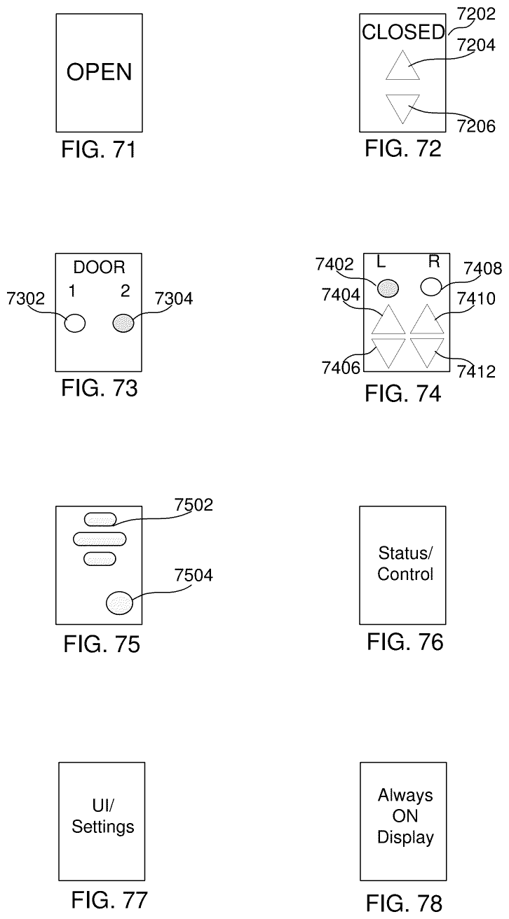

Turning now to FIG. 71, a user interface for a control module adapted to provided status information associated with a door, such as a garage door, is shown. The user interface could be a display which may indicate an open or closed state of the garage door, or simply an indicator light such as an LED which may indicate the open and closed state of the door.

Turning now to FIG. 72, a user interface for a control module adapted to provided status information and a control interface, such as up and down actuators, associated with a door, such as a garage door, is shown. The user interface may comprise one or more control actuators and one or more status indicators. More particularly, the user interface may comprise an information field 7202 that provides information such as a status of the open and closed state of a garage door. The user interface may also comprise a first actuator 7204 enabling a user to open the garage door and a second actuator 7206 enabling a user to close the garage door, where control signals to open or close the door (i.e., an open signal or a close signal) are sent in response to the selection of the actuators 7204 and 7206. The actuators may be buttons that are pushed or portions of a touch screen that may be selected.

Turning now to FIG. 73, a user interface for a control module adapted to provided status information associated with multiple doors, such as garage doors, is shown. The user interface may comprise a first information field 7302 that indicates the state of a first garage door and a second information field 7304 that indicates the state of a second garage door. While an oval-shaped indicator which may be lit in a certain color (e.g. green for closed or red for open), it should be understood that other indications could be provided, such as a word “open” or “closed”.

Turning now to FIG. 74, a user interface for a control module adapted to provided status information and a control interface, such as up and down actuators, associated with multiple doors, such as garage doors, is shown. More particularly, the user interface may comprise a first information field 7402 that indicates the state of a first garage door (shown here by way of example as an LED associated with a left (L) garage door), a first actuator 7404 enabling a user to open the garage door, and a second actuator 7406 enabling a user to close the first garage door. The user interface may comprise a second information field 7408 that indicates the state of a second garage door, a third actuator 7410 enabling a user to open the garage door, and a fourth actuator 7412 enabling a user to close the second garage door.

Another beneficial application of control modules is the use of control modules that interface with camera doorbells. There are a number of problems and costs associated with both traditional doorbells and conventional camera-type doorbells, and corresponding cost savings associated with being able to use control modules that provide functionality associated with doorbells. General problems associated with wired doorbells include (i) the transformer must be wired to both the doorbell and the chime for a conventional wired chime, (ii) the chime must be in a fixed location because it's wired, (iii) there is a limited/inconvenient ability to control the volume/tone of the chime, (iv) because a wired chime is in a fixed location, the volume setting of the chime may not be desirable in different locations in the home (e.g., it's too loud in the hall where they are usually placed, but hard to hear in other rooms in the house), and (v) the doorbell must be integrated with the chime, which generally requires purchasing an adapter from the doorbell provider.

General problems for wireless doorbells include (i) wireless doorbells may not be viewed favorably by homeowners, and typically may be used in aftermarket do-it-yourself (DIY) installs, (ii) wireless doorbells require batteries that must be replaced, which is a nuisance for a home owner, (iii) having a critical part of a home monitoring system relying on batteries is problematic, (iv) current plug-in chimes require a transformer/cord/plug and must be plugged into an outlet, which may be unsightly and limited to outlet locations, where switch locations may be more desirable in many cases, particularly if the chime control module has user interface controls.

Control modules are beneficial for both wired and wireless doorbells. According to one implementation, wired doorbells and wired chimes may be implemented, but control modules would still provide the opportunity to place additional chimes, or possibly other functional control modules associated with the doorbell in additional locations (e.g., a status display control module or a display control module showing a camera view from the camera of the doorbell).

According to another implementation, control modules may be used with a wired doorbell and a wireless chime, which provides many benefits. For example, a home builder has flexibility and reduced labor costs for installing a transformer for a wired doorbell. This is simpler than installing a transformer for a conventional doorbell having a chime, where lines from the transformer have to be routed to both the chime and the doorbell. A homeowner gets the benefit of a wired doorbell, where there is no need to replace batteries on a critical component of a home monitoring system. A homeowner also gets the benefit of placing chimes at multiple locations, and more desirable locations. Unlike chimes that are placed high in the wall in a hall, the homeowner has access to the chime control module, and can easily adjust the tone of the chime and the volume, for example. Also, there are opportunities for integration of the doorbell with Bluetooth speakers or speakers that are a part of an intercom system.

According to a further implementation, control modules can be used with a wireless doorbell and a wireless chime.

A chime control module may have a user interface to easily adjust the tone and volume of the chime, or to easily access other information. Because the chime can be placed in different locations, the chime can be heard in one location, without being too loud in another (i.e., easily heard downstairs without waking a sleeping baby upstairs).

A control module associated with cameras, such as cameras associated with a doorbell camera, could be provided, where the status could be always on, or could be set up so that a user could tap on a display to see the status of a camera (i.e., see the image of video that the camera is capturing). A control module could be used to see or check the state of a camera without having to rely on a mobile device. If a camera goes off-line, a message could be displayed on the control module. Some or all communication/control features of the doorbell interface could be provided on the control module for communication or control.

A display control module for a camera could also be provided. This makes it more convenient for a homeowner, who won't always have access to their phone, or won't necessarily pay attention to their phones for certain information. The ability to access certain information in certain locations is beneficial. For example, a user could see a camera view from a control module in a light switch in a bedroom. According to some implementations, the display could be off, and tapped to see the camera view, with an option to swipe the screen to see other camera views if multiple doorbell cameras or other cameras are used. For example, a homeowner may have their phone on a charger downstairs, and happens to be upstairs when the doorbell rings. It would be convenient for the homeowner to see who is at the door without having to get their phone or go downstairs. For example, the door chime control module may comprise a manual volume control or a tone control element to select different tones.

Turning now to FIG. 75, an example of a door chime control module of a door chime associated with a doorbell, such as doorbell camera, is shown. The door chime control module may comprise a speaker 7502 and a microphone 7504. It should be understood that the control module could include actuators for controlling the operation of the doorbell camera. For example, the door chime control module may comprise a manual volume control element or a tone control element to select different tones.

Turning now to FIG. 76, a user interface of a control module that enables determining a status of a doorbell camera and controlling of a doorbell camera is shown. The user interface could comprise indicator lights, a touch screen display, or a combination of indicator lights and a touch screen display. The user interface may also comprise actuator elements, such as actuator buttons. By way of example, a user may be able to turn on the display or curser through different cameras. According to some implementations, the touch screen display may enable volume control or chime control.

Turning now to FIG. 77, a user interface of a control module enabling controlling settings of an associated doorbell camera is shown. The user interface could comprise a touch screen display, actuator elements, such as actuator buttons, or a combination of a touch screen display or actuator elements. The user interface may enable a user to set various settings of the doorbell camera and associated control modules (such as associated chime modules). The settings may include, for example, volume control, zoom settings, chime control, and touchscreen settings. By way of example, a user may be able to control the same settings that they could control a computer or mobile device, such as may be provided on an app on a computer or mobile device or a website accessible on a computer or mobile device.

Turning now to FIG. 78, a control module having a dedicated display is shown. According to the implementation of FIG. 78, a display may be always on to show what is being captured by the doorbell camera, or be selectable to be off or always on show what is being captured by the camera. For example, the display may have different modes of operation, where the mode of operation may be selected by way of an app on a computer or mobile device or a website accessible on a computer or mobile device. The display may be a touch screen display, where the modes could be selected by using the touch screen capabilities of the display. According to some implementations, the modes could include an “always on” mode, a mode where the image from the camera is displayed in response to an activation of the camera by the user (such as by using the touch screen feature or an app on a computer or mobile device or a website accessible on a computer or mobile device, and a mode where the screen would show what is captured by the camera when motion is detected, for example.

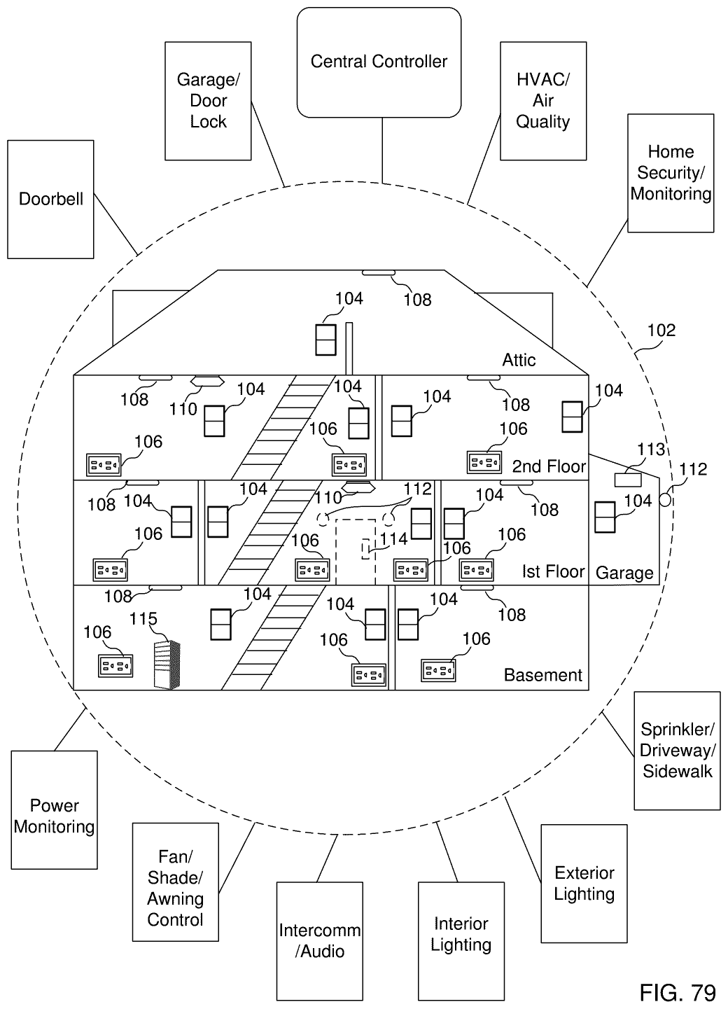

Turning now to FIG. 79, a system for integrating control modules associated with different control functions of a building such as a residential building is shown. The system of FIG. 79 comprises a plurality of different categories of control modules having similar functionality that may interact with each other or with a central controller. According to some implementations, the categories of control modules could include doorbell control modules, garage/door lock control modules, HVAC/air quality control modules, home security/home monitoring control modules, power monitoring control modules (which may include power consumption associated with a given switch or outlet or with solar power generation, storage and usage), fan/shade/awning control modules, intercom/audio control modules, interior lighting control modules, exterior lighting control modules, and sprinkler/driveway and sidewalk control modules to provide sprinkler control and control of the heating of driveways and sidewalks.

According to some implementations, doorbell control modules may include door chimes, cameras, and various control modules having user interfaces for controlling the operation of the doorbell and doorbell control modules, as described above.

According to some implementations, garage/door lock control modules may include status or control modules, as described above.

According to some implementations, HVAC/air quality control modules may include various types of sensors, status and control-type control modules associated with HVAC or air quality systems.

According to some implementations, home security/home monitoring control modules may include cameras, various types of sensors, status and control-type control modules associated with home security or home monitoring systems.

According to some implementations, power monitoring control modules may include status and control-type control modules associated with lighting or electrical outlets for example, and solar power generation, storage and usage.

According to some implementations, fan/shade/awning control modules may include various types of sensors, status and control-type control modules associated with fans or shades and awnings for windows.

According to some implementations, intercom/audio control modules may include\various types of sensors, status and control-type control modules associated with audio or intercom systems in a home.

According to some implementations, interior lighting control modules may include any type of lighting control device, including dimmer control modules, timer control modules, smart switch control modules, smart outlet (i.e., controlled outlet) control modules, for example.

According to some implementations, exterior lighting control modules may include any type of lighting control device, including various sensor control modules, timer control modules, and smart switch control modules.

According to some implementations, sprinkler/driveway and sidewalk control modules may include various sensor control modules, timer control modules, and smart switch control modules. According to some aspects, these control modules may receive information, such as weather conditions near the building having the system. The control modules may receive the information by way of a central controller for the building, or may comprise wireless communication circuits (e.g., WiFi or cellular transceivers) for receiving information that would enable the control module to function. For example, is snowfall is recorded in the area, the control module may turn on the sidewalk heater.

A beneficial aspect of the system 100 is that the ability to place control modules in a variety of different locations enables various systems, such as systems associated with the various categories of control modules to exchange information or otherwise interact and improve the operation of the individual systems, such as by improving reliability, accuracy, efficiency, or other metrics associated with the system. According to some implementations, all of the control modules may communicate with a central controller, which may communicate with control modules of other systems. The central controller may operate on a particular wireless protocol, such as a cellular protocol, WiFi, Zigbee, Z-Wave, Matter, Thread, Bluetooth, NFC, or some other communication network, such as a proprietary communication network and mesh networks associated with the various protocols. According to some implementations, the central controller may have multiple wireless interfaces. According to other implementations, control modules of different systems may communicate directly with one another, such as by the implementation of the Matter protocol. Various external environmental measurements may be determined through external sensors, or through information stored in or acquired from the central controller.

According to some implementations, doorbell control modules may provide information to interact with one or more of the garage/door lock system, home security/home monitoring systems, fan/shade/awning systems, intercom/audio systems, interior lighting systems and exterior lighting systems, for example. According to some implementations, a doorbell may include various sensors, which may include for example, temperature and humidity sensors. That is, because the doorbell is outside, it can be used to detect temperature, humidity, ambient light level, atmospheric pressure, or other environmental conditions that could be used by other systems, such as HVAC or air quality systems.

According to some implementations, garage/door lock control modules may provide information to interact with one or more of the home security and monitoring systems, intercom/audio systems, interior lighting systems and exterior lighting systems, for example.

According to some implementations, HVAC/air quality control modules may provide information to interact with one or more of the power monitoring system, fan/shade/awning control system, intercom/audio systems, interior lighting systems and exterior lighting systems, for example.

According to some implementations, home security/home monitoring control modules may provide information to interact with one or more of fan/shade/awning control system, intercom/audio systems, interior lighting systems, exterior lighting systems, and the sprinkler/driveway/sidewalk system, for example.

According to some implementations, power monitoring control modules may provide information to interact with one or more of the interior and exterior lighting systems, for example.

According to some implementations, fan/shade/awning control modules may provide information to interact with one or more of the home security/monitoring systems, intercom/audio systems and interior and exterior lighting systems, for example.

Turning now to FIG. 80, a system showing additional details for integrating control modules associated with different control functions associated with a building such as a residential building is shown. A variety of modules may be implemented according to the system 100 of FIG. 1 or the system of FIG. 80, which shows the integration of different systems withing a building, such as a residential building, as shown in FIG. 80. One category of modules may comprise lighting and load control modules, which may include a dimmer controller (e.g., simple dimmer or smart dimmer) module, a motion sensor (e.g., vacancy and/or occupancy) module, a smart timer module, an astronomical timer module, a countdown timer module, a scene controller module, a humidity sensor module, a temperature sensor module, an ambient light sensor module (e.g., to control an on/off state or dimming state), a power and/or current consumption detection module (e.g., to control an on/off state or dimming state), a wirelessly controlled outlet module (e.g., nightstand lamp control), and one or more switch modules/one or more corresponding controlled outlet modules that are wirelessly connected (e.g., nightstand lamp control) for example.

Another category of modules may comprise ceiling fan, shade, and awning control modules, which may include a ceiling fan speed control/status module, a shade control/status module, an awning control/status module, an air flow sensor module, a temperature sensor module, and an ambient light sensor module for example.

Another category of modules may comprise heating, ventilation, and air conditioning (HVAC) modules, which may include a temperature sensor/HVAC system interface (e.g., a wired or wireless connection to an HVAC system) module, a humidity sensor/HVAC system interface module, an air pressure sensor/HVAC system interface module, a thermostat Control/HVAC system interface module, a thermostat Status/HVAC system interface module, an ambient light sensor/HVAC system interface module, and an air quality sensor/HVAC system interface module for example. By way of example, the HVAC system may comprise a furnace 8002 that may be connected to a system of ducts 8004 and a fresh air system 8006 that filters incoming air and exchanges it with air that is removed from the building. Some types of fresh air systems include Heat Recovery Ventilation (HRV) and Energy Recovery Ventilation systems. The HVAC system may also comprise an air conditioning system 8008, which may be outside or on the roof of a building for example. Sensors may be implemented in modules that can be placed in various power adapters implemented as power adapters having a switch, such as power adapter 104 or a power adapter having an outlet such as power adapter 106.

Other sensors may be employed to improve air quality in a home, such as in a kitchen, which may comprise a stove 8010 adapted to burn natural gas that may release contaminants into the air. While an exhaust fan 8012 may be used to remove contaminants in the kitchen while a homeowner is cooking or at other times. While a homeowner may turn on the exhaust fan, it may be beneficial for the exhaust fan to be turned on in response to the detection of contaminants in the air. An air quality sensor 8014 may be placed in a power adapter 104 having a switch as shown in FIG. 81 by way of example, or in a power adapter 106 having an outlet for example.

Another category of modules may comprise air quality or air quality system modules, which may include a temperature sensor/air quality system interface module, a humidity sensor/air quality system interface module, an air pressure sensor/air quality system interface module, a carbon monoxide (CO) sensor/air quality system interface module, a particulate matter (PM) sensor/air quality system interface module, and a volatile organic compounds (VOC) sensor/air quality system interface module for example.

Another category of modules may comprise ventilation fan control modules, which may include a ventilation fan manual On/Off control and status module, a ventilation fan manual speed control and status module, a countdown timer module, a temperature sensor module, a humidity sensor module, an air pressure sensor module, an ambient light sensor module, a chemical sensor module, and an air quality sensor module, for example. Ventilation fans may also be used in bathrooms, such as a ventilation fan 8020 that extends to a vent 8022. The ventilation fan may be controlled by a power adapter 104 which may comprise a control module 8024. The control module 8024 may comprise one or more of a temperature sensor, humidity sensor or a particulate sensor. According to some implementations, the control module 8024 may also comprise a wireless communication circuit that may be in communication with a system, such as an HVAC system or an air quality system, and may control the ON/OFF state of the ventilation fan, automatically in response to a reading by a sensor or in response to a signal received by a wireless communication circuit.

According to another implementation, an attic fan 8030 that draws air from in the building, such as through open windows, to provide cooling and ventilation to the building by driving the air out of a vent 8032 or additional attic vents 8036 as shown. the attic fan 8030 may be controlled by a power adapter 104 which may comprise a sensor control module 8038. The sensor control module 8038 may also comprise one or more of a temperature sensor, humidity sensor or a particulate sensor and a wireless communication circuit. The sensor control module 8038 may communicate with additional control modules having sensor associated with the operation of the attic fan 8030, such as a control module 8040 in the attic, a control module 8042 in a second floor hallway, a control module 8044 in a second floor bedroom, or a control module 8046 in a first floor hallway.

Another category of modules may comprise wireless control and wireless network control modules, which may include a network hub module, a network integration module, a network bridge module, a network controller module, a network extender module, a wireless router module, a mesh network access point module, and a wired network access port module (e.g., Ethernet connection) for example.

Another category of modules may comprise charging modules, which may include a USB charger module (e.g., USB-A OR USB-C), an inductive coupling charger module, and a low voltage charger for a coaxial cable module for example.

Another category of modules may comprise home security/home monitoring modules, which may include a motion sensor/network interface module, an occupancy sensor/network interface module, a thermal imaging sensor/network interface module, a door lock status sensor/network interface module, a window status sensor/network interface module, a glass break detection sensor/network interface module, a siren detection sensor/network interface module, an emergency notifier/network interface module (e.g., audible or visual), an emergency signal generator/network interface module (e.g., emergency button to initiate a 911 call), an alarm control panel/network interface module (e.g., keypad, control, information, status), a camera/network interface module, a display/network interface module, a weather alert/network interface module (e.g., audible or visual), a fire detection sensor/network interface module, and an air quality sensor/network interface module (e.g., CO, PM, VOC) for example.

Another category of modules may comprise home comfort modules, which may include a night light module, a white noise maker module, an air freshener module, an outside temperature display module (e.g., based upon an outdoor sensor or external data, such as internet data provided by way of a direct or system wireless connection), a room temperature sensor/display module, a humidity sensor/display module, an air pressure sensor/display module, and an ambient light sensor module (e.g., dimming control) for example.

Another category of modules may comprise audio/video (AV) modules, which may include a speaker/network interface module (e.g., WiFi or Bluetooth), a smart speaker module (e.g., Alexa, Google Home, Apple Homekit, Samsung Smart Things), a speaker control/network Interface module (e.g., volume, tone, balance, etc.), a video display/network interface module (e.g., video from a local or remote camera), an intercom interface/network interface module, an intercom speaker/network interface module, and an intercom video/network interface module for example.

Another category of modules may comprise doorbell modules, which may include a remote doorbell chime module, an intercom interface for a doorbell module, a display for doorbell camera module, a doorbell status/control module, an outdoor temperature display module (e.g., for temperature reading from sensor in the doorbell), a barometric pressure display module (e.g., for an air pressure reading from a pressure sensor in the doorbell or from external data, such as internet data), an outdoor humidity display module (e.g., from a humidity sensor in the doorbell), and an indoor/outdoor humidity display module (e.g., from a humidity sensor in the module and a humidity in the doorbell) for example.

Another category of modules may comprise garage door opener modules, such as garage door opener control modules 8048, which may be used to control a garage door opener or provide a status of the open/closed state of the garage door. As described above, the various garage door opener control modules, which may include a garage door status module (e.g., open/closed status and elapsed time since status change), a garage door control module (e.g., up/down control), and a garage door motion alert module (e.g., audible or visual indication of an opening or closing) for example, may be placed at different locations within the building, other than within the garage as shown in FIG. 80.

Another category of modules may comprise door lock modules, which may include a camera module (e.g., indoor and/or outdoor), a video or image display module (e.g., indoor and/or outdoor), a keypad module (e.g., indoor and/or outdoor), a motion detection module (e.g., indoor and/or outdoor), a temperature sensor module (e.g., indoor and/or outdoor), a pressure sensor module (e.g., indoor and/or outdoor), and a humidity sensor module (e.g., indoor and/or outdoor) for example.

Another category of modules may comprise sprinkler system modules, which may include a sprinkler control interface module (e.g., on/off control, status, timer functions, sprinkler settings), a daily/weekly/monthly rainfall monitor module (e.g., based upon outdoor sprinkler system sensors and/or external data such as internet data), and an information display module (e.g., Residential Watering Restrictions, watering recommendations) for example.

Another category of modules may comprise sidewalk and/or driveway heater modules, which may include a snow/ice detection module (e.g., based upon cameras associated with camera and/or external data), and a sidewalk/driveway heater control module (e.g., on/off, timer functions, temperature setting) for example. According to some implementations, sensor and/or control modules may be provided in power adapters to control heating elements under a driveway 8050 or a sidewalk 8052. The sensors may be a part of another system, such as a doorbell camera system that may comprise a sensor that may be used to turn the heating elements on or off. For example, a doorbell camera may detect snow on the sidewalk, and turn on the sidewalk and driveway heating element. One or more humidity and temperature sensors may also detect conditions for snow to control the sidewalk and driveway heating element.

Another category of modules may comprise power and energy management modules, which may include a power consumption for an outlet module (e.g., display/control/wireless communication), a power consumption module (e.g., display/control/wireless communication), a current draw module (e.g., for an outlet or a switch and may comprises display/control/wireless communication), a weather forecasts module, and a weather alerts module for example.

Another category of modules may comprise solar energy management modules, which may include a charging status module, an energy consumption module, an energy savings module, an energy consumption mix module (e.g., natural gas consumption compared to solar energy consumption), an energy storage status module (e.g., battery), an available energy from solar energy storage module, a weather forecasts module, a weather alerts module, an energy storage projections module (e.g., charging/discharging) based upon weather forecasts), an automatic load leveling for optimizing power consumption module, and a solar panel defect alert module for example.

Another category of modules may comprise general sensor modules e.g., stand-alone sensors), which may include a motion sensor module (e.g., for outdoor motion detection), a temperature sensor for outdoor temperature module, a humidity sensor for outdoor humidity module, an air pressure sensor for outdoor air pressure module, an air flow sensor module, and an air quality monitor (e.g., for detecting an open door or window) for example.

Another category of modules may comprise general information modules, which may include an analog or digital clock module, a world clock module, a sunrise/sunset time module, a calendar and/or current date module, a current day of a 365 day year module (e.g. 67/356), a wind direction/speed module, a barometric pressure reading/“analog” barometer dial/barometric change alert module, a phase of the moon module, and a regional tide status module for example.

It should be understood that, for each category of modules or for modules in two or more different categories of modules, the functionality of two or more different modules may be combined into a single module.

According to some implementations, doorbells or doorbell modules may provide information to and interact with one or more of the garage/door lock systems, home security and monitoring systems, fan/shade/awning systems, intercom/audio systems, interior lighting systems and exterior lighting systems, for example. The doorbell module could rely upon advanced computer techniques to take an action based upon the detection of a condition at the doorbell. A user may establish operation settings, such as settings associated with the detection of a person approaching the door. For example, a doorbell or doorbell module may detect, such as by using a camera, a sensor or other detection element, if a person approaching the door is a known person (e.g., a family member or trusted friend) or an unknown person, and the doorbell or doorbell module may provide a signal to another system. For example, the doorbell or doorbell module may provide a signal to a door lock to change the state of the door lock (e.g., unlock the door if the person is a known person or lock the door if the person is an unknown person). The doorbell may also provide a signal to a garage door opener to change the state of the garage (e.g., open the garage door if the person is a known person and normally enters through the garage door or close the garage door if the person is an unknown person).

A doorbell or doorbell module may also interact with a home security systems or a home monitoring system. For example, if the camera of the doorbell detects an adverse party (e.g., a known previous intruder, a home invasion suspect, a known felon, or one who may wish to cause harm to someone at the home), the doorbell may provide an alert to a homeowner, such as by way of a communication signal to a mobile device or computer. The doorbell may also provide a communication to a home monitoring system or the appropriate local, state or federal authorities. The doorbell system may also provide an audible or visual alert to the adverse party. For example, the doorbell may provide an audible message that the adverse party has been identified and the authorities have been contacted.

A doorbell or doorbell module may also interact with fan/shade/awning systems. Because the doorbell is outside, it can provide information, such as temperature, humidity, and air pressure, to another system which may allow that system to change a state of the system. For example, if the camera of the doorbell detects that sun is present, it may operate one or more fans (e.g., ceiling fans or attic fans), shades or awnings for example. While information related to weather, such as a predicted presence of sunlight on a given day may be generally accurate, the information may not be helpful or a substitute for actual conditions at a home. For example, a forecast for a partly sunny day or rain in a given area will provide little information related to if and when the sun is actually out or behind the clouds or whether it ever actually rains at a given home. The use of cameras and sensors may be used in conjunction with weather predictions to control the operation of one or more of a fan, a shade, and an awning.

A doorbell or doorbell module may also interact with an intercom or audio system. According to one implementation, a doorbell may provide a message to a homeowner using an intercom system based upon the operation of the doorbell. For example, the doorbell may provide an indication that someone has actuated the doorbell, where the intercom system would provide a ring indication (e.g., a doorbell noise or other audible message). That is, one or more speakers associated with an intercom system could be used to provide an indication that the doorbell has been actuated. The message may be specific based upon an image detected by the camera of the doorbell. For example, the intercom system may provide an indication of the person or persons detected by a camera of the doorbell. The indication may include a warning if the person is determined to be an adversarial party. Even if the person detected by the camera is an unknown person, the doorbell, such as using advanced computer techniques, may make a determination of a possible motive or goal of the person. For example, the camera may detect a person with a clipboard, and determine that the person may be seeking signatures for a petition or a political activity. The camera may also detect a child selling items associated with a fundraiser for an organization, such as a girl with boxes of cookies or a boy with tins of popcorn. The doorbell could provide a message to be transmitted on the intercom system providing an indication of what the goals or motives of the person may be.

A doorbell or doorbell module may also interact with an interior lighting systems and exterior lighting systems. If a camera of the doorbell detects an ambient light level that may not be detected based upon a weather forecast, such as a particularly cloudy condition (which may not be consistent with weather forecasts) at the home, the doorbell may send a message to a lighting control system that controls a number of lights to change the state of one or more interior or exterior lights. Alternatively, the doorbell may send a message to one or more interior and exterior lights to change the state of those lights.

A doorbell or doorbell module may also interact with an HVAC or air quality system. For example, as the external temperature rises or the sun is out at a certain time of day, a Heat Recovery System (HRS) or Energy Recovery System (ERS) may change its operation based upon the temperature of the air being drawn into the system. The doorbell may also send a message to a humidifier or dehumidifier system, HVAC system or air quality system of a home that would alter the operation of the humidifier or dehumidifier system, HVAC system or air quality system based upon a detected external humidity.

According to some implementations, garage door/door lock modules may provide information to and interact with one or more of the home security and monitoring systems, intercom/audio systems, interior lighting systems and exterior lighting systems, for example. Modules associated with a garage door system as described above in reference to FIGS. 71-78 could provide information to or receive information from a home monitoring system. For example, a state of a garage door may be integrated into a home monitoring systems, and could be displayed on a “dashboard” for a home monitoring system. The home monitoring system may send messages associated with the status of a garage door alone, or in combination with other status information. Because many homeowners may have a number of apps related to different functions or systems in their home, incorporating the status and operation of a garage door opener into a home monitoring system may be beneficial. That is, because of the number of apps that may be available to a homeowner, some homeowners may only rely on some of the more important apps, and may not receive all of the information from apps that a homeowner may tend to ignore, even if that information may be helpful to the homeowner. That is, if the information associated with a garage door is incorporated into another system, the homeowner may have access to that information without having to rely upon multiple apps or computer based programs.

Electronic door locks, also referred to as smart door locks (i.e., door locks have a keypad or a short range signaling circuit such as an NFC circuit, or a scanner such as a bar code scanner or QR code scanner), may also be incorporated into a home monitoring system. While information related to the status of a door lock may be important to a user, a homeowner may be less likely to monitor the status of a door lock. However, like the status of a garage door, it may be beneficial to incorporate an electronic door lock as a part of a home monitoring system, not just for providing status, but also for home automation, where the door lock may be controlled or automated by the home monitoring system. For example, knowing the state of the lock may be beneficial by enabling parents to monitor when children return from school.

Garage door opener modules and electronic door locks may be adapted to communicate with one or both of intercom systems and audio systems to provide an audible indication associated with the state of a garage door or door lock, where the status may be provided at certain times. For example, if a garage door is open or an electronic door lock is unlocked after a predetermined time (e.g., 9:00 PM), the status may be audibly provided on the intercom system or audio system. While a status may be available to a homeowner on an app on their mobile device for example, a homeowner may not check the status, but would be interested in knowing if the garage door is open or the door is unlocked. For example, a homeowner could enable a feature of their home monitoring app that would provide an audible indication of the status of the door on one or more speakers that are a part of the intercom system or audio system.

In addition to being integrated with home monitoring systems as described above, garage door opener modules and electronic locks can also be configured to control interior lighting systems and exterior lighting systems separate from a home monitoring system. For example, when a garage door opens, the garage door opener or a module associated with the garage door opener may send a signal to a module in a power adapter configured to control a light in a mud room or laundry room accessible from the garage. Similarly, an electronic lock may be adapted to communicate with a module adapted to control a light, such as a ceiling light in a foyer. For example, when a person attempts to actuate an electronic door lock, a light, such as an inside light in a foyer or outside lights near the door lock may be turned on.

According to some implementations, HVAC/air quality system modules may provide information to and interact with one or more of the power monitoring system, fan/shade/awning control system, intercom/audio systems, interior lighting systems and exterior lighting systems, for example. More particularly, HVAC and air quality system modules may comprise temperature sensors, humidity sensors, ambient light sensors, air quality sensors, or other sensors that may provide data to an HVAC system or an air quality system. As conditions detected by one of the sensors start to change, these conditions can be analyzed to determine whether the power requirements, as estimated and monitored by a power monitoring system, have changed. The power monitoring system may therefore determine whether the load on an electrical system on a load may change. If the power monitoring systems determines that the changes in power demand, as estimated in part due to measurements and data provided by HVAC and air quality system modules, and particularly changes that may lead to an excess electric current draw, it may be possible to reduce unnecessary current and power consumption in some other system.

HVAC and air quality system modules may also interact with fan, shade, and awning control systems, such as by providing measurements or other data to one or more of a fan system (e.g., ceiling fans or an attic fan), shade control systems or awning systems. For example, if a temperature of a room detected by a temperature sensor module indicates that a room temperature is rising, nominally or with respect to the temperatures of other rooms, a ceiling fan may be turned on or off, shades may be lowered or raised, or awnings may be opened to block the sunshine entering through a window and heating the room or closed to allow more sunlight in. That is, because certain conditions may be affecting one room or area of a home, it may not be possible or beneficial to compensate for the change in conditions in one room or area by changing the settings of an HVAC system would affect a larger region. Rather, fans, shades or awnings may be able to compensate for the change in conditions in the one room or area without adversely affecting the temperature in another room or area.

An HVAC or air quality system may also interact with intercom systems or audio systems, such as by providing an indication of a condition in which a homeowner may be interested. For example, if a temperature or an air quality reading in a room reaches a certain temperature that may indicate that a window had been left open, the HVAC system or air quality system may provide, in addition to any message provided by way of an app or other message to a homeowner, an audible message by way of one or more speakers associated with an intercom or audio system. According to one implementation, the selection of a speaker to provide the message may be based upon the likely location of the homeowner as determined through advanced computer techniques or through the use of motion sensors associated with the HVAC system, home monitoring system, or some other system.

According to some implementations, home security/home monitoring modules may provide information to and interact with one or more of fan/shade/awning control system, intercom/audio systems, interior lighting systems, exterior lighting systems, and a sprinkler/driveway/sidewalk system, for example. A shade control system and awning control system may receive information from a home monitoring system that a detected intruder is in the area and may automatically lower the shades to prevent an intruder from looking into windows of the home. The home monitoring system may also provide different types of warning messages on an intercom system or an audio system. The home monitoring system may also control the state of one or both of interior lights and exterior lights, such as by turning on all of the interior lights and exterior lights, to expose or scare off an intruder.

According to some implementations, power monitoring modules may provide information to and interact with one or more of the interior and exterior lighting systems, for example.

According to some implementations, fan/shade/awning modules may provide information to and interact with one or more of the intercom/audio systems and interior and exterior lighting systems, for example. For example, one or both of interior and exterior lighting systems may change the state of lights based upon conditions detected by fan control systems, shade control systems, and awning control systems that would cause those systems to change the operation or state of a fan, shade or awning. That is, it may be beneficial to provide more light in a given room if the shades or awning are lowered, or less light if the shade or awnings are raised.

A beneficial aspect of the use of modules is that the ability to place control modules in a variety of different locations enables various systems, such as systems associated with the various categories of control modules to exchange information or otherwise interact and improve the operation of the individual systems, such as by improving reliability, accuracy, efficiency, or other metrics associated with the system.

A module used for lighting/load control may control power applied to a load based upon a signal provided to a base having the module or by way of a wireless communication signal to another module or to a receiver adapted to control the application of power applied to the light or load.

A network interface may be wired or wireless and may be associated with a given system (e.g., a home monitoring system), accessible on a multi-system interface (e.g., Alexa, Google Home, Apple Homekit, Samsung Smart Things) or accessible on a given local or wide area network (e.g., WiFi, Zigbee, Z-Wave, proprietary, cellular).

Ventilation Fan Control and Ceiling Fan/Shade/Awning Control may directly control a fan, shade or awning (e.g., the module is used in a switch power adapter for controlling the application of power to the fan, shade or awning) or indirectly control the fan shade or awning (the module may wirelessly communicate another switch, another module or directly with the fan, shade or awning).

Ventilation fans could include attic fan, bathroom exhaust fan, stovetop hood or any other ventilation fan that could be used in a residence or commercial building.

Any module may implement one or more of a variety of communication protocols, such as WiFi, ZigBee, Z-wave, Bluetooth, NFC, Thread, or Matter for example.

A module in any category may include information, status, or control features or any combination of information, status and control features. A module having a system or network interface may also be implemented without a system or network interface.

Information provided by a given module may be generated by the module based upon information received by a sensor of the module or from another module, or based upon information received from a remote source (e.g., a local temperature received by a system (e.g., a local temperature received from Alexa for example) or pulled from the internet over a WiFi connection).

Various modules may have combinations of the various features described above and may interact with multiple systems (e.g., HVAC and Home Monitoring).

According to some implementations, all of the control modules may communicate with a central controller, which may communicate with control modules of a given system associated with the module or with other systems. The central controller may operate on a particular wireless protocol, such as a cellular protocol, WiFi, Zigbee, Z-Wave, Matter, Thread, Bluetooth, NFC, or some other communication network, such as a proprietary communication network and mesh networks associated with the various protocols.

According to some implementations, the central controller may have multiple wireless interfaces.

According to some implementations, control modules of different systems may communicate directly with one another. Various external environmental measurements may be determined through external sensors, or through information stored in or acquired from the central controller.

Turning now to FIG. 81, a flow chart 8100 shows a method of implementing an error detection module. The method of FIG. 81 could be implemented with any of the error detection circuits described above, whether in a power adapter or associated with a test module, such as the error detection circuit as described above in reference to FIGS. 14-17, 35-53, and 56-63. According to some implementations, the method of FIG. 81 could be implemented using the test module 5704. A switch element, such as switch element 5814, is configured to route a line voltage to a load at a block 8102. A control circuit, such as control circuit 5810, is coupled to the switch element, wherein the control circuit is adapted to control the switch element to detect a type of wiring error at a block 8104. A user interface, such as user interface 5812, is provided to indicate a test result associated with a detected wiring error at a block 8106. A test circuit, such as test circuit 5808, is coupled to the control circuit, wherein the test circuit is adapted to select a contact element to determine a voltage of the contact element at a block 8108. The control circuit may test for one or more wiring errors of a group of wiring errors comprising a line connection missing, a neutral connection missing, a traveler connection missing, line and neutral wires swapped, line and load wires swapped, line and traveler wires swapped, neutral and load wires swapped, neutral and traveler wires swapped, and load and traveler wires swapped at a block 8110. An indication of a type of wiring error may be provided at a block 8112. While various blocks of the flow chart are shown by way of example, it should be understood that not all of the blocks are necessary to perform the method, and some blocks may provide additional beneficial enhancements.

Turning now to FIG. 82, a flow chart 8200 shows a method of implementing an in-wall power adapter adapted to receive a module and adapted to provide power to a load. The method of FIG. 82 may be implemented by any of the error detection circuits set forth above, such as the error detection circuit shown and described in FIGS. 14-17, 35-53, and 56-63 or some other suitable error detection circuit. According to some implementations, the method of FIG. 82 could be implemented using the in-wall power adapters as shown in FIGS. 14-17 and 35-42. A plurality of contact elements adapted to be coupled to wires of a junction box are provided at a block 8202. An error detection circuit is coupled to one or more contact elements of the plurality of contact elements at a block 8204, wherein the error detection circuit is adapted to detect a wiring error. A test is performed, by the error detection circuit for example, for one or more wiring errors of a group of wiring errors comprising a line connection missing, a neutral connection missing, a traveler connection missing, line and neutral wires swapped, line and load wires swapped, line and traveler wires swapped, neutral and load wires swapped, neutral and traveler wires swapped, and load and traveler wires swapped at a block 8206. An indication of a detected wiring error is provided at a block 8208. According to some implementations, a switch may be coupled to the error detection circuit as described for example in FIGS. 41 and 42, wherein the error detection circuit is adapted to control the switch to disable an operation of the in-wall power adapter at a block 8210. According to some implementations, the switch is coupled to a contact element adapted to provide power to a load. While various blocks of the flow chart are shown by way of example, it should be understood that not all of the blocks are necessary to perform the method, and some blocks may provide additional beneficial enhancements.

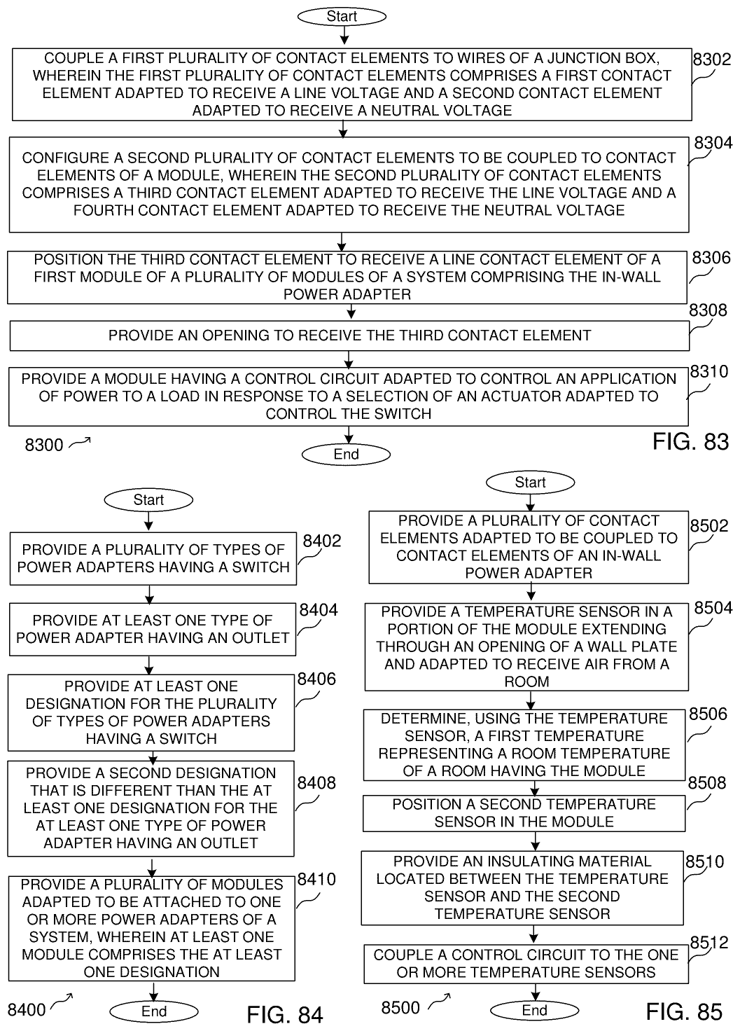

Turning now to FIG. 83, a flow chart 8300 shows a method of implementing an in-wall power adapter configured to receive a module. The method of FIG. 83 could be implemented as shown and described above in relation of FIGS. 2-12. A first plurality of contact elements are coupled to wires of a junction box at a block 8302, wherein the first plurality of contact elements comprises a first contact element adapted to receive a line voltage and a second contact element adapted to receive a neutral voltage. A second plurality of contact elements are configured to be coupled to contact elements of a module, wherein the second plurality of contact elements comprises a third contact element adapted to receive the line voltage and a fourth contact element adapted to receive the neutral voltage at a block 8304. The third contact element is positioned to receive a line contact element of a first module of a plurality of modules of a system comprising the in-wall power adapter at a block 8306, wherein the third contact element is not positioned to receive a line contact element of a second module of the plurality of modules. An opening is provided to receive the third contact element at a block 8308. A module having a control circuit adapted to control an application of power to a load in response to a selection of an actuator adapted to control the switch is provided at a block 8310, where a switch is provided on the in-wall power adapter to control power provided to a load. According to some implementations, an outlet to receive a plug may be provided on the power adapter. According to another implementation, the second module comprises a module having an outlet for receiving a plug. While various blocks of the flow chart are shown by way of example, it should be understood that not all of the blocks are necessary to perform the method, and some blocks may provide additional beneficial enhancements.

Turning now to FIG. 84, a flow chart 8400 shows a method of indicating compatibility of modules and power adapters adapted to receive modules. The method of FIG. 84 could be implemented as shown and described above in reference to FIG. 13 or using some other suitable designations. A plurality of types of power adapters having a switch is provided at a block 8402. At least one type of power adapter having an outlet is provided at a block 8404. At least one designation for the plurality of types of power adapters having a switch is provided at a block 8406. A second designation that is different than the at least one designation for the at least one type of power adapter having an outlet is provided at a block 8408. A plurality of modules adapted to be attached to one or more power adapters of a system is provided at a block 8410, wherein at least one module comprises the at least one designation. While various blocks of the flow chart are shown by way of example, it should be understood that not all of the blocks are necessary to perform the method, and some blocks may provide additional beneficial enhancements.

According to some implementations, providing a plurality of types of power adapters having a switch may comprise providing a first type of power adapter configured to control an application of power to a load. According to some implementations, providing the first type of power adapter having a switch may comprise providing one of a single pole power adapter and a primary multiway power adapter. According to some implementations, providing a plurality of types of power adapters having a switch may comprise providing a companion multiway power adapter configured to send signals to a primary multiway power adapter. According to some implementations, providing the at least one module may further comprise the second designation. According to some implementations, the at least one module may be prevented from being attached to at least one power adapter not having the at least one designation.

Turning now to FIG. 85, a flow chart 8500 shows a method of implementing a module adapted to be attached to an in-wall power adapter. The method of FIG. 85 could be implemented as shown and described above with reference to FIGS. 65-70 for example using some other suitable devices. A plurality of contact elements adapted to be coupled to contact elements of an in-wall power adapter are provided at a block 8502, wherein the plurality of contact elements comprises a first contact element adapted to receive a line voltage and a second contact element adapted to receive a neutral voltage. A temperature sensor in a portion of the module extending through an opening of a wall plate and adapted to receive air from a room providing at a block 8504. A first temperature representing a room temperature of a room having the module is determined, using the temperature sensor, at a block 8506. According to some implementations, a second temperature sensor may be positioned in the module at a block 8508. An insulating material may also be provided between the temperature sensor and the second temperature sensor at a block 8510. A control circuit to coupling the one or more temperature sensors a block 8512. While various blocks of the flow chart are shown by way of example, it should be understood that not all of the blocks are necessary to perform the method, and some blocks may provide additional beneficial enhancements.

According to some implementations, the second temperature sensor determines a second temperature associated with the module and the control circuit generates an estimated room temperature based upon the first temperature and the second temperature. According to some implementations, the insulating material may be located between a first portion of the module having the temperature sensor and a second portion of the module having the second temperature sensor.

According to some implementations, a channel adapted to receive air from the room may be provided, wherein the temperature sensor detects an air temperature of air in the channel. According to some implementations, a fan adapted to draw air into the channel may be provided. According to some implementations, a wireless communication circuit may be provided to the control circuit, wherein the wireless communication circuit is adapted to transmit a temperature associated with the room.

Further aspects of the disclosure are provided by the subject matter of the following clauses:

An error detection module adapted to be attached to an in-wall power adapter, the error detection module comprising a switch element configured to route a line voltage to a load; a control circuit coupled to the switch element, wherein the control circuit is adapted to control the switch element; and a user interface adapted to provide a test result associated with a detected error; wherein the control circuit controls the switch element to detect a type of wiring error.

The error detection module of any preceding clause, wherein the control circuit performs a test to detect a wiring error when a neutral wire is not connected to a contact element of the in-wall power adapter.

The error detection module of any preceding clause, wherein the control circuit performs a test to detect a wiring error when a line wire and a load wire connected to the in-wall power adapter are swapped.

The error detection module of any preceding clause, wherein the control circuit performs tests for detecting one or more wiring error of a group of wiring error comprising a line connection missing, a neutral connection missing, a traveler connection missing, line and neutral wires swapped, line and load wires swapped, line and traveler wires swapped, neutral and load wires swapped, neutral and traveler wires swapped, and load and traveler wires swapped.

The error detection module of any preceding clause, further comprising a test circuit coupled to the control circuit, wherein the test circuit is configured to select a contact element of the error detection module to determine a voltage of the contact element.

The error detection module of any preceding clause, wherein the test circuit comprises a multiplexer circuit.

The error detection module of any preceding clause, wherein the user interface provides an indication of a type of wiring error.

An error detection module adapted to be attached to an in-wall power adapter, the error detection module comprising a switch element configured to connect a line voltage to one of a load contact element and a traveler contact element; a control circuit coupled to the switch element, wherein the control circuit is adapted to control the switch element; and a user interface adapted to provide a test result associated with a detected wiring error; wherein the control circuit controls the switch element to detect a type of wiring error.

The error detection module of any preceding clause, further comprising a second switch element configured to route a signal from a contact element associated with a multiway wiring arrangement to one of the load contact element and the traveler contact element.

The error detection module of any preceding clause, wherein the switch element and the second switch element are controlled by the control circuit to couple either a line contact element or the contact element associated with a multiway wiring arrangement to the load contact element.

The error detection module of any preceding clause, wherein the control circuit tests for one or more wiring errors of the group of wiring errors comprising a line connection missing, a neutral connection missing, a traveler connection missing, line and neutral wires swapped, line and load wires swapped, line and traveler wires swapped, neutral and load wires swapped, neutral and traveler wires swapped, and load and traveler wires swapped.

The error detection module of any preceding clause, further comprising a test circuit coupled to the control circuit for selecting a contact element to determine a voltage of the contact element.

The error detection module of any preceding clause, wherein the test circuit comprises a multiplexer circuit.

The error detection module of any preceding clause, wherein the user interface provides an indication of a type of wiring error.

A method of detecting a wiring error detection for an in-wall power adapter, the method comprising configuring a switch element to route a line voltage to a load; coupling a control circuit to the switch element, wherein the control circuit is adapted to control the switch element; and providing a user interface to indicate a test result associated with a detected wiring error; wherein the control circuit controls the switch element to detect a type of wiring error.

The method of any preceding clause, further comprising detecting, by the control circuit, a wiring error when a neutral wire is not connected to a contact element of the in-wall power adapter.

The method of any preceding clause, further comprising detecting, by the control circuit, a wiring error when a line wire and a load wire connected to the in-wall power adapter are swapped.

The method of any preceding clause, further comprising testing, by the control circuit, for one or more wiring errors of a group of wiring errors comprising a line connection missing, a neutral connection missing, a traveler connection missing, line and neutral wires swapped, line and load wires swapped, line and traveler wires swapped, neutral and load wires swapped, neutral and traveler wires swapped, and load and traveler wires swapped.

The method of any preceding clause, further comprising coupling a test circuit to the control circuit, wherein the test circuit is adapted to select a contact element to determine a voltage of the contact element.

The method of any preceding clause, further comprising providing an indication of a type of wiring error.

An in-wall power adapter adapted to receive a module and adapted to provide power to a load, the in-wall power adapter comprising a plurality of contact elements adapted to be coupled to wires of a junction box; an error detection circuit coupled to one or more contact elements of the plurality of contact elements, wherein the error detection circuit is adapted to detect a wiring error; and a user interface adapted to provide an indication of a detected wiring error.

The in-wall power adapter of any preceding clause, wherein the error detection circuit performs a test to detect a wiring error when a neutral wire is not connected to the in-wall power adapter.

The in-wall power adapter of any preceding clause, wherein the error detection circuit performs a test to detect a wiring error when a line wire and a load wire connected to the in-wall power adapter are swapped.

The in-wall power adapter of any preceding clause, wherein the error detection circuit tests for one or more wiring errors of a group of wiring errors comprising a line connection missing, a neutral connection missing, a traveler connection missing, line and neutral wires swapped, line and load wires swapped, line and traveler wires swapped, neutral and load wires swapped, neutral and traveler wires swapped, and load and traveler wires swapped.

The in-wall power adapter of any preceding clause, further comprising a switch coupled to the error detection circuit, wherein the error detection circuit is adapted to control the switch to disable an operation of the in-wall power adapter when a wiring error exists.

The in-wall power adapter of any preceding clause, wherein the switch is coupled to a contact element adapted to provide power to a load.

The in-wall power adapter of any preceding clause, wherein the user interface comprises at least one of a wireless communication circuit or an LED.

An in-wall power adapter adapted to receive a module and adapted to provide power to a load, the in-wall power adapter comprising a plurality of contact elements adapted to be coupled to wires of a junction box; a switch element configured to route a line voltage to a load; an error detection circuit coupled to one or more contact elements of the plurality of contact elements, wherein the error detection circuit is adapted to detect a wiring error; and a user interface adapted to provide an indication of a detected wiring error.

The in-wall power adapter of any preceding clause, wherein the error detection circuit performs a test to detect a wiring error when a neutral wire is not connected to the in-wall power adapter.

The in-wall power adapter of any preceding clause, wherein the error detection circuit performs a test to detect a wiring error when a line wire and a load wire connected to the in-wall power adapter are swapped.

The in-wall power adapter of any preceding clause, wherein the error detection circuit tests for one or more wiring conditions of a group of wiring conditions comprising a line connection missing, a neutral connection missing, a traveler connection missing, line and neutral wires swapped, line and load wires swapped, line and traveler wires swapped, neutral and load wires swapped, neutral and traveler wires swapped, and load and traveler wires swapped.

The in-wall power adapter of any preceding clause, further comprising a second switch coupled to the error detection circuit, wherein the error detection circuit is adapted to control the second switch to disable an operation of the in-wall power adapter when a wiring error exists.

The in-wall power adapter of any preceding clause, wherein the second switch is coupled to a contact element adapted to provide power to a load.

The in-wall power adapter of any preceding clause, wherein the user interface comprises at least one of a wireless communication circuit and an LED.

A method of implementing an in-wall power adapter adapted to receive a module and adapted to provide power to a load, the method comprising providing a plurality of contact elements adapted to be coupled to wires of a junction box; coupling an error detection circuit to one or more contact elements of the plurality of contact elements, wherein the error detection circuit is adapted to detect a wiring error; and providing an indication of a detected wiring error.

The method of any preceding clause, further comprising performing, by the error detection circuit, a test to detect a wiring error when a neutral wire is not connected to the in-wall power adapter.

The method of any preceding clause, further comprising performing, by the error detection circuit, a test to detect a wiring error when a line wire and a load wire connected to the in-wall power adapter are swapped.

The method of any preceding clause, further comprising performing, by the error detection circuit, a test for one or more wiring errors of a group of wiring errors comprising a line connection missing, a neutral connection missing, a traveler connection missing, line and neutral wires swapped, line and load wires swapped, line and traveler wires swapped, neutral and load wires swapped, neutral and traveler wires swapped, and load and traveler wires swapped.

The method of any preceding clause, further comprising coupling a switch to the error detection circuit, wherein the error detection circuit is adapted to control the switch to disable an operation of the in-wall power adapter.

The method of any preceding clause, wherein the switch is coupled to a contact element adapted to provide power to a load.

An in-wall power adapter configured to receive a module, the in-wall power adapter comprising a first plurality of contact elements adapted to be coupled to wires of a junction box, wherein the first plurality of contact elements comprises a first contact element adapted to receive a line voltage and a second contact element adapted to receive a neutral voltage; and a second plurality of contact elements adapted to be coupled to a module, wherein the second plurality of contact elements comprises a third contact element adapted to receive the line voltage and a fourth contact element adapted to receive the neutral voltage; wherein the third contact element is positioned to receive a line contact element of a first module of a plurality of modules of a system comprising the in-wall power adapter; and wherein the third contact element is not positioned to receive a line contact element of a second module of the plurality of modules.

The in-wall power adapter of any preceding clause, wherein an opening is provided to receive the third contact element.

The in-wall power adapter of any preceding clause further comprising a switch adapted to provide power to a load.

The in-wall power adapter of any preceding clause, wherein the module comprises a control circuit adapted to control an application of power to a load in response to a selection of an actuator adapted to control the switch.

The in-wall power adapter of any preceding clause, wherein the second module comprises a module having an outlet for receiving a plug.

The in-wall power adapter of any preceding clause, further comprising an outlet for receiving a plug.

The in-wall power adapter of any preceding clause, wherein the module comprises a transformer for generating a DC voltage based upon the line voltage received at the third contact element.

An in-wall power adapter configured to receive a module, the in-wall power adapter comprising a first plurality of contact elements adapted to be coupled to wires of a junction box, wherein the first plurality of contact elements comprises a first contact element adapted to receive a line voltage and a second contact element adapted to receive a neutral voltage; and a second plurality of contact elements adapted to be coupled to a module, wherein the second plurality of contact elements comprises a third contact element adapted to receive the line voltage, a fourth contact element adapted to receive the line voltage, and a fifth contact element adapted to receive the neutral voltage; wherein the third contact element is positioned to receive a line contact element of a first module of a plurality of modules of a system comprising the in-wall power adapter; and wherein the fourth contact element is positioned to receive a line contact element of a second module of the plurality of modules.

The in-wall power adapter of any preceding clause, further comprising an outlet for receiving a plug.

The in-wall power adapter of any preceding clause, wherein the second module comprises a passive module.

The in-wall power adapter of any preceding clause, wherein the module comprises a transformer for generating a DC voltage based upon the line voltage received at the third contact element.

The in-wall power adapter of any preceding clause, wherein the second module comprises a module having an outlet for receiving a plug.

The in-wall power adapter of any preceding clause, wherein the second module comprises a control circuit adapted to control an application of power to a load attached to the second module.

The in-wall power adapter of any preceding clause, further comprising a switch adapted to provide power to a load.

A method of implementing an in-wall power adapter configured to receive a module, the method comprising coupling a first plurality of contact elements adapted to wires of a junction box, wherein the first plurality of contact elements comprises a first contact element adapted to receive a line voltage and a second contact element adapted to receive a neutral voltage; and configuring a second plurality of contact elements to be coupled to contact elements of a module, wherein the second plurality of contact elements comprises a third contact element adapted to receive the line voltage and a fourth contact element adapted to receive the neutral voltage; and positioning the third contact element to receive a line contact element of a first module of a plurality of modules of a system comprising the in-wall power adapter; wherein the third contact element is not positioned to receive a line contact element of a second module of the plurality of modules.

The method of any preceding clause, further comprising providing an opening to receive the third contact element. The method of any preceding clause, further comprising providing a switch on the in-wall power adapter to provide power to a load.

The method of any preceding clause, further comprising providing a module having a control circuit adapted to control an application of power to a load in response to a selection of an actuator adapted to control the switch.

The method of any preceding clause, further comprising providing an outlet for receiving a plug.

The method of any preceding clause, wherein the second module comprises a module having an outlet for receiving a plug.

A system for indicating compatibility of modules and power adapters adapted to receive modules, the system comprising a plurality of types of power adapters having a switch; and at least one type of power adapter having an outlet; wherein the plurality of types of power adapters having a switch comprises at least one designation and the at least one type of power adapter having an outlet comprises a second designation that is different than the at least one designation.

The system of any preceding clause, wherein the plurality of types of power adapters having a switch comprises a first type of power adapter configured to control an application of power to a load.

The system of any preceding clause, wherein the first type of power adapter having a switch comprises one of a single pole power adapter and a primary multiway power adapter.

The system of any preceding clause, wherein a second type of power adapter having a switch comprises a companion multiway power adapter configured to send signals to a primary multiway power adapter.

The system of any preceding clause, further comprising a plurality of modules adapted to be attached to one or more power adapters of the system, wherein at least one module comprises the at least one designation.

The system of any preceding clause, wherein the at least one module further comprises the second designation.

The system of any preceding clause, wherein the at least one module is prevented from being attached to at least one power adapter not having the at least one designation.

A system for indicating compatibility of modules and power adapters adapted to receive modules, the system comprising a plurality of types of power adapters having a switch comprising a first type of power adapters configured to be coupled to a load and a second type of power adapter configured to provide signals to a power adapter of the first type of power adapters; and at least one type of power adapter having an outlet; wherein the system comprises at least a first designation for the first type of power adapter having a switch, a second designation for the second type of power adapter having a switch, and a third designation for power adapters having an outlet.

The system of any preceding clause, wherein the first type of power adapter having a switch comprises one of a single pole power adapter and a primary multiway power adapter.

The system of any preceding clause, wherein a second type of power adapter having a switch comprises a companion multiway power adapter configured to send signals to a first type of power adapter comprising a primary multiway power adapter.

The system of any preceding clause, further comprising a plurality of modules adapted to be attached to one or more power adapters of the system, wherein at least one module comprises the first designation.

The system of any preceding clause, wherein the at least one module further comprises the second designation.

The system of any preceding clause, wherein the plurality of types of power adapters having a switch are adapted to block a module having an outlet for receiving a plug.

A method of indicating compatibility of modules and power adapters adapted to receive modules, the method comprising providing a plurality of types of power adapters having a switch; providing at least one type of power adapter having an outlet; providing at least one designation for the plurality of types of power adapters having a switch; and providing a second designation that is different than the at least one designation for the at least one type of power adapter having an outlet.

The method of any preceding clause, wherein providing a plurality of types of power adapters having a switch comprises providing a first type of power adapter configured to control an application of power to a load.

The method of any preceding clause, wherein providing the first type of power adapter having a switch comprises providing one of a single pole power adapter and a primary multiway power adapter.

The method of any preceding clause, wherein providing a plurality of types of power adapters having a switch comprises providing a companion multiway power adapter configured to send signals to a primary multiway power adapter.

The method of any preceding clause, further comprising providing a plurality of modules adapted to be attached to one or more power adapters of a system, wherein at least one module comprises the at least one designation.

The method of any preceding clause, wherein providing the at least one module further comprises the second designation.

The method of any preceding clause, wherein the at least one module is prevented from being attached to at least one power adapter not having the at least one designation.

A module adapted to be attached to an in-wall power adapter, the module comprising a plurality of contact elements adapted to be coupled to contact elements of an in-wall power adapter, wherein the plurality of contact elements comprises a first contact element adapted to receive a line voltage and a second contact element adapted to receive a neutral voltage; and a temperature sensor adapted to receive air from a room; wherein the temperature sensor determines a first temperature representing a room temperature of the room having the module.

The module of any preceding clause, wherein the portion of the module is adapted to extend through an opening of the wall plate, the module further a control circuit coupled to the temperature sensor.

The module of any preceding clause, further comprising a second temperature sensor positioned in the module, wherein the second temperature sensor determines a second temperature associated with the module and the control circuit generates an estimated room temperature based upon the first temperature and the second temperature.

The module of any preceding clause, further comprising an insulating material located between a first portion of the module having the temperature sensor and a second portion of the module having the second temperature sensor.

The module of any preceding clause, further comprising a channel adapted to receive air from the room, wherein the temperature sensor detects an air temperature of air in the channel.

The module of any preceding clause, further comprising a fan adapted to draw air into the channel.

The module of any preceding clause, further comprising a wireless communication circuit coupled to the control circuit, wherein the wireless communication circuit is adapted to transmit a temperature associated with the room.

A module adapted to be attached to an in-wall power adapter, the module comprising a plurality of contact elements adapted to be coupled to contact elements of an in-wall power adapter, wherein the plurality of contact elements comprises a first contact element adapted to receive a line voltage and a second contact element adapted to receive a neutral voltage; an opening on a surface of a module adapted to receive air; and a temperature sensor on the module having a portion extending through an opening of a wall plate attached to an in-wall power adapter; wherein the temperature sensor determines a first temperature representing a room temperature of a room having the module.

The module of any preceding clause, further comprising a control circuit coupled to the temperature sensor.

The module of any preceding clause, further comprising a second temperature sensor positioned in the module, wherein the second temperature sensor determines a second temperature associated with the module and the control circuit generates an estimated room temperature based upon the first temperature and the second temperature.

The module of any preceding clause, further comprising an insulating material located between a first portion of the module having the temperature sensor and a second portion of the module having the second temperature sensor.

The module of any preceding clause, further comprising a fan adapted to draw air into a channel having the temperature sensor.

The module of any preceding clause, further comprising a wireless communication circuit coupled to the control circuit, wherein the wireless communication circuit is adapted to transmit a temperature associated with the room.

A method of implementing a module adapted to be attached to an in-wall power adapter, the method comprising providing a plurality of contact elements adapted to be coupled to contact elements of an in-wall power adapter, wherein the plurality of contact elements comprises a first contact element adapted to receive a line voltage and a second contact element adapted to receive a neutral voltage; providing a temperature sensor adapted to receive air from a room; and determining, using the temperature sensor, a first temperature representing a room temperature of a room having the module.

The method of any preceding clause, wherein the portion of the module is adapted to extend through an opening of the wall plate, the method further comprising coupling a control circuit to the temperature sensor.

The method of any preceding clause, further comprising positioning a second temperature sensor in the module, wherein the second temperature sensor determines a second temperature associated with the module and the control circuit generates an estimated room temperature based upon the first temperature and the second temperature.

The method of any preceding clause, further comprising providing an insulating material located between a first portion of the module having the temperature sensor and a second portion of the module having the second temperature sensor.

The method of any preceding clause, further comprising providing a channel adapted to receive air from the room, wherein the temperature sensor detects an air temperature of air in the channel.

The method of any preceding clause, further comprising providing a fan adapted to draw air into the channel.

The method of any preceding clause, further comprising coupling a wireless communication circuit to the control circuit, wherein the wireless communication circuit is adapted to transmit a temperature associated with the room.

What applicant is claiming:

1. An error detection module adapted to be attached to an in-wall power adapter, the error detection module comprising:
a switch element configured to route a line voltage to a load;
a control circuit coupled to the switch element, wherein the control circuit is adapted to control the switch element; and
a user interface adapted to provide a test result associated with a detected error;
wherein the control circuit controls the switch element to detect a type of wiring error.

2. The error detection module of claim 1, wherein the control circuit performs a test to detect a wiring error when a neutral wire is not connected to a contact element of the in-wall power adapter.

3. The error detection module of claim 1, wherein the control circuit performs a test to detect a wiring error when a line wire and a load wire connected to the in-wall power adapter are swapped.

4. The error detection module of claim 1, wherein the control circuit performs tests for detecting one or more wiring error of a group of wiring error comprising a line connection missing, a neutral connection missing, a traveler connection missing, line and neutral wires swapped, line and load wires swapped, line and traveler wires swapped, neutral and load wires swapped, neutral and traveler wires swapped, and load and traveler wires swapped.

5. The error detection module of claim 1, further comprising a test circuit coupled to the control circuit, wherein the test circuit is configured to select a contact element of the error detection module to determine a voltage of the contact element.

6. The error detection module of claim 5, wherein the test circuit comprises a multiplexer circuit.

7. The error detection module of claim 1, wherein the user interface provides an indication of a type of wiring error.

8. An error detection module adapted to be attached to an in-wall power adapter, the error detection module comprising:
a switch element configured to connect a line voltage to one of a load contact element and a traveler contact element;
a control circuit coupled to the switch element, wherein the control circuit is adapted to control the switch element; and
a user interface adapted to provide a test result associated with a detected wiring error;
wherein the control circuit controls the switch element to detect a type of wiring error.

9. The error detection module of claim 8, further comprising a second switch element configured to route a signal from a contact element associated with a multiway wiring arrangement to one of the load contact element and the traveler contact element.

10. The error detection module of claim 9, wherein the switch element and the second switch element are controlled by the control circuit to couple either a line contact element or the contact element associated with a multiway wiring arrangement to the load contact element.

11. The error detection module of claim 8, wherein the control circuit tests for one or more wiring errors of the group of wiring errors comprising a line connection missing, a neutral connection missing, a traveler connection missing, line and neutral wires swapped, line and load wires swapped, line and traveler wires swapped, neutral and load wires swapped, neutral and traveler wires swapped, and load and traveler wires swapped.

12. The error detection module of claim 8, further comprising a test circuit coupled to the control circuit for selecting a contact element to determine a voltage of the contact element.

13. The error detection module of claim 12, wherein the test circuit comprises a multiplexer circuit.

14. The error detection module of claim 8, wherein the user interface provides an indication of a type of wiring error.

15. A method of detecting a wiring error for an in-wall power adapter, the method comprising:
configuring a switch element to route a line voltage to a load;
coupling a control circuit to the switch element, wherein the control circuit is adapted to control the switch element; and
providing a user interface to indicate a test result associated with a detected wiring error;
wherein the control circuit controls the switch element to detect a type of wiring error.

16. The method of claim 15, further comprising detecting, by the control circuit, a wiring error when a neutral wire is not connected to a contact element of the in-wall power adapter.

17. The method of claim 15, further comprising detecting, by the control circuit, a wiring error when a line wire and a load wire connected to the in-wall power adapter are swapped.

18. The method of claim 15, further comprising testing, by the control circuit, for one or more wiring errors of a group of wiring errors comprising a line connection missing, a neutral connection missing, a traveler connection missing, line and neutral wires swapped, line and load wires swapped, line and traveler wires swapped, neutral and load wires swapped, neutral and traveler wires swapped, and load and traveler wires swapped.

19. The method of claim 15, further comprising coupling a test circuit to the control circuit, wherein the test circuit is adapted to select a contact element to determine a voltage of the contact element.

20. The method of claim 15, further comprising providing an indication of a type of wiring error.
